(19) United States
(12) Patent Application Publication
(10) Pub. No.: US 2026/0253656 A1
(43) Pub. Date: Aug. 27, 2026

(54) Shift Register Unit, Driving Method Thereof, Display Substrate and Display Apparatus

(71) Applicants: Chengdu BOE Optoelectronics Technology Co., Ltd., Chengdu, Sichuan (CN); BOE Technology Group Co., Ltd., Beijing (CN); Beijing BOE Technology Development Co., Ltd., Beijing (CN)

(72) Inventors: Yao HUANG, Beijing (CN); Rong WANG, Beijing (CN); Mengmeng DU, Beijing (CN)

(21) Appl. No.: 18/995,197

(22) PCT Filed: May 21, 2024
(86) PCT No.: PCT/CN2024/094416

§ 371 Date: Jan. 16, 2025

(30) Foreign Application Priority Data
Jun. 13, 2023 (CN) 202310701919.2

(51) Int. Cl. G11C 19/28; G09G 3/3233; G09G 3/3266

(52) U.S. Cl. CPC G11C 19/28; G09G 3/3233; G09G 3/3266; G09G 2300/0426; G09G 2300/0452; G09G 2300/0819; G09G 2300/0842; G09G 2300/0861; G09G 2310/0286; G09G 2310/08; G09G 2330/021

(57) ABSTRACT

A shift register unit includes: a node control sub-circuit configured to provide a signal at a signal input terminal or a first power supply terminal to a first node and provide a signal at a second power supply terminal or a first clock signal terminal to a second node under control of signals at a first clock signal terminal and a second clock signal terminal; a pull-down sub-circuit configured to provide a signal at a third power supply terminal to the first node; an output sub-circuit configured to provide a signal at the first power supply terminal or the second clock signal terminal to a first signal output terminal under control of signals at the first node, the second node and the second power supply terminal.

### CROSS-REFERENCE TO RELATED APPLICATIONS

This application is a national stage application of PCT Application No. PCT/CN2024/094416, which is filed on May 21, 2024 and claims priority to Chinese Patent Application No. 202310701919.2, filed on Jun. 13, 2023, to the China National Intellectual Property Administration, entitled “Shift Register Unit, Driving Method Thereof, Display Substrate and Display apparatus”, contents of which should be regarded as being incorporated herein by reference.

### TECHNICAL FIELD

The present disclosure relates to, but is not limited to, the field of display technology, and more particularly, to a shift register unit, a driving method thereof, a display substrate and a display apparatus.

### BACKGROUND

An Organic Light Emitting Diode (OLED) and a Quantum dot Light Emitting Diode (QLED) are active light emitting display devices and have advantages of self-illumination, a wide viewing angle, a high contrast ratio, low power consumption, an extremely high reaction speed, lightness and thinness, flexibility, and a low cost, etc. With continuous development of display technologies, a flexible display apparatus (Flexible Display) in which an OLED or QLED is used as a light emitting element and signal control is performed by a Thin Film Transistor (TFT) has become a mainstream product in the field of display at present.

### SUMMARY

The following is a summary of subject matters described herein in detail. This summary is not intended to limit the protection scope of claims.

In a first aspect, the present disclosure provides a shift register unit including: a node control sub-circuit, an output sub-circuit, and a pull-down sub-circuit;

The node control sub-circuit is electrically connected to a signal input terminal, a first clock signal terminal, a second clock signal terminal, a first power supply terminal, a second power supply terminal, a first node, a the second node, respectively, and is configured to provide a signal at the signal input terminal or the first power supply terminal to the first node and provide a signal at the second power supply terminal or the first clock signal terminal to the second node under control of signals at the first clock signal terminal and the second clock signal terminal;

The pull-down sub-circuit is electrically connected to the first node and a third power supply terminal, respectively, and is configured to provide a signal at the third power supply terminal to the first node;

The output sub-circuit is electrically connected to the second clock signal terminal, the first power supply terminal, the second power supply terminal, a first signal output terminal, the first node, and the second node, respectively, and is configured to provide a signal at the first power supply terminal or the second clock signal terminal to the first signal output terminal under control of signals at the first node, the second node, and the second power supply terminal;

An absolute value of a voltage value of the signal at the third power supply terminal is less than an absolute value of a voltage value of the signal at the second power supply terminal.

In an exemplary implementation mode, the pull-down sub-circuit includes: an eleventh transistor;

A first electrode of the eleventh transistor is electrically connected to the third power supply terminal, and a second electrode of the eleventh transistor is electrically connected to the first node.

In an exemplary implementation mode, a control electrode of the eleventh transistor is electrically connected to the first node.

In an exemplary implementation mode, the node control sub-circuit includes: a first transistor, a second transistor, a third transistor, a sixth transistor, and a seventh transistor;

A control electrode of the first transistor is connected to the first clock signal terminal, a first electrode of the first transistor is electrically connected to the signal input terminal, and a second electrode of the first transistor is electrically connected to the first node;

A control electrode of the second transistor is electrically connected to the first node, a first electrode of the second transistor is connected to the first clock signal terminal, and the second electrode of the second transistor is electrically connected to the second node;

A control electrode of the third transistor is electrically connected to the first clock signal terminal, a first electrode of the third transistor is connected to the second power supply terminal, and a second electrode of the third transistor is electrically connected to the second node;

A control electrode of the sixth transistor is electrically connected to the second node, a first electrode of the sixth transistor is connected to the first power supply terminal, and a second electrode of the sixth transistor is electrically connected to a fourth node;

A control electrode of a seventh transistor is electrically connected to the second clock signal terminal, a first electrode of the seventh transistor is connected to the fourth node, and a second electrode of the seventh transistor is electrically connected to the first node.

In an exemplary implementation mode, the output sub-circuit includes: a fourth transistor, a fifth transistor, and an eighth transistor;

A control electrode of the fourth transistor is electrically connected to the second node, a first electrode of the fourth transistor is connected to the first power supply terminal, and a second electrode of the fourth transistor is electrically connected to the first signal output terminal;

A control electrode of the fifth transistor is electrically connected to a third node, a first electrode of the fifth transistor is connected to the second clock signal terminal, and a second electrode of the fifth transistor is electrically connected to the first signal output terminal;

A control electrode of the eighth transistor is electrically connected to the second power supply terminal, a first electrode of the eighth transistor is electrically connected to the first node, and a second electrode of the eighth transistor is electrically connected to the third node.

In an exemplary implementation mode, the pull-down sub-circuit includes: an eleventh transistor;

A control electrode of the eleventh transistor is electrically connected to the third node.

In an exemplary implementation mode, the output sub-circuit further includes: at least one of a first capacitor and a second capacitor;

A first plate of the first capacitor is electrically connected to the second node, and a second plate of the first capacitor is electrically connected to the first power supply terminal;

A first plate of the second capacitor is electrically connected to the third node, and a second plate of the second capacitor is electrically connected to the first signal output terminal.

In an exemplary implementation mode, the output sub-circuit is further electrically connected to a third clock signal terminal and a second signal output terminal, respectively, is configured to provide signals at the second power supply terminal or the third clock signal terminal to the second signal output terminal under control of signals at the first node and the second node.

In an exemplary implementation mode, the output sub-circuit includes: a fourth transistor, a fifth transistor, an eighth transistor, a ninth transistor, and a tenth transistor;

A control electrode of the fourth transistor is electrically connected to the second node, a first electrode of the fourth transistor is connected to the first power supply terminal, and a second electrode of the fourth transistor is electrically connected to the first signal output terminal;

A control electrode of the fifth transistor is electrically connected to a third node, a first electrode of the fifth transistor is connected to the second clock signal terminal, and a second electrode of the fifth transistor is electrically connected to the first signal output terminal;

A control electrode of the eighth transistor is electrically connected to the second power supply terminal, a first electrode of the eighth transistor is electrically connected to the first node, and a second electrode of the eighth transistor is electrically connected to the third node;

A control electrode of the ninth transistor is electrically connected to the first node, a first electrode of the ninth transistor is connected to the third clock signal terminal, and a second electrode of the ninth transistor is electrically connected to the second signal output terminal;

A control electrode of the tenth transistor is electrically connected to the second node, a first electrode of the tenth transistor is connected to the second power supply terminal, and a second electrode of the tenth transistor is electrically connected to the second signal output terminal.

In an exemplary implementation mode, the output sub-circuit further includes: a twelfth transistor; the control electrode of the ninth transistor is electrically connected to the first node through the twelfth transistor;

A control electrode of the twelfth transistor is electrically connected to the second power supply terminal, a first electrode of the twelfth transistor is electrically connected to the first node, and a second electrode of the twelfth transistor is electrically connected to the control electrode of the ninth transistor.

In an exemplary implementation mode, the output sub-circuit further includes: at least one of a first capacitor, a second capacitor, a third capacitor, and a fourth capacitor;

A first plate of the first capacitor is electrically connected to the second node, and a second plate of the first capacitor is electrically connected to the first power supply terminal;

A first plate of the second capacitor is electrically connected to the third node, and a second plate of the second capacitor is electrically connected to the first signal output terminal;

A first plate of the third capacitor is electrically connected to the control electrode of the ninth transistor, and a second plate of the third capacitor is connected to the second signal output terminal; and

A first plate of the fourth capacitor is electrically connected to the second node, and a second plate of the fourth capacitor is connected to the second power supply terminal.

In an exemplary implementation mode, the signal at the third clock signal terminal and the signal at the second clock signal terminal are mutually inverted signals.

In an exemplary implementation mode, further including: an output control sub-circuit;

The output control sub-circuit is electrically connected to the first power supply terminal and the first signal output terminal, respectively, and is configured to store a voltage difference between signals at the first signal output terminal and the first power supply terminal.

In an exemplary implementation mode, the output control sub-circuit includes: a fifth capacitor;

A first plate of the fifth capacitor is electrically connected to the first power supply terminal, and a second electrode of the fifth capacitor is electrically connected to the first signal output terminal.

In an exemplary implementation mode, the signal at the first clock signal terminal and the signal at the second clock signal terminal are not simultaneously effective level signals.

In a second aspect, the present disclosure further provides a display substrate including: a base substrate and sub-pixels, a gate line and a gate driving circuit disposed on the base substrate, the base substrate is provided with a display region and a non-display region, the gate driving circuit is located in the non-display region, the sub-pixels and the gate line are located in the display region, and the gate line is electrically connected to the sub-pixels and the gate driving circuit, respectively;

The gate driving circuit includes a plurality of cascaded shift register units described above, wherein a first signal output terminal of an i-th stage shift register unit is connected to a signal input terminal of an (i+1)-st stage shift register unit, 1≤i<N, N is a total number of stages of the shift register units.

In an exemplary implementation mode, a first signal output terminal of a shift register unit is electrically connected to the gate line.

In an exemplary implementation mode, further including: an initial signal line, a first clock signal line, a second clock signal line, a first power supply line, a second power supply line, and a third power supply line disposed on the base substrate and located in the non-display region;

Any one of the initial signal line, the first clock signal line, the second clock signal line, the first power supply line, the second power supply line, and the third power supply line extends in a first direction, and the gate line extends in a second direction, and the first direction intersects the second direction.

In an exemplary implementation mode, the initial signal line, the first clock signal line, the second clock signal line, and the first power supply line are sequentially arranged in a direction close to the display region, and are located at a side of the shift register units away from the display region.

In an exemplary implementation mode, a shift register unit includes a plurality of transistors, and the second power supply line is located at a side of the first power supply line close to the display region and is located between the plurality of transistors of the shift register unit.

In an exemplary implementation mode, the third power supply line is located at a side of the second power supply line close to the display region, and an orthographic projection of the third power supply line on the base substrate is partially overlapped with orthographic projections of the shift register units on the base substrate.

In an exemplary implementation mode, a shift register unit includes: a first transistor, a second transistor, a third transistor, a sixth transistor, and a seventh transistor;

At least a portion of any one of the first transistor, the second transistor, the third transistor, the sixth transistor, and the seventh transistor is located between the first power supply line and the second power supply line.

In an exemplary implementation mode, a shift register unit includes: a fourth transistor, a fifth transistor, an eighth transistor, an eleventh transistor, and a twelfth transistor, and a number of the second power supply line is at least one;

At least a portion of any one of the fourth transistor, the fifth transistor, the eighth transistor, the eleventh transistor, and the twelfth transistor is located at a side of the second power supply line close to the display region.

In an exemplary implementation mode, a shift register unit includes a second capacitor; and

The second capacitor is located at a side of the third power supply line close to the display region.

In an exemplary implementation mode, further including: a third clock signal line and a fourth clock signal line disposed on the base substrate and located in the non-display region, any one of the third clock signal line and the fourth clock signal line extends in the first direction;

A number of the second power supply line is two, a second power supply line close to the display region is located at a side of any one of the third clock signal line and the fourth clock signal line close to the display region, and a second power supply line away from the display region is located between the first power supply line and the third power supply line.

In an exemplary implementation mode, a shift register unit includes: a fourth transistor, a fifth transistor, an eighth transistor, a ninth transistor, a tenth transistor, an eleventh transistor, a twelfth transistor, and a fourth capacitor;

The fourth transistor, the fifth transistor, the eighth transistor, the eleventh transistor, and the twelfth transistor are located between the second power supply line away from the display region and any one of the third clock signal line and the fourth clock signal line, and the ninth transistor and the tenth transistor are located at a side of the second power supply line close to the display region close to the display region;

An orthographic projection of the second power supply line close to the display region on the base substrate is partially overlapped with an orthographic projection of the fourth capacitor on the base substrate.

In an exemplary implementation mode, a first clock signal terminal of the i-th stage shift register unit is electrically connected to one of the first clock signal line and the second clock signal line, and a second clock signal terminal of the i-th stage shift register unit is electrically connected to the other of the first clock signal line and the second clock signal line;

Signal lines connected to first clock signal terminals of adjacent shift register units are different, and signal lines connected to second clock signal terminals of adjacent shift register units are different.

In an exemplary implementation mode, a shift register unit includes: a fourth transistor and a fifth transistor;

An orthographic projection of the third power supply line on the base substrate is partially overlapped with of orthographic projections of the fourth transistor and the fifth transistor on the base substrate.

In an exemplary implementation mode, an active layer of the eighth transistor extends in the second direction, any one of a first electrode and a second electrode of the eighth transistor extends in the first direction, and a gate electrode of the eighth transistor extends at least partially in the first direction.

In an exemplary implementation mode, a gate electrode of the eleventh transistor and a gate electrode of the fifth transistor are of an integral structure, an orthographic projection of a first electrode of the eleventh transistor on the base substrate is partially overlapped with an orthographic projection of the third power supply line on the base substrate and the first electrode of the eleventh transistor is electrically connected to the third power supply line, and a second electrode of the eleventh transistor, a first electrode of the eighth transistor and a first electrode of the twelfth transistor are of an integral structure.

In an exemplary implementation mode, a width of any one of the first power supply line, the second power supply line, and the third power supply line in the second direction is less than a width of any one of the first clock signal line, the second clock signal line, the third clock signal line, and the fourth clock signal line in the second direction.

In an exemplary implementation mode, a third clock signal terminal of the i-th stage shift register unit is electrically connected to one of the third clock signal line and the fourth clock signal line, and a third clock signal terminal of the (i+1)-st stage shift register unit is electrically connected to the other of the third clock signal line and the fourth clock signal line.

In an exemplary implementation mode, a channel width of an active layer of the tenth transistor the ninth transistor is greater than a channel width of an active layer of the fourth transistor.

In an exemplary implementation mode, the channel width of the active layer of the tenth transistor the ninth transistor is not less than 90 microns.

In an exemplary implementation mode, the channel width of the active layer of the fourth transistor is not greater than 50 microns.

In an exemplary implementation mode, a channel width of an active layer of the ninth transistor the tenth transistor is greater than a channel width of an active layer of the fifth transistor.

In an exemplary implementation mode, the channel width of the active layer of the ninth transistor the tenth transistor is not less than 90 microns.

In an exemplary implementation mode, the channel width of the active layer of the fifth transistor is not greater than 50 microns.

In an exemplary implementation mode, a second signal output terminal of the shift register unit is electrically connected to the gate line.

In a third aspect, the present disclosure further provides a display apparatus including the display substrate described above.

In a fourth aspect, the present disclosure also provides a method for driving a shift register unit, configured to drive the shift register unit described above, wherein the method includes:
Providing a signal at the signal input terminal or the first power supply terminal to the first node and providing a signal at the second power supply terminal or the first clock signal terminal to the second node under control of signals at the first clock signal terminal and the second clock signal terminal by the node control sub-circuit;
Providing a signal at the third power supply terminal to the first node by the pull-down sub-circuit; and
Providing a signal at the first power supply terminal or the second clock signal terminal to the first signal output terminal under control of signals at the first node and the second node by the output sub-circuit.

In an exemplary implementation mode, the shift register unit further includes: an output control sub-circuit;

The method further includes: providing a signal at the second power supply terminal or a third clock signal terminal to the second signal output terminal under control of signals at the first node and the second node by the output sub-circuit; and

Storing a voltage difference between signals at the first signal output terminal and the first power supply terminal by the output control sub-circuit.

Other aspects of the present disclosure may be comprehended after the drawings and the detailed descriptions are read and understood.

### BRIEF DESCRIPTION OF DRAWINGS

Accompanying drawings are intended to provide an understanding of technical solutions of the present application and form a part of the specification, and are used to explain the technical solutions of the present application together with embodiments of the present application, and do not constitute a limitation on the technical solutions of the present application.

FIG. 1 is a schematic structural diagram of a shift register unit according to an embodiment of the present disclosure;

FIG. 2 is an equivalent circuit diagram of a pull-down sub-circuit;

FIG. 3 is an equivalent circuit diagram of another pull-down sub-circuit;

FIG. 4 is an equivalent circuit diagram of a node control sub-circuit.

FIG. 5 is a first equivalent circuit diagram of an output sub-circuit.

FIG. 6 is an equivalent circuit diagram of an output sub-circuit;

FIG. 7 is a second schematic structural diagram of a shift register unit according to an embodiment of the present disclosure;

FIG. 8 is a third equivalent circuit diagram of an output sub-circuit;

FIG. 9 is a fourth equivalent circuit diagram of an output sub-circuit;

FIG. 10 is a third schematic structural diagram of a shift register unit according to an embodiment of the present disclosure;

FIG. 11 is an equivalent circuit diagram of an output control sub-circuit.

FIG. 12 is a first equivalent circuit diagram of a shift register unit;

FIG. 13 is a second equivalent circuit diagram of a shift register unit;

FIG. 14 is a third equivalent circuit diagram of a shift register unit;

FIG. 15 is a fourth equivalent circuit diagram of a shift register unit;

FIG. 16 is a fifth equivalent circuit diagram of a shift register unit;

FIG. 17 is a sixth equivalent circuit diagram of a shift register unit;

FIG. 18 is a seventh equivalent circuit diagram of a shift register unit;

FIG. 19 is a signal timing simulation diagram of the shift register unit provided in FIGS. 12 and 13;

FIG. 20 is a signal timing simulation diagram of the shift register provided in FIG. 14 to FIG. 18.

FIG. 21 is a comparison diagram of signals at a first node and a second signal output terminal of different shift register units;

FIG. 22 is a schematic diagram of a structure of a display apparatus.

FIG. 23 is a first schematic diagram of a planar structure of a display substrate.

FIG. 24 is a second schematic diagram of a planar structure of a display substrate.

FIG. 25 is a third schematic plan view of a display substrate.

FIG. 26A is an equivalent circuit diagram of a pixel driving circuit.

FIG. 26B is a working timing diagram of the pixel driving circuit provided in FIG. 26A.

FIG. 27A is an equivalent circuit diagram of another pixel driving circuit.

FIG. 27B is a working timing diagram of the pixel driving circuit provided in FIG. 27A.

FIG. 28 is a first cascade schematic diagram of a gate driving circuit;

FIG. 29 is a second cascade schematic diagram of a gate driving circuit;

FIG. 30 is a first schematic diagram of a structure of a display substrate.

FIG. 31 is a second schematic diagram of a structure of a display substrate.

FIG. 32 is a schematic diagram after a pattern of a semiconductor layer is formed in FIG. 30;

FIG. 33 is a schematic diagram after a pattern of a semiconductor layer is formed in FIG. 31;

FIG. 34 is a schematic diagram of a pattern of a first conductive layer in FIG. 30.

FIG. 35 is a schematic diagram after a pattern of a first conductive layer is formed in FIG. 30.

FIG. 36 is a schematic diagram of a pattern of a first conductive layer in FIG. 31.

FIG. 37 is a schematic diagram after a pattern of a first conductive layer is formed in FIG. 31.

FIG. 38 is a schematic diagram of a pattern of a second conductive layer in FIG. 30.

FIG. 39 is a schematic diagram after a pattern of a second conductive layer is formed in FIG. 30.

FIG. 40 is a schematic diagram of a pattern of a second conductive layer in FIG. 31.

FIG. 41 is a schematic diagram after a pattern of a second conductive layer is formed in FIG. 31.

FIG. 42 is a schematic diagram after a pattern of a third insulation layer is formed in FIG. 30;

FIG. 43 is a schematic diagram after a pattern of a third insulation layer is formed in FIG. 31;

FIG. 44 is a schematic diagram of a pattern of a third conductive layer in FIG. 30.

FIG. 45 is a schematic diagram after a pattern of a third conductive layer is formed in FIG. 30;

FIG. 46 is a schematic diagram of a pattern of a third conductive layer in FIG. 31.

FIG. 47 is a schematic diagram after a pattern of a third conductive layer is formed in FIG. 31;

FIG. 48 is a schematic diagram after a pattern of a fourth insulation layer is formed in FIG. 30.

FIG. 49 is a schematic diagram after a pattern of a fourth insulation layer is formed in FIG. 31.

FIG. 50 is a schematic diagram of a pattern of a fourth conductive layer in FIG. 30 and FIG. 31.

FIG. 51 is a schematic diagram after a pattern of a fourth conductive layer is formed in FIG. 30.

FIG. 52 is a schematic diagram after a pattern of a fourth conductive layer is formed in FIG. 31.

### DETAILED DESCRIPTION

To make objectives, technical solutions, and advantages of the present disclosure clearer, the embodiments of the present disclosure will be described in detail below with reference to the accompanying drawings. It is to be noted that implementations may be implemented in multiple different forms. Those of ordinary skills in the art may easily understand such a fact that modes and contents may be transformed into various forms without departing from the purpose and scope of the present disclosure. Therefore, the present disclosure should not be explained as being limited to the contents recorded in the following implementations only. The embodiments and features in the embodiments of the present disclosure may be randomly combined with each other if there is no conflict. In order to keep following description of the embodiments of the present disclosure clear and concise, detailed description of part of known functions and known components are omitted in the present disclosure. The drawings of the embodiments of the present disclosure only involve structures involved in the embodiments of the present disclosure, and for other structures, reference may be made to conventional designs.

In the accompanying drawings, a size of each composition element, a thickness of a layer, or a region may be exaggerated sometimes for clarity. Therefore, an implementation of the present disclosure is not necessarily limited to the size, and a shape and a size of each component in the drawings do not reflect an actual scale. In addition, the accompanying drawings schematically illustrate ideal examples, and an implementation of the present disclosure is not limited to shapes, numerical values, or the like shown in the drawings.

Ordinal numerals “first”, “second”, “third”, etc., in the specification are set not to form limits in numbers but only to avoid confusion between constituent elements.

In the specification, for convenience, expressions “central”, “above”, “below”, “front”, “back”, “vertical”, “horizontal”, “top”, “bottom”, “inside”, “outside”, etc., for indicating directional or positional relationships are used to illustrate positional relationships between the constituent elements with reference to the accompanying drawings, not to indicate or imply that involved devices or elements are required to have specific orientations or are structured and operated in the specific orientations but only to easily describe the present specification and simplify the description, and thus should not be understood as limitations on the present disclosure. The positional relationships between the constituent elements may be changed as appropriate based on a direction according to which each constituent element is described. Therefore, appropriate replacements based on situations are allowed, which is not limited to the expressions in the specification.

In the specification, unless otherwise explicitly specified and defined, terms “mounting”, “coupling”, and “connection” should be understood in a broad sense. For example, it may be a fixed connection, or a detachable connection, or an integral connection; it may be a mechanical connection or an electrical connection; it may be a direct connection, or an indirect connection through a middleware, or an internal communication between two elements. Those of ordinary skills in the art may understand specific meanings of the above terms in the present disclosure according to specific situations.

In the specification, a transistor refers to an element that at least includes three terminals, i.e., a gate electrode, a drain electrode, and a source electrode. The transistor has a channel region between the drain electrode (drain electrode terminal, drain region, or drain) and the source electrode (source electrode terminal, source region, or source), and a current can flow through the drain electrode, the channel region, and the source electrode. It is to be noted that in the specification, the channel region refers to a region through which a current mainly flows.

In the specification, a first electrode may be a drain electrode, and a second electrode may be a source electrode. Or, the first electrode may be a source electrode, and the second electrode may be a drain electrode. In a case that transistors with opposite polarities are used, or in a case that a direction of a current changes during operation of a circuit, or the like, functions of the “source electrode” and the “drain electrode” are sometimes interchangeable. Therefore, the “source electrode” and the “drain electrode” are interchangeable in the specification.

In the specification, an “electrical connection” includes a case that constituent elements are connected together through an element with a certain electrical action. The “element with a certain electrical effect” is not particularly limited as long as electrical signals between the connected constituent elements may be sent and received. Examples of the “element with a certain electrical action” not only include an electrode and a wiring, but also include a switching element such as a transistor, a resistor, an inductor, a capacitor, another element with various functions, etc.

In the specification, “parallel” refers to a state in which an angle formed by two straight lines is above −10° and below 10°, and thus may include a state in which the angle is above −5° and below 5°. In addition, “perpendicular” refers to a state in which an angle formed by two straight lines is above 80° and below 100°, and thus may include a state in which the angle is above 85° and below 95°.

In the specification, a “film” and a “layer” are interchangeable. For example, a “conductive layer” may be replaced with a “conductive film” sometimes. Similarly, an “insulation film” may be replaced with an “insulation layer” sometimes.

In the specification, “disposed in a same layer” adopted refers to a structure formed by patterning two (or more than two) structures through a same patterning process, and their materials may be the same or different. For example, materials of precursors for forming multiple structures disposed in a same layer are the same, and final materials may be the same or different.

A triangle, rectangle, trapezoid, pentagon, or hexagon, etc. in the specification is not strictly defined, and it may be an approximate triangle, rectangle, trapezoid, pentagon, or hexagon, etc. There may be some small deformations caused by tolerance, and there may be a chamfer, an arc edge, deformation, etc.

In the present disclosure, “about” means that a boundary is not defined so strictly and numerical values within process and measurement error ranges are allowed.

A display substrate includes: a pixel driving circuit, a light emitting element and a gate driving circuit, wherein the gate driving circuit is configured to provide a gate signal to a transistor in the pixel driving circuit so that the pixel driving circuit can drive the light emitting element to emit light. A Low Temperature Poly-Silicon (LTPS for short) technology is used in a display substrate. The LTPS technology has advantages such as a high resolution, a high response speed, high brightness, and a high aperture ratio. Although it is welcomed by the market, the LTPS technology also has some defects, such as a relatively high production cost and relatively large power consumption. At this time, a technical solution of Low Temperature Polycrystalline Oxide (LTPO for short) came into being. Compared with the LTPS technology in which a pixel driving circuit includes low temperature poly-silicon transistors, in LTPO technology, a pixel driving circuit includes temperature poly-silicon transistors and metal oxide transistors. A leakage current in a metal oxide transistor is smaller, which makes pixel point response faster. An additional layer of oxide is added to a display substrate, which can reduce energy consumption required for exciting pixel points, thus reducing power consumption during displaying of a screen. For a display product using the LTPO technology, a set of drive circuits are included to control metal oxide transistors in the display product. As the size, resolution and refresh frequency of the display substrate increase, the compensation time of the pixel driving circuit in one frame is shorter and shorter. Worse still, the driving circuit for controlling the metal oxide transistors in the display substrate usually has a low voltage at some nodes, so that the voltage of the output signal of the driving circuit for controlling the metal oxide transistors cannot reach a predetermined voltage, i.e., the driving ability of the driving circuit for controlling the metal oxide transistors is weak, which leads to a low degree of conduction of the metal oxide transistors, affecting the performance of the pixel driving circuit, thereby reducing the display effect of the display substrate.

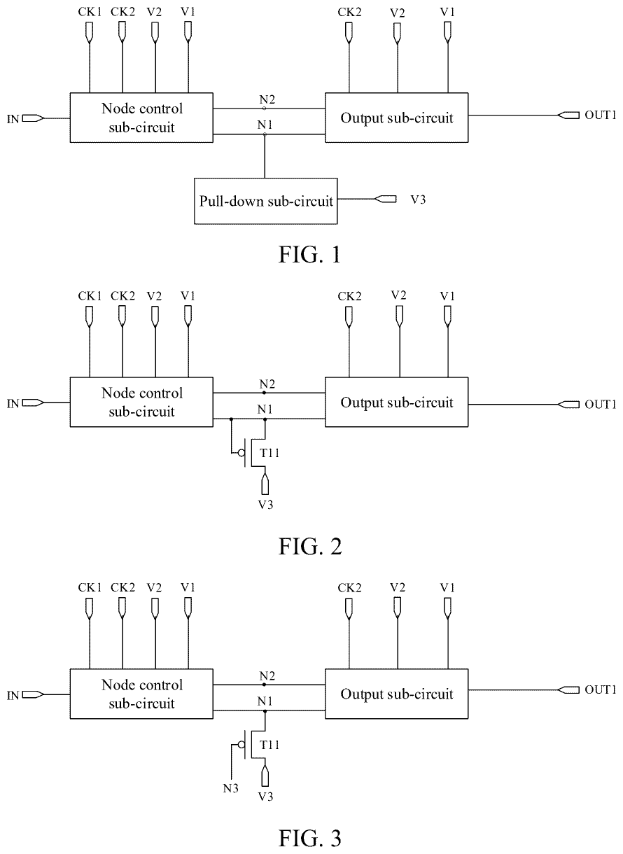

FIG. 1 is a first schematic structural diagram of a shift register unit according to an embodiment of the present disclosure. As shown in FIG. 1, a shift register unit according to an embodiment of the present disclosure may include a node control sub-circuit, an output sub-circuit, and a pull-down sub-circuit.

As shown IN FIG. 1, the node control sub-circuit is electrically connected to a signal input terminal IN, a first clock signal terminal CK1, a second clock signal terminal CK2, a first power supply terminal V1, a second power supply terminal V2, a first node N1, and a second node N2, respectively, and is configured to provide a signal at the signal input terminal IN or the first power supply terminal V1 to the first node N1 and provide a signal at the second power supply terminal V2 or the first clock signal terminal CK1 to the second node N2 under control of signals at the first clock signal terminal CK1 and the second clock signal terminal CK2. The pull-down sub-circuit is electrically connected to the first node N1 and a third power supply terminal V3, respectively, and is configured to provide a signal at the third power supply terminal V3 to the first node N1. The output sub-circuit is electrically connected to the second clock signal terminal CK2, the first power supply terminal V1, the second power supply terminal V2, a first signal output terminal OUT1, the first node N1, and the second node N2, respectively, and is configured to provide a signal at the first power supply terminal V1 or the second clock signal terminal CK2 to the first signal output terminal OUT1 under control of signals at the second power supply terminal V2, the first node N1, and the second node N2.

In an exemplary implementation mode, the first power supply terminal V1 continuously provides a high-level signal, and the second power supply terminal V2 and the third power supply terminal V3 continuously provide low-level signals.

In an exemplary implementation mode, an absolute value of a voltage value of a signal at the third power supply terminal V3 is less than an absolute value of a voltage value of a signal at the second power supply terminal V2. Illustratively, the width of the signal line to which the second power supply terminal V2 is connected is different from the width of the signal line to which the third power supply terminal V3 is connected.

In an exemplary implementation mode, a signal at any one of the first clock signal terminal CK1 and the second clock signal terminal CK2 may be a periodic pulse signal.

In an exemplary implementation mode, the signal at the signal output terminal IN is a single pulse signal.

A shift register unit according to an embodiment of the present disclosure includes a node control sub-circuit, an output sub-circuit, and a pull-down sub-circuit, wherein the node control sub-circuit is electrically connected to a signal input terminal, a first clock signal terminal, a second clock signal terminal, a first power supply terminal, a second power supply terminal, a first node, and a second node, respectively, and is configured to provide a signal at the signal input terminal or the first power supply terminal to the first node and provide a signal at the second power supply terminal or the first clock signal terminal to the second node under control of signals at the first clock signal terminal and the second clock signal terminal. The pull-down sub-circuit is electrically connected to the first node and a third power supply terminal, respectively, and is configured to provide a signal at the third power supply terminal to the first node. The output sub-circuit is electrically connected to the second clock signal terminal, the first power supply terminal, a first signal output terminal, the first node, and the second node, respectively, and is configured to provide a signal at the first power supply terminal or the second clock signal terminal to the first signal output terminal under control of signals at the first node and the second node. An absolute value of a voltage value of a signal at the third power supply terminal is less than an absolute value of a voltage value of a signal at the second power supply terminal. By providing a pull-down sub-circuit, the shift register unit according to the present disclosure can pull down a signal at the first node to a low-level signal with a lower-voltage value, so that some transistors in the shift register unit can be fully turned on, which in turn allows the voltage of the output signal of the shift register unit to reach a predetermined voltage, improves the driving capability of the shift register unit, can ensure the conduction capability of the transistors in the pixel driving circuit, and the performance of the pixel driving circuit and the display effect of the display substrate are improved.

In an exemplary implementation mode, FIG. 2 is an equivalent circuit diagram of a pull-down sub-circuit, and FIG. 3 is an equivalent circuit diagram of another pull-down sub-circuit. As shown in FIGS. 2 and 3, the pull-down sub-circuit may include an eleventh transistor T11. A first electrode of the eleventh transistor T11 is electrically connected to the third power supply terminal V3, and a second electrode of the eleventh transistor T11 is electrically connected to the first node N1.

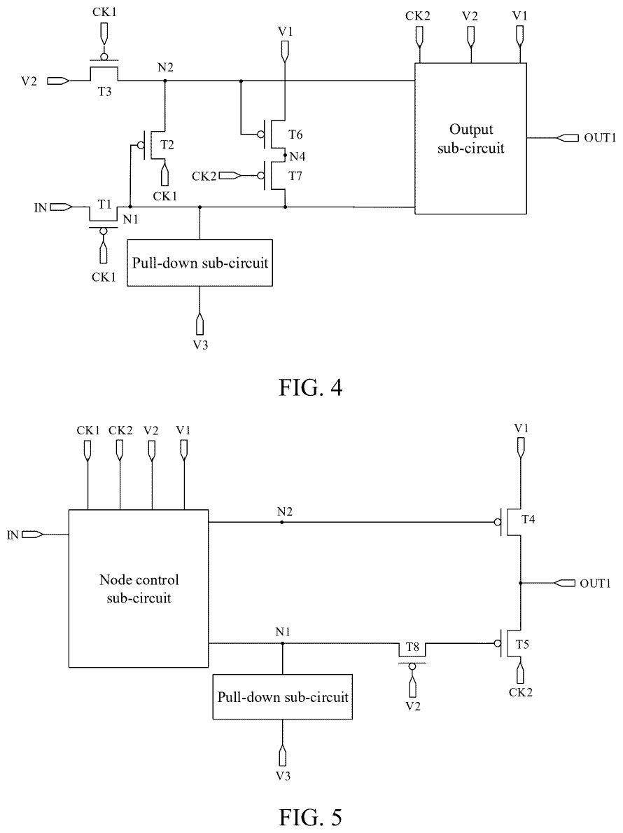

In an exemplary implementation mode, FIG. 4 is an equivalent circuit diagram of a node control sub-circuit. As shown in FIG. 4, the node control sub-circuit may include a first transistor T1, a second transistor T2, a third transistor T3, a sixth transistor T6, and a seventh transistor T7. A control electrode of the first transistor T1 is electrically connected to the first clock signal terminal CK1, a first electrode of the first transistor T1 is connected to the signal input terminal IN, and a second electrode of the first transistor T1 is electrically connected to the first node N1; a control electrode of the second transistor T2 is electrically connected to the first node N1, a first electrode of the second transistor T2 is connected to the first clock signal terminal CK1, and a second electrode of the second transistor T2 is electrically connected to the second node N2; a control electrode of the third transistor T3 is electrically connected to the first clock signal terminal CK1, a first electrode of the third transistor T3 is connected to the second power supply terminal V2, and a second electrode of the third transistor T3 is electrically connected to the second node N2; a control electrode of the sixth transistor T6 is electrically connected to the second node N2, a first electrode of the sixth transistor T6 is connected to the first power supply terminal V1, and a second electrode of the sixth transistor T6 is electrically connected to the fourth node; a control electrode of the seventh transistor T7 is electrically connected to the second clock signal terminal CK2, a first electrode of the seventh transistor T7 is electrically connected to the fourth node, and a second electrode of the seventh transistor T7 is electrically connected to the first node N1.

In an exemplary implementation mode, FIG. 5 is a first equivalent circuit diagram of an output sub-circuit. As shown in FIG. 5, the output sub-circuit may include a fourth transistor T4, a fifth transistor T5, and an eighth transistor T8. A control electrode of the fourth transistor T4 is electrically connected to the second node N2, a first electrode of the fourth transistor T4 is connected to the first power supply terminal V1, and a second electrode of the fourth transistor T4 is electrically connected to the first signal output terminal OUT1; a control electrode of the fifth transistor T5 is electrically connected to the third node N3, a first electrode of the fifth transistor T5 is connected to the second clock signal terminal CK2, and a second electrode of the fifth transistor T5 is electrically connected to the first signal output terminal OUT1; a control electrode of the eighth transistor T8 is electrically connected to the second power supply terminal V2, a first electrode of the eighth transistor T8 is electrically connected to the first node N1, and a second electrode of the eighth transistor T8 is electrically connected to the third node N3.

In an exemplary implementation mode, as shown in FIG. 2, a control electrode of the eleventh transistor T11 may be electrically connected to the first node N1.

In an exemplary implementation mode, as shown in FIG. 3, a control of the eleventh transistor may be electrically connected to the third node N3.

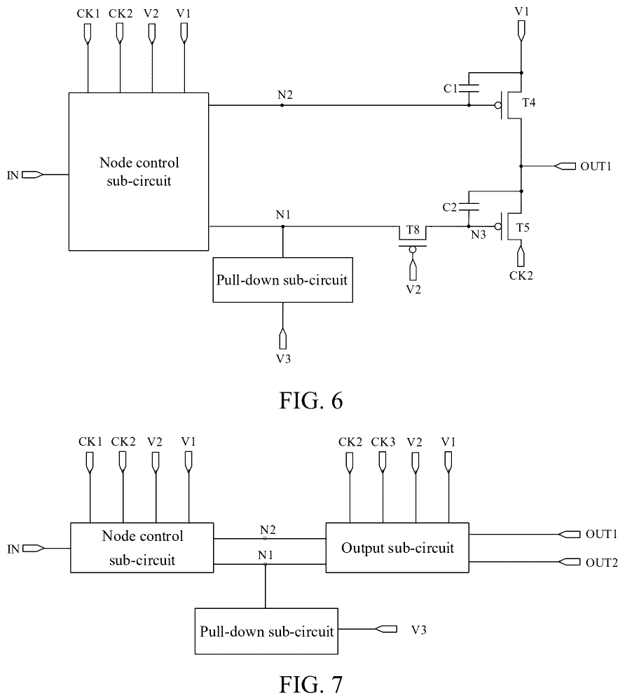

In an exemplary implementation mode, FIG. 6 is a second equivalent circuit diagram of an output sub-circuit. As shown in FIG. 6, the output sub-circuit may include at least one of a first capacitor C1 and a second capacitor C2. A first plate of the first capacitor C1 is electrically connected to the second node N2, and a second plate of the first capacitor C1 is electrically connected to the first power supply terminal V1; a first plate of the second capacitor C2 is electrically connected to the third node, and a second plate of the second capacitor C2 is electrically connected to the first signal output terminal OUT1. FIG. 6 is illustrated by an example in which in which the output sub-circuit further includes the first capacitor C1 and the second capacitor C2.

In an exemplary implementation mode, FIG. 7 is a second schematic structural diagram of a shift register unit according to an embodiment of the present disclosure. As shown in FIG. 7, an output sub-circuit is electrically connected to a second clock signal terminal CK2, a first power supply terminal V1, a first signal output terminal OUT1, a first node N1, a second node N2, a third clock signal terminal CK3, a second power supply terminal V2, and a second signal output terminal OUT2, respectively, and is configured to provide a signal at the first power supply terminal V1 or the second clock signal terminal CK2 to the first signal output terminal OUT1, and to provide a signal at the second power supply terminal V2 or the third clock signal terminal CK3 to the second signal output terminal OUT2 under control of signals at the first node N1 and the second node N2.

In an exemplary implementation mode, signals at the first signal output terminal OUT1 and the second signal output terminal OUT2 are single pulse signals, and the signal at the first signal output terminal OUT1 and the signal at the second signal output terminal OUT2 are mutually inverted signals, that is, when the signal at the first signal output terminal OUT1 is a high-level signal, the signal at the second signal output terminal OUT2 is a low-level signal, and when the signal at the first signal output terminal OUT1 is a low-level signal, the signal at the second signal output terminal OUT2 is a high-level signal.

In an exemplary implementation mode, the first signal output terminal OUT1 is configured to output a cascade signal, which is a low-level signal, and the second signal output terminal OUT2 is configured to output a gate scan signal. Exemplarily, the gate scan signal is a high-level signal or a low-level signal.

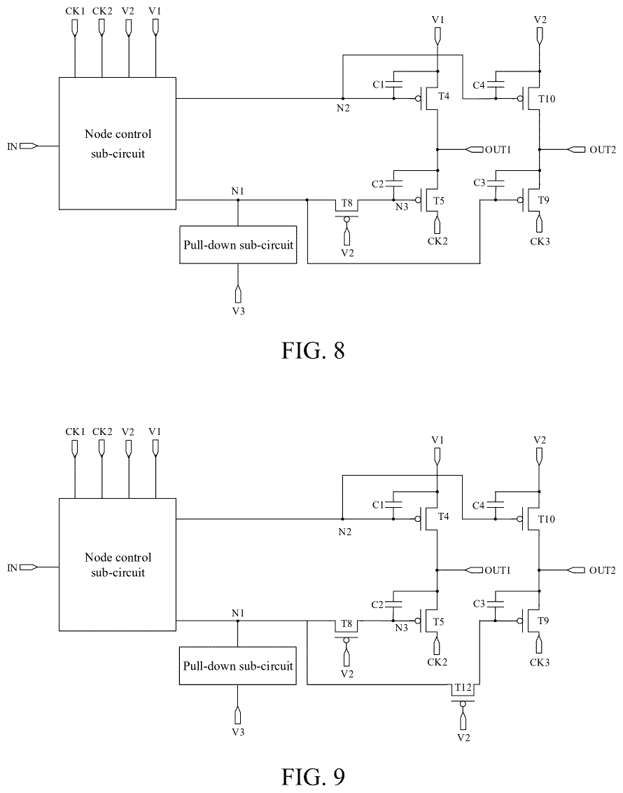

In an exemplary implementation mode, FIG. 8 is a third equivalent circuit diagram of an output sub-circuit. As shown in FIG. 8, the output sub-circuit may include a fourth transistor T4, a fifth transistor T5, an eighth transistor T8, a ninth transistor T9, and a tenth transistor T10. A control electrode of the fourth transistor T4 is electrically connected to the second node N2, a first electrode of the fourth transistor T4 is connected to the first power supply terminal V1, and a second electrode of the fourth transistor T4 is electrically connected to the first signal output terminal OUT1; a control electrode of the fifth transistor T5 is electrically connected to the third node N3, a first electrode of the fifth transistor T5 is connected to the second clock signal terminal CK2, and a second electrode of the fifth transistor T5 is electrically connected to the first signal output terminal OUT1; a control electrode of the eighth transistor T8 is electrically connected to the second power supply terminal V2, a first electrode of the eighth transistor T8 is electrically connected to the first node N1, and a second electrode of the eighth transistor T8 is electrically connected to the third node N3; a control electrode of the ninth transistor T9 is electrically connected to the first node N1, a first electrode of the ninth transistor T9 is connected to the third clock signal terminal CK3, and a second electrode of the ninth transistor T9 is electrically connected to the second signal output terminal OUT2; and a control electrode of the tenth transistor T10 is electrically connected to the second node N2, a first electrode of the tenth transistor T10 is connected to the second power supply terminal V2, and a second electrode of the tenth transistor T10 is electrically connected to the second signal output terminal OUT2.

In an exemplary implementation mode, FIG. 9 is a fourth equivalent circuit diagram of an output sub-circuit. As shown in FIG. 9, the output sub-circuit may include a fourth transistor T4, a fifth transistor T5, an eighth transistor T8, a ninth transistor T9, a tenth transistor T10, and a twelfth transistor T12, and a control electrode of the ninth transistor T9 is electrically connected to the first node N1 through the twelfth transistor T12. A control electrode of the fourth transistor T4 is electrically connected to the second node N2, a first electrode of the fourth transistor T4 is connected to the first power supply terminal V1, and a second electrode of the fourth transistor T4 is electrically connected to the first signal output terminal OUT1; a control electrode of the fifth transistor T5 is electrically connected to the third node N3, a first electrode of the fifth transistor T5 is connected to the second clock signal terminal CK2, and a second electrode of the fifth transistor T5 is electrically connected to the first signal output terminal OUT1; a control electrode of the eighth transistor T8 is electrically connected to the second power supply terminal V2, a first electrode of the eighth transistor T8 is electrically connected to the first node N1, and a second electrode of the eighth transistor T8 is electrically connected to the third node N3; a control electrode of the ninth transistor T9 is electrically connected to the first node N1, a first electrode of the ninth transistor T9 is connected to the third clock signal terminal CK3, and a second electrode of the ninth transistor T9 is electrically connected to the second signal output terminal OUT2; a control electrode of the tenth transistor T10 is electrically connected to the second node N2, a first electrode of the tenth transistor T10 is electrically connected to the second power supply terminal V2, a second electrode of the tenth transistor T10 is electrically connected to the second signal output terminal OUT2, a control electrode of the twelfth transistor T12 is electrically connected to the second power supply terminal V2, a first electrode of the twelfth transistor T12 is electrically connected to the first node N1, and a second electrode of the twelfth transistor T12 is electrically connected to the control electrode of the ninth transistor T9.

In an exemplary implementation mode, the twelfth transistor T12 is a transistor that is continuously turned on, which can ensure that a signal at the control electrode of the ninth transistor T9 is stable, avoid a large deviation of an output signal of the shift register unit, and can ensure the stability of the output signal of the shift register unit.

In an exemplary implementation mode, as shown in FIGS. 8 and 9, the output sub-circuit may further include at least one of a first capacitor C1, a second capacitor C2, a third capacitor C3, and a fourth capacitor C4.

In an exemplary implementation mode, as shown in FIGS. 8 and 9, a first plate of the first capacitor C1 is electrically connected to the second node N2, and a second plate of the first capacitor C1 is electrically connected to the first power supply terminal V1; a first plate of the second capacitor C2 is electrically connected to the third node N3, and a second plate of the second capacitor C2 is connected to the first signal output terminal OUT1; a first plate of the third capacitor C3 is electrically connected to a control electrode of the ninth transistor T9, and a second plate of the third capacitor C3 is connected to the second signal output terminal OUT2; a first plate of the fourth capacitor C4 is electrically connected to the second node N2, and a second plate of the fourth capacitor C4 is connected to the second power supply terminal V2.

In an exemplary implementation mode, the output sub-circuit may include a second capacitor C2 and a fourth capacitor C4, or may include a second capacitor C2, or may include a first capacitor C1 and a third capacitor C3, or may include a third capacitor C3, or may include a first capacitor C1, a second capacitor C2, a third capacitor C3, and a fourth capacitor C4. FIGS. 8 and 9 are illustrated by an example in which the output sub-circuit includes a first capacitor C1, a second capacitor C2, a third capacitor C3, and a fourth capacitor C4. The first capacitor C1 can ensure the stability of the second node N2, the second capacitor C2 can ensure the voltage difference between signals at the third node N3 and the first signal output terminal OUT1, the third capacitor can ensure the voltage difference between signals at the first node N1 and the second signal output terminal OUT2, and the fourth capacitor C4 can ensure the stability of a signal at the second node N2.

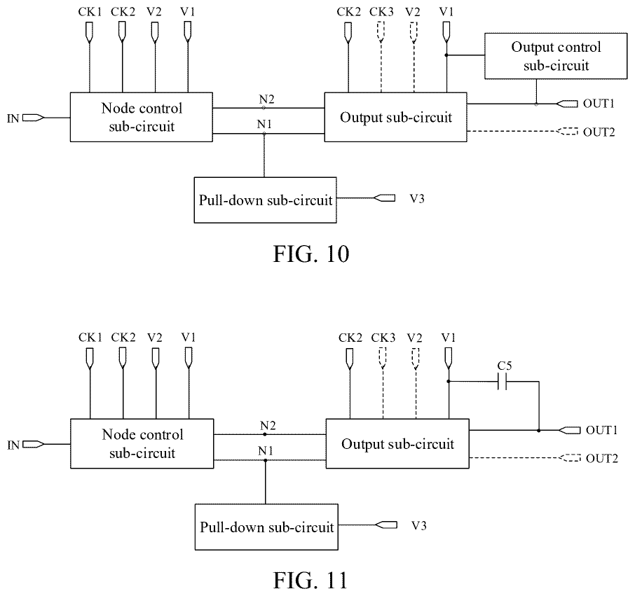

In an exemplary implementation mode, FIG. 10 is a third schematic structural diagram of a shift register unit according to an embodiment of the present disclosure. As shown in FIG. 10, the shift register unit may further include an output control sub-circuit. The output control sub-circuit electrically is connected to the first power supply terminal V1 and the first signal output terminal OUT1, respectively, is configured to store a voltage difference between signals at the first signal output terminal OUT1 and the first power supply terminal V1. The output sub-circuit of the shift register unit in FIG. 10 may be electrically connected to the second clock signal terminal CK2, the first power supply terminal V1, the first node N1, the second node N2, and the first signal output terminal OUT1, or may be electrically connected to the second clock signal terminal CK2, the third clock signal line CK3, the first power supply terminal V1, the second power supply terminal V2, the first node N1, the second node N2, the first signal output terminal OUT1, and the second signal output terminal OUT2.

In the present disclosure, since the signal output by the first signal output terminal OUT1 is a cascade signal, that is, the signal line connected to the first signal output terminal OUT1 does not flow through the display region where the pixel driving circuit is located, that is, the load of the signal line connected to the first signal output terminal OUT1 is small, a signal at the first signal output terminal OUT1 is susceptible to being affected by the parasitic capacitance of some transistors in the output sub-circuit, thereby causing fluctuation in the signal at the first signal output terminal OUT1. The present disclosure can make the signal output from the first signal output terminal OUT1 relatively stable by providing the output control sub-circuit, which improves performance of the shift register unit.

In an exemplary implementation mode, FIG. 11 is an equivalent circuit diagram of an output control sub-circuit. As shown in FIG. 11, in an exemplary embodiment, the output control sub-circuit includes a fifth capacitor C5. A first plate of the fifth capacitor C5 is electrically connected to the first power supply terminal V1, and a second electrode of the fifth capacitor C5 is electrically connected to the first signal output terminal OUT1.

In an exemplary implementation mode, a dotted line in FIGS. 10 and 11 indicate that a connection may be made, or may not be made.

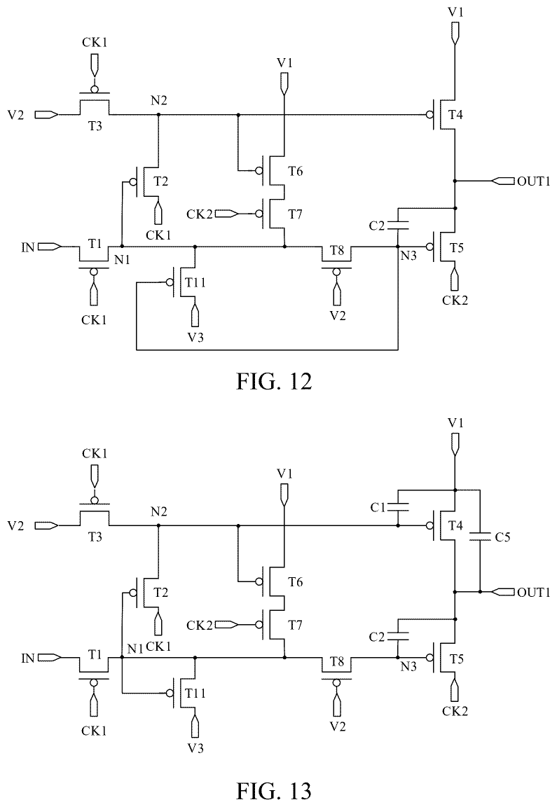

In an exemplary implementation mode, FIG. 12 is a first equivalent circuit diagram of a shift register unit, and FIG. 13 is a second equivalent circuit diagram of a shift register unit. As shown in FIGS. 12 and 13, the shift register unit may further output a control sub-circuit, wherein a node control sub-circuit includes a first transistor T1, a second transistor T2, a third transistor T3, a sixth transistor T6, and a seventh transistor T7, the output sub-circuit includes a fourth transistor T4, a fifth transistor T5, an eighth transistor T8, and at least one of a first capacitor C1 and a second capacitor C2, the pull-down sub-circuit includes an eleventh transistor T11, and the output control sub-circuit includes a fifth capacitor C5. Herein, FIG. 12 is illustrated by an example in which the shift register unit includes a second capacitor C2, and FIG. 13 is illustrated by an example in which the shift register unit includes a first capacitor C1 and a second capacitor C2. FIG. 12 is illustrated by an example in which a control electrode of the eleventh transistor is electrically connected to the third node N3, and FIG. 13 is illustrated by an example in which a control electrode of the eleventh transistor is electrically connected to the first node N1.

In an exemplary implementation mode, as shown in FIGS. 12 and 13, a control electrode of the first transistor T1 is electrically connected to the first clock signal terminal CK1, a first electrode of the first transistor T1 is electrically connected to the signal input terminal IN, and a second electrode of the first transistor T1 is electrically connected to the first node N1; a control electrode of the second transistor T2 is electrically connected to the first node N1, a first electrode of the second transistor T2 is connected to the first clock signal terminal CK1, and a second electrode of the second transistor T2 is electrically connected to the second node N2; a control electrode of the third transistor T3 is electrically connected to the first clock signal terminal CK1, a first electrode of the third transistor T3 is connected to the second power supply terminal V2, and a second electrode of the third transistor T3 is electrically connected to the second node N2; a control electrode of the fourth transistor T4 is electrically connected to the second node N2, a first electrode of the fourth transistor T4 is connected to the first power supply terminal V1, and a second electrode of the fourth transistor T4 is electrically connected to the first signal output terminal OUT1; a control electrode of the fifth transistor T5 is electrically connected to the third node N3, a first electrode of the fifth transistor T5 is connected to the second clock signal terminal CK2, and a second electrode of the fifth transistor T5 is electrically connected to the first signal output terminal OUT1; a control electrode of the sixth transistor T6 is electrically connected to the second node N2, a first electrode of the sixth transistor T6 is connected to the first power supply terminal V1, and a second electrode of the sixth transistor T6 is electrically connected to the fourth node; a control electrode of the seventh transistor T7 is electrically connected to the second clock signal terminal CK2, a first electrode of the seventh transistor T7 is connected to the fourth node, and a second electrode of the seventh transistor T7 is electrically connected to the first node N1; a control electrode of the eighth transistor T8 is electrically connected to the second power supply terminal V2, a first electrode of the eighth transistor T8 is electrically connected to the first node N1, and a second electrode of the eighth transistor T8 is electrically connected to the third node N3; a control electrode of the eleventh transistor T11 is electrically connected to the first node N1 or the third node N3, a first electrode of the eleventh transistor T11 is electrically connected to the third power supply terminal V3, and a second electrode of the eleventh transistor T11 is electrically connected to the first node N1; a first plate of the first capacitor C1 is electrically connected to the second node N2, and a second plate of the first capacitor C1 is electrically connected to the first power supply terminal V1; a first plate of the second capacitor C2 is electrically connected to the third node N3, and a second plate of the second capacitor C2 is connected to the first signal output terminal OUT1; a first plate of the fifth capacitor C5 is electrically connected to the first power supply terminal V1, and a second electrode of the fifth capacitor C5 is electrically connected to the first signal output terminal OUT1. FIG. 12 is illustrated by an example in which a control electrode of the eleventh transistor T11 is electrically connected to the third node N3, and FIG. 13 is illustrated by an example in which a control electrode of the eleventh transistor T11 is electrically connected to the first node N1.

In an exemplary implementation mode, transistors may be divided into N type transistors and P type transistors according to characteristics of the transistors. When a transistor is a P-type transistor, its turn-on voltage is a low-level voltage (e.g., 0V, −5 V, −10 V, or another suitable voltage), and its turn-off voltage is a high-level voltage (e.g., 5 V, 10 V, or another suitable voltage). When a transistor is an N-type transistor, its turn-on voltage is a high-level voltage (e.g., 5 V, 10 V, or another suitable voltage), and its turn-off voltage is a low-level voltage (e.g., 0 V, −5 V, −10 V, or another suitable voltage).

In an exemplary implementation mode, the first transistor T1 to the eighth transistor T8 and the eleventh transistor T11 may all be P-type transistors.

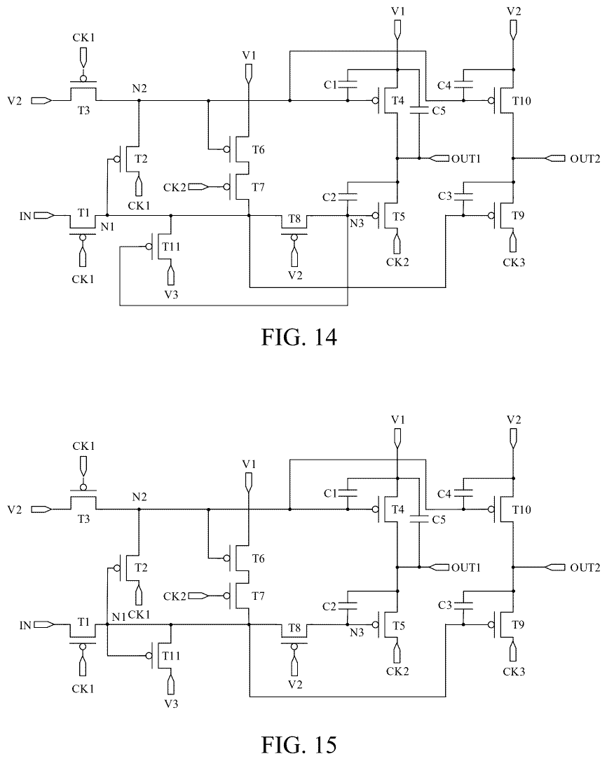

In an exemplary implementation mode, FIG. 14 is a third equivalent circuit diagram of a shift register unit, and FIG. 15 is a fourth equivalent circuit diagram of a shift register unit. As shown in FIGS. 14 and 15, the shift register unit further includes an output control sub-circuit, the node control sub-circuit includes a first transistor T1, a second transistor T2, a third transistor T3, a sixth transistor T6, and a seventh transistor T7, the output sub-circuit includes a fourth transistor T4, a fifth transistor T5, an eighth transistor T8, a ninth transistor T9, and a tenth transistor T10, and at least one of a first capacitor C1, a second capacitor C2, a third capacitor C3, and a fourth capacitor C4, the pull-down sub-circuit includes an eleventh transistor T11, the output control sub-circuit includes a fifth capacitor C5. FIGS. 14 and 15 are illustrated by an example in which the shift register unit includes a first capacitor C1, a second capacitor C2, a third capacitor C3, and a fourth capacitor C4. FIG. 14 is illustrated by an example in which a control electrode of the eleventh transistor is electrically connected to the third node N3, and FIG. 15 is illustrated by an example in which a control electrode of the eleventh transistor is electrically connected to the first node N1.

In an exemplary implementation mode, as shown in FIGS. 14 and 15, a control electrode of the first transistor T1 is electrically connected to the first clock signal terminal CK1, a first electrode of the first transistor T1 is electrically connected to the signal input terminal IN, and a second electrode of the first transistor T1 is electrically connected to the first node N1; a control electrode of the second transistor T2 is electrically connected to the first node N1, a first electrode of the second transistor T2 is connected to the first clock signal terminal CK1, and a second electrode of the second transistor T2 is electrically connected to the second node N2; a control electrode of the third transistor T3 is electrically connected to the first clock signal terminal CK1, a first electrode of the third transistor T3 is connected to the second power supply terminal V2, and a second electrode of the third transistor T3 is electrically connected to the second node N2; a control electrode of the fourth transistor T4 is electrically connected to the second node N2, a first electrode of the fourth transistor T4 is connected to the first power supply terminal V1, and a second electrode of the fourth transistor T4 is electrically connected to the first signal output terminal OUT1; a control electrode of the fifth transistor T5 is electrically connected to the third node N3, a first electrode of the fifth transistor T5 is connected to the second clock signal terminal CK2, and a second electrode of the fifth transistor T5 is electrically connected to the first signal output terminal OUT1; a control electrode of the sixth transistor T6 is electrically connected to the second node N2, a first electrode of the sixth transistor T6 is connected to the first power supply terminal V1, and a second electrode of the sixth transistor T6 is electrically connected to the fourth node; a control electrode of the seventh transistor T7 is electrically connected to the second clock signal terminal CK2, a first electrode of the seventh transistor T7 is connected to the fourth node, and a second electrode of the seventh transistor T7 is electrically connected to the first node N1; a control electrode of the eighth transistor T8 is electrically connected to the second power supply terminal V2, a first electrode of the eighth transistor T8 is electrically connected to the first node N1, and a second electrode of the eighth transistor T8 is electrically connected to the third node N3; a control electrode of the ninth transistor T9 is electrically connected to the first node N1, a first electrode of the ninth transistor T9 is connected to the third clock signal terminal CK3, and a second electrode of the ninth transistor T9 is electrically connected to the second signal output terminal OUT2; a control electrode of the tenth transistor T10 is electrically connected to the second node N2, a first electrode of the tenth transistor T10 is connected to the second power supply terminal V2, and a second electrode of the tenth transistor T10 is electrically connected to the second signal output terminal OUT2; a control electrode of the eleventh transistor T11 is electrically connected to the first node N1 or the third node N3, a first electrode of the eleventh transistor T11 is electrically connected to the third power supply terminal V3, and a second electrode of the eleventh transistor T11 is electrically connected to the first node N1; a first plate of the first capacitor C1 is electrically connected to the second node N2, and a second plate of the first capacitor C1 is electrically connected to the first power supply terminal V1; a first plate of the second capacitor C2 is electrically connected to the third node N3, and a second plate of the second capacitor C2 is connected to the first signal output terminal OUT1; a first plate of the third capacitor C3 is electrically connected to a control electrode of the ninth transistor T9, and a second plate of the third capacitor C3 is connected to the second signal output terminal OUT2; a first plate of the fourth capacitor C4 is electrically connected to the second node N2, and a second plate of the fourth capacitor C4 is connected to the second power supply terminal V2; a first plate of the fifth capacitor C5 is electrically connected to the first power supply terminal V1, and a second electrode of the fifth capacitor C5 is electrically connected to the first signal output terminal OUT1. FIG. 14 is illustrated by an example in which a control electrode of the eleventh transistor T11 is electrically connected to the third node N3, and FIG. 15 is illustrated by an example in which a control electrode of the eleventh transistor T11 is electrically connected to the first node N1.

In an exemplary implementation mode, the first transistor T1 to the eleventh transistor T11 may all be P-type transistors.

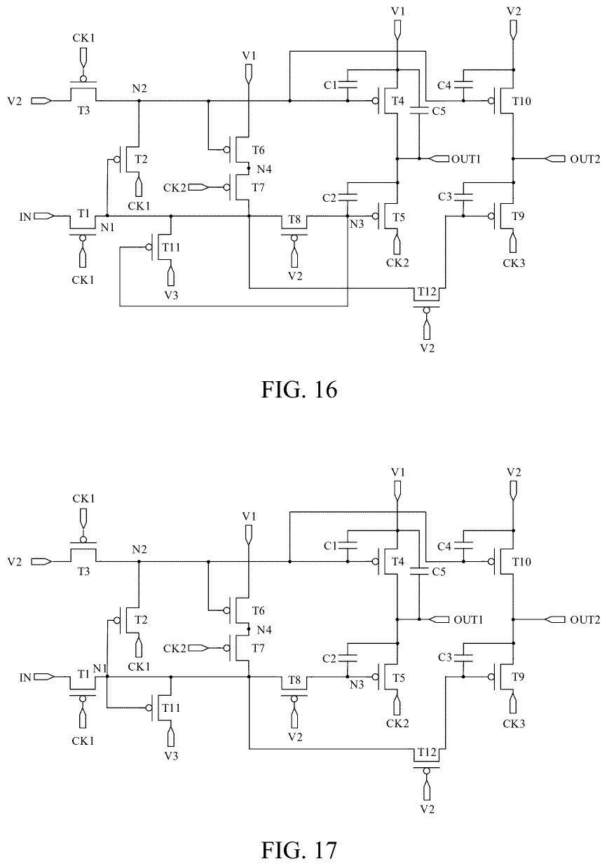

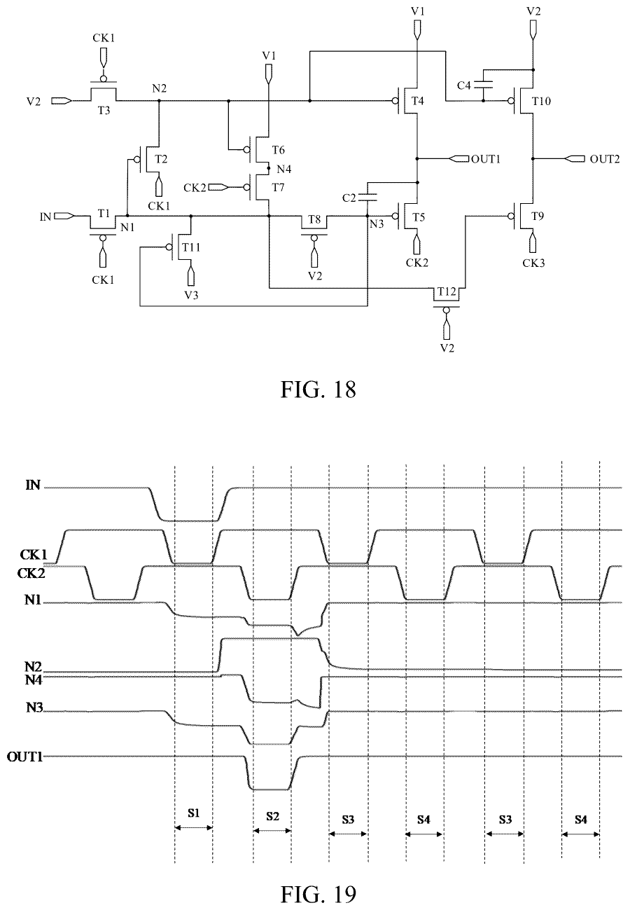

In an exemplary implementation mode, FIG. 16 is a fifth equivalent circuit diagram of a shift register unit, FIG. 17 is a sixth equivalent circuit diagram of a shift register unit, and FIG. 18 is a seventh equivalent circuit diagram of a shift register unit. As shown in FIGS. 16 to 18, an output control sub-circuit is also included, the node control sub-circuit includes a first transistor T1, a second transistor T2, a third transistor T3, a sixth transistor T6, and a seventh transistor T7, the output sub-circuit includes a fourth transistor T4, a fifth transistor T5, an eighth transistor T8, a ninth transistor T9, a tenth transistor T10, a twelfth transistor T12, and at least one of a first capacitor C1, a second capacitor C2, a third capacitor C3, and a fourth capacitor C4, the pull-down sub-circuit includes an eleventh transistor T11, the output control sub-circuit includes a fifth capacitor C5. FIGS. 16 and 17 are illustrated by an example in which the shift register unit includes a first capacitor C1, a second capacitor C2, a third capacitor C3, and a fourth capacitor C4, and FIG. 18 is illustrated by an example in which the shift register unit includes a second capacitor C2 and a fourth capacitor C4. FIGS. 16 and 18 are illustrated by an example in which a control electrode of the eleventh transistor T11 is electrically connected to the third node N3, and FIG. 17 is illustrated by an example in which a control electrode of the eleventh transistor T11 is electrically connected to the first node N1.

In an exemplary implementation mode, as shown in FIGS. 16 to 18, a control electrode of the first transistor T1 is electrically connected to the first clock signal terminal CK1, a first electrode of the first transistor T1 is connected to the signal input terminal IN, and a second electrode of the first transistor T1 is electrically connected to the first node N1; a control electrode of the second transistor T2 is electrically connected to the first node N1, a first electrode of the second transistor T2 is connected to the first clock signal terminal CK1, and a second electrode of the second transistor T2 is electrically connected to the second node N2; a control electrode of the third transistor T3 is electrically connected to the first clock signal terminal CK1, a first electrode of the third transistor T3 is connected to the second power supply terminal V2, and a second electrode of the third transistor T3 is electrically connected to the second node N2; a control electrode of the fourth transistor T4 is electrically connected to the second node N2, a first electrode of the fourth transistor T4 is connected to the first power supply terminal V1, and a second electrode of the fourth transistor T4 is electrically connected to the first signal output terminal OUT1; a control electrode of the fifth transistor T5 is electrically connected to the third node N3, a first electrode of the fifth transistor T5 is connected to the second clock signal terminal CK2, and a second electrode of the fifth transistor T5 is electrically connected to the first signal output terminal OUT1; a control electrode of the sixth transistor T6 is electrically connected to the second node N2, a first electrode of the sixth transistor T6 is connected to the first power supply terminal V1, and a second electrode of the sixth transistor T6 is electrically connected to the fourth node; a control electrode of the seventh transistor T7 is electrically connected to the second clock signal terminal CK2, a first electrode of the seventh transistor T7 is connected to the fourth node, and a second electrode of the seventh transistor T7 is electrically connected to the first node N1; a control electrode of the eighth transistor T8 is electrically connected to the second power supply terminal V2, a first electrode of the eighth transistor T8 is electrically connected to the first node N1, and a second electrode of the eighth transistor T8 is electrically connected to the third node N3; a control electrode of the ninth transistor T9 is electrically connected to a second electrode of the twelfth transistor T12, a first electrode of the ninth transistor T9 is connected to the third clock signal terminal CK3, and a second electrode of the ninth transistor T9 is electrically connected to the second signal output terminal OUT2; a control electrode of the tenth transistor T10 is electrically connected to the second node N2, a first electrode of the tenth transistor T10 is connected to the second power supply terminal V2, and a second electrode of the tenth transistor T10 is electrically connected to the second signal output terminal OUT2; a control electrode of the eleventh transistor T11 is electrically connected to the first node N1 or the third node N3, a first electrode of the eleventh transistor T11 is electrically connected to the third power supply terminal V3, and a second electrode of the eleventh transistor T11 is electrically connected to the first node N1; a control electrode of the twelfth transistor T12 is electrically connected to the second power supply line, and a first electrode of the twelfth transistor T12 is electrically connected to the first node N1; a first plate of the first capacitor C1 is electrically connected to the second node N2, and a second plate of the first capacitor C1 is electrically connected to the first power supply terminal VGH; a first plate of the second capacitor C2 is electrically connected to the third node N3, and a second plate of the second capacitor C2 is connected to the first signal output terminal OUT1; a first plate of the third capacitor C3 is electrically connected to a control electrode of the ninth transistor T9, and a second plate of the third capacitor C3 is connected to the second signal output terminal OUT2; a first plate of the fourth capacitor C4 is electrically connected to the second node N2, and a second plate of the fourth capacitor C4 is connected to the second power supply terminal V2; and a first plate of the fifth capacitor C5 is electrically connected to the first power supply terminal V1, and a second electrode of the fifth capacitor C5 is electrically connected to the first signal output terminal OUT1.

In an exemplary implementation mode, the first transistor T1 to the eleventh transistor T11 may all be P-type transistors.

In an exemplary implementation mode, a signal at the first clock signal terminal CK1 and a signal at the second clock signal terminal CK2 are not simultaneously effective level signals. For example, when the signal at the first clock signal terminal CK1 is an effective level signal, the signal at the second clock signal terminal CK2 is an ineffective level signal, and when the signal at the second clock signal terminal CK2 is an effective level signal, the signal at the first clock signal terminal CK1 is an ineffective level signal.

In an exemplary implementation mode, a signal at the third clock signal terminal CK3 and a signal at the second clock signal terminal CK2 may or may not be mutually inverted signals. When the signal at the third clock signal terminal CK3 and the signal at the second clock signal terminal CK2 are mutually inverted signals, when the signal at the third clock signal terminal CK3 is an effective level signal, the signal at the second clock signal terminal CK2 is an ineffective level signal, and when the signal at the third clock signal terminal CK3 is an ineffective level signal, the signal at the second clock signal terminal CK2 is an effective level signal.

In an exemplary implementation mode, signals at the first signal output terminal OUT1 and the second signal output terminal OUT2 are mutually inverted signals.

FIG. 19 is a signal timing simulation diagram of the shift register unit provided in FIGS. 12 and 13. FIG. 19 is illustrated by an example in which all transistors in the shift register unit are A P-type transistors.

In an exemplary implementation mode, for the shift register unit provided in FIGS. 12 and 13, since the control electrode of the eighth transistor T8 is electrically connected to the second power supply terminal V2, the eighth transistor T8 is continuously turned on.

In conjunction with what shown in FIGS. 12 and 19, a working process of the control shift register unit provided in FIG. 12 includes the following stages.

In a first stage S1, that is, an input stage, signals at the signal input terminal IN and the first clock signal terminal CK1 are low-level signals, and a signal at the second clock signal terminal GCK2 is a high-level signal. The signal at the first clock signal terminal CK1 is a low-level signal, the first transistor T1 and the third transistor T3 are turned on, a low-level signal at the signal input terminal IN is written to the first node N1, and a low-level signal at the second power supply terminal V2 is written to the second node N2. Since the eighth transistor T8 is continuously turned on, both a signal at the third node N3 and a signal at the first node N1 are both low-level signals. The signal at the first node N1 is a low-level signal, the second transistor T2 is turned on, and a low-level signal at the first clock signal terminal CK1 is written to the second node N2 to ensure that a signal at the second node N2 is continuously a low-level signal. The signal at the second node N2 is a low-level signal, the fourth transistor T4 and the sixth transistor T6 are turned on, a high-level signal at the first power supply terminal V1 is written to the first signal output terminal OUT1 and the fourth node N4, and the low-level signal at the second power supply terminal V2 is written to the second signal output terminal OUT2. The signal at the third node N3 is a low-level signal, the fifth transistor T5 and the eleventh transistor T11 are turned on, a signal at the third power supply terminal V3 is written to the first node N1, which further pulls down the level of the signal at the first node N1, so that the signal at the first node N1 is continuously a low-level signal. Since a signal at the second clock signal terminal CK2 is a high-level signal, the seventh transistor T7 is turned off, a high-level signal at the fourth node N4 will not be written to the first node N1, and the signal at the first node N1 will not be pulled up. In this stage, signals at the first node N1, the second node N2, and the third node N3 are low-level signals, a signal at the fourth node N4 is a high-level signal, a signal at the first power supply terminal V1 is written to the first signal output terminal OUT1, and a signal output by the first signal output terminal OUT1 is a high-level signal.

In a second stage S2, that is, an output stage, signals at the signal input terminal IN and the first clock signal terminal CK1 are high-level signals, and a signal at the second clock signal terminal GCK2 is a low-level signal. The signal at the first clock signal terminal CK1 is a high-level signal, the first transistor T1 and the third transistor T3 are turned off, and a signal at the first node N1 remains a low-level signal. Since the eighth transistor T8 is continuously turned on, both a signal at the third node N3 and a signal at the first node N1 are low-level signals. The signal at the first node N1 is a low-level signal, the second transistor T2 is turned on, a high-level signal at the first clock signal terminal CK1 is written to the second node N2, a signal at the second node N2 is a high-level signal, a signal at the second node N2 is a high-level signal, the fourth transistor T4 and the sixth transistor T6 are turned off, and a high-level signal at the first power supply terminal V1 cannot be written to the first signal output terminal OUT1. The signal at the third node N3 is a low-level signal, the fifth transistor T5 and the eleventh transistor T11 are turned on, a signal at the third power supply terminal V3 is written to the first node N1, a signal at the first node N1 is kept as a low-level signal continuously, and a low-level signal at the second clock signal terminal CK2 is written to the first signal output terminal OUT1. Since the signal at the second clock signal terminal CK2 is a low-level signal, the seventh transistor T7 is turned on, and a signal at the fourth node N4 is pulled down by the signal at the first node N1, and a signal at the fourth node N4 is a low-level signal. In this stage, signals at the first node N1, the third node N3, and the fourth node N4 are low-level signals, a signal at the second node N2 is a high-level signal, a low-level signal at the second clock signal terminal CK2 is written to the first signal output terminal OUT1, and a signal output by the first signal output terminal OUT1 is a low-level signal.

In a third stage S3, signals at the signal input terminal IN and the second clock signal terminal GCK2 are high-level signals, and a signal at the first clock signal terminal CK1 is a low-level signal. The signal at the first clock signal terminal CK1 is a low-level signal, the first transistor T1 and the third transistor T3 are turned on, a high-level signal at the signal input terminal IN is written to the first node N1, and a low-level signal at the second power supply terminal V2 is written to the second node N2. Since the eighth transistor T8 is continuously turned on, both a signal at the third node N3 and a signal at the first node N1 are high-level signals. The signal at the first node N1 is a high-level signal, and the second transistor T2 is turned off. A signal at the second node N2 is a low-level signal, the fourth transistor T4 and the sixth transistor T6 are turned on, and a high-level signal at the first power supply terminal V1 is written to the first signal output terminal OUT1 and the fourth node N4. A signal at the third node N3 is a high-level signal, the fifth transistor T5 and the eleventh transistor T11 are turned off, a signal at the third power supply terminal V3 cannot be written to the first node N1, the signal at the first node N1 is kept as a high-level signal, and a high-level signal at the second clock signal terminal CK2 cannot be written to the first signal output terminal OUT1. As the signal at the second clock signal terminal CK2 is the high-level signal, the seventh transistor T7 is turned off. In this stage, the signal at the second node N2 is a low-level signal, signals at the first node N1, the third node N3, and the fourth node N4 are high-level signals, a signal at the first power supply terminal V1 is written to the first signal output terminal OUT1, and a signal output by the first signal output terminal OUT1 is a high-level signal.

In a second stage S4, signals at the signal input terminal IN and the first clock signal terminal CK1 are high-level signals, and the signal at the second clock signal terminal CK2 is a low-level signal. A signal at the first clock signal terminal CK1 is a high-level signal, the first transistor T1 and the third transistor T3 are turned off, and a signal at the first node N1 remains a high-level signal. Since the eighth transistor T8 is continuously turned on, both a signal at the third node N3 and a signal at the first node N1 are high-level signals. The signal at the first node N1 is a high-level signal, and the second transistor T2 is turned off. A signal at the second node N2 is continuously a low-level signal, the fourth transistor T4 and the sixth transistor T6 are turned on, and a high-level signal at the first power supply terminal V1 is written to the first signal output terminal OUT1 and the fourth node N4. The signal at the third node N3 is a high-level signal, the fifth transistor T5 and the eleventh transistor T11 are turned off, a signal at the third power supply terminal V3 cannot be written to the first node N1, a signal at the first node N1 is kept as a high-level signal, and the high-level signal at the second clock signal terminal CK2 cannot be written to the first signal output terminal OUT1. As the signal at the second clock signal terminal CK2 is the high-level signal, the seventh transistor T7 is turned off. In this stage, the signal at the second node N2 is a low-level signal, signals at the first node N1, the third node N3, and the fourth node N4 are high-level signals, a signal at the first power supply terminal V1 is written to the first signal output terminal OUT1, and a signal output by the first signal output terminal OUT1 is a high-level signal.

The working process of the shift register unit further includes a plurality of third stages S3 and fourth stages S4, with the third stages S3 and the fourth stages S4 operating alternately.

The shift register unit provided in FIG. 13 is different from the shift register unit provided in FIG. 12 in that the node connected to the control electrode of the eleventh transistor is different. FIG. 12 is illustrated by an example in which the control electrode of the eleventh transistor is connected to the third node, and FIG. 13 is illustrated by an example in which the control electrode of the eleventh transistor is connected to the first node. Since signals at the first node N1 and the third node N3 are simultaneously high-level signals or low-level signals, that is, the eleventh transistors in the shift register unit provided in FIGS. 12 and 13 are simultaneously turned on or off, the working process of the shift register unit provided in FIG. 13 is the same as that of the shift register unit provided in FIG. 12.

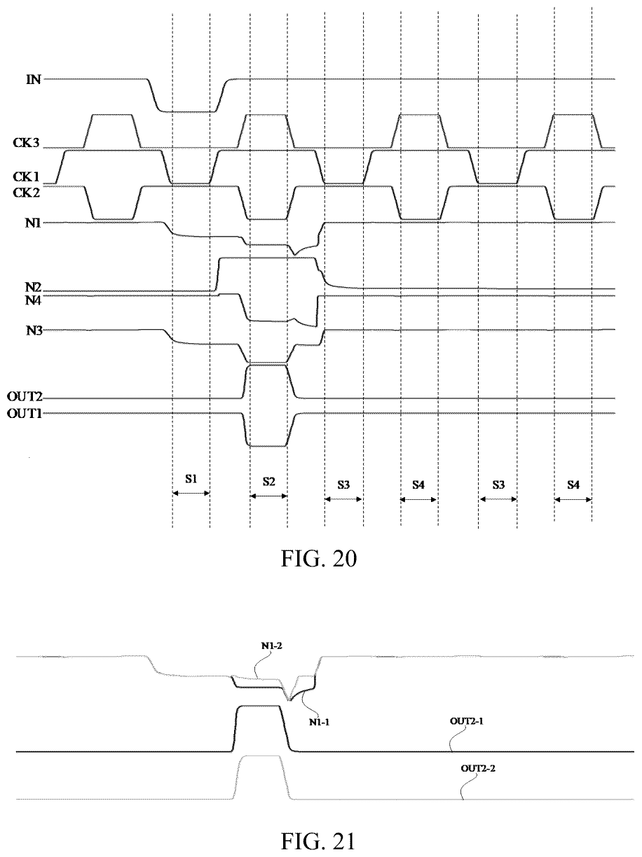

FIG. 20 is a signal timing simulation diagram of the shift register provided in FIG. 14 to FIG. 18. FIG. 20 is illustrated by an example in which all transistors in the shift register are all P-type transistors.

In an exemplary implementation mode, for the shift register unit provided in FIGS. 14 and 15, since a control electrode of the eighth transistor T8 is electrically connected to the second power supply terminal V2, the eighth transistor T8 is continuously turned on. For the shift register units provided in FIGS. 16 to 18, control electrodes of both the eighth transistor T8 and the twelve transistor T12 are electrically connected to the second power supply terminal V2, and the eighth transistor T8 and the twelve transistor T12 are continuously turned on.

In conjunction with what shown in FIGS. 14 and 20, a working process of the control shift register unit provided in FIG. 14 includes the following stages.

In a first stage S1, that is, an input stage, signals at the signal input terminal IN, the first clock signal terminal CK1 and the third clock signal terminal CK3 are low-level signals, and a signal at the second clock signal terminal GCK2 is a high-level signal. The signal at the first clock signal terminal CK1 is a low-level signal, the first transistor T1 and the third transistor T3 are turned on, the low-level signal at the signal input terminal IN is written to the first node N1, and the low-level signal at the second power supply terminal V2 is written to the second node N2. Since the eighth transistor T8 is continuously turned on, both a signal at the third node N3 and a signal at the first node N1 are both low-level signals. The signal at the first node N1 is a low-level signal, the second transistor T2 and the ninth transistor T9 are turned on, the low-level signal at the first clock signal terminal CK1 is written to the second node N2 to ensure that the signal at the second node N2 is continuously a low-level signal, and a low-level signal at the third clock signal terminal CK3 is written to the second signal output terminal OUT2. A signal at the second node N2 is a low-level signal, the fourth transistor T4, the sixth transistor T6, and the tenth transistor T10 are turned on, the high-level signal at the first power supply terminal V1 is written to the first signal output terminal OUT1 and the fourth node N4, and the low-level signal at the second power supply terminal V2 is written to the second signal output terminal OUT2. The signal at the third node N3 is a low-level signal, the fifth transistor T5 and the eleventh transistor T11 are turned on, a signal at the third power supply terminal V3 is written to the first node N1, which further pulls down the level of the signal at the first node N1, so that the signal at the first node N1 is continuously a low-level signal. Since the signal at the second clock signal terminal CK2 is a high-level signal, the seventh transistor T7 is turned off, the high-level signal at the fourth node N4 will not be written to the first node N1, and the signal at the first node N1 will not be pulled up. In this stage, signals at the first node N1, the second node N2, and the third node N3 are low-level signals, the signal at the fourth node N4 is a high-level signal, the signal at the first power supply terminal V1 is written to the first signal output terminal OUT1, a signal output by the first signal output terminal OUT1 is a high-level signal, the signal at the third clock signal terminal CK3 and the signal at the second power supply terminal V2 are written to the second signal output terminal OUT2, and a signal output by the second signal output terminal OUT2 is a low-level signal.

In a second stage S2, that is, an output stage, signals at the signal input terminal IN, the first clock signal terminal CK1 and the third clock signal terminal CK3 are high-level signals, and a signal at the second clock signal terminal GCK2 is a low-level signal. The signal at the first clock signal terminal CK1 is a high-level signal, the first transistor T1 and the third transistor T3 are turned off, and a signal at the first node N1 remains a low-level signal. Since the eighth transistor T8 is continuously turned on, both a signal at the third node N3 and a signal at the first node N1 are low-level signals. The signal at the first node N1 is a low-level signal, the second transistor T2 and the ninth transistor T9 are turned on, a high-level signal at the first clock signal terminal CK1 is written to the second node N2, a signal at the second node N2 is a high-level signal, a high-level signal at the third clock signal terminal CK3 is written to the second signal output terminal OUT2, a signal at the second node N2 is a high-level signal, the fourth transistor T4, the sixth transistor T6, and the tenth transistor T10 are turned off, a high-level signal at the first power supply terminal V1 cannot be written to the first signal output terminal OUT1, and a low-level signal at a first low-level signal terminal VGL1 cannot be written to the second signal output terminal OUT2. The signal at the third node N3 is a low-level signal, the fifth transistor T5 and the eleventh transistor T11 are turned on, a signal at the third power supply terminal V3 is written to the first node N1, the signal at the first node N1 is kept as a low-level signal continuously, and the low-level signal at the second clock signal terminal CK2 is written to the first signal output terminal OUT1. Since the signal at the second clock signal terminal CK2 is a low-level signal, the seventh transistor T7 is turned on, and a signal at the fourth node N4 is pulled down by the signal at the first node N1, and the signal at the fourth node N4 is a low-level signal. In this stage, signals at the first node N1, the third node N3, and the fourth node N4 are low-level signals, the signal at the second node N2 is a high-level signal, the low-level signal at the second clock signal terminal CK2 is written to the first signal output terminal OUT1, a signal output by the first signal output terminal OUT1 is low-level signal, the signal at the third clock signal terminal CK3 is written to the second signal output terminal OUT2, and a signal output by the second signal output terminal OUT2 is high-level signal.

In a third stage S3, signals at the signal input terminal IN and the second clock signal terminal GCK2 are high-level signals, and signals at the first clock signal terminal CK1 and the third clock signal terminal CK3 are low-level signals. The signal at the first clock signal terminal CK1 is a low-level signal, the first transistor T1 and the third transistor T3 are turned on, the high-level signal at the signal input terminal IN is written to the first node N1, and the low-level signal at the second power supply terminal V2 is written to the second node N2. Since the eighth transistor T8 is continuously turned on, both a signal at the third node N3 and a signal at the first node N1 are high-level signals. The signal at the first node N1 is a high-level signal, and the second transistor T2 and the ninth transistor T9 are turned off. A signal at the second node N2 is a low-level signal, the fourth transistor T4, the sixth transistor T6, and the tenth transistor T10 are turned on, the high-level signal at the first power supply terminal V1 is written to the first signal output terminal OUT1 and the fourth node N4, and the low-level signal at the second power supply terminal V2 is written to the second signal output terminal OUT2. The signal at the third node N3 is a high-level signal, the fifth transistor T5 and the eleventh transistor T11 are turned off, a signal at the third power supply terminal V3 cannot be written to the first node N1, the signal at the first node N1 is kept as a high-level signal, and the high-level signal at the second clock signal terminal CK2 cannot be written to the first signal output terminal OUT1. As the signal at the second clock signal terminal CK2 is the high-level signal, the seventh transistor T7 is turned off. In this stage, the signal at the second node N2 is a low-level signal, signals at the first node N1, the third node N3, and the fourth node N4 are high-level signals, the signal at the first power supply terminal V1 is written to the first signal output terminal OUT1, a signal output by the first signal output terminal OUT1 is a high-level signal, the signal at the second power supply terminal V2 is written to the second signal output terminal OUT2, and a signal output by the second signal output terminal OUT2 is a low-level signal.

In a fourth stage S4, signals at the signal input terminal IN, the first clock signal terminal CK1 and the third clock signal terminal CK3 are high-level signals, and a signal at the second clock signal terminal CK2 is a low-level signal. The signal at the first clock signal terminal CK1 is a high-level signal, the first transistor T1 and the third transistor T3 are turned off, and a signal at the first node N1 remains a high-level signal. Since the eighth transistor T8 is continuously turned on, both a signal at the third node N3 and a signal at the first node N1 are high-level signals. The signal at the first node N1 is a high-level signal, the second transistor T2 and the ninth transistor T9 are turned off, and the high-level signal at the third clock signal terminal CK3 cannot be written to the second output signal terminal. The signal at the second node N2 is continuously a low-level signal, the fourth transistor T4, the sixth transistor T6, and the tenth transistor T10 are turned on, the high-level signal at the first power supply terminal V1 is written to the first signal output terminal OUT1 and the fourth node N4, and the low-level signal at the second power supply terminal V2 is written to the second signal output terminal OUT2. The signal at the third node N3 is a high-level signal, the fifth transistor T5 and the eleventh transistor T11 are turned off, a signal at the third power supply terminal V3 cannot be written to the first node N1, the signal at the first node N1 is kept as a high-level signal, and the high-level signal at the second clock signal terminal CK2 cannot be written to the first signal output terminal OUT1. As the signal at the second clock signal terminal CK2 is the high-level signal, the seventh transistor T7 is turned off. In this stage, the signal at the second node N2 is a low-level signal, signals at the first node N1, the third node N3, and the fourth node N4 are high-level signals, the signal at the first power supply terminal V1 is written to the first signal output terminal OUT1, a signal output by the first signal output terminal OUT1 is a high-level signal, the signal at the second power supply terminal V2 is written to the second signal output terminal OUT2, and a signal output by the second signal output terminal OUT2 is a low-level signal.

A working process of the shift register unit includes a plurality of third stages S3 and fourth stages S4, with the third stages S3 and the fourth stages S4 operating alternately.

The shift register unit provided in FIG. 15 is different from the shift register unit provided in FIG. 14 in that the node connected to a control electrode of the eleventh transistor is different, FIG. 14 is illustrated by an example in which the control electrode of the eleventh transistor is connected to the third node, and FIG. 15 is illustrated by an example in which the control electrode of the eleventh transistor is connected to the first node. Since signals at the first node N1 and the third node N3 are high-level signals or low-level signals at the same time, that is, the eleventh transistors in the shift register unit provided in FIGS. 14 and 15 are turned on or off at the same time, the working process of the shift register unit provided in FIG. 15 is the same as that of the shift register unit provided in FIG. 14.

The shift register unit provided in FIG. 16 is different from the shift register unit provided in FIG. 14 in that the shift register unit provided in FIG. 16 further includes the twelfth transistor T12. Since the twelfth transistor T12 is turned on, the second transistor T12 may be equivalent to a piece of wire and does not affect working process of other transistors of the shift register unit. Therefore, a working process of the shift register unit provided in FIG. 16 is the same as that of the shift register unit provided in FIG. 14.

The shift register unit provided in FIGS. 17 and 18 is different from the shift register unit provided in FIG. 15 in that the shift register unit provided in FIGS. 17 and 18 further includes the twelfth transistor T12. Since the twelfth transistor T12 is turned on, the second transistor T12 may be equivalent to a piece of wire and does not affect working process of other transistors of the shift register unit. Therefore, a working process of the shift register unit provided in FIGS. 17 and 18 is the same as that of the shift register unit provided in FIG. 15.

The Provision of the eleventh transistor T11 in the present disclosure may enable the first node N1 to be pulled down to a signal at the third power supply terminal V3 with a lower voltage value, which improves the conduction degree of the ninth transistor T9, so that the fifth transistor T5 and the ninth transistor T9 can be fully turned on.

FIG. 21 is a comparison diagram of signals at a first node and a second signal output terminal of different shift register units. In FIG. 21, N1-1 and OUT2-1 refer to the first node and the second signal output terminal, respectively, in any one of the shift register units in FIGS. 14 to 18 according to the present application, and N1-2 and OUT2-2 refer to the first node and the second signal output terminal, respectively, in a shift register unit whose transistors include only the first transistor to the tenth transistor. As shown in FIG. 21, in the output stage and part of the output stage, the voltage value of the signal at N1-1 is less than the voltage value of the signal at N1-2, and the duration of the rising edge of the signal at OUT2-1 is less than the duration of the rising edge of the signal at OUT2-2, that is, the shift register unit according to the present disclosure can increase the voltage value of the output signal at the second signal output terminal, and improve the performance of the shift register unit.

An embodiment of the present disclosure further provides a method for driving a shift register unit, configured to drive the shift register unit, and the method for driving the shift register unit may include the following acts.

Act 100: a node control sub-circuit provides a signal at a signal input terminal or a first power supply terminal to a first node, and provides a signal at a second power supply terminal or a first clock signal terminal to a second node under control of signals at the first clock signal terminal and a second clock signal terminal.

Act 200: the pull-down sub-circuit provides a signal at the third power supply terminal to the first node.

Act 300: an output sub-circuit provides a signal at the first power supply terminal or the second clock signal terminal to the first signal output terminal under control of signals at the first node and the second node.

The shift register unit is the shift register unit in accordance with any one of the foregoing embodiments, and its implementation principle and implementation effect are similar to the foresaid implementation principle and implementation effect and will not be repeated herein. In an exemplary implementation mode, the method for driving the shift register unit may further include: providing a signal at the second power supply terminal or the third clock signal terminal to the second signal output terminal under control of signals at the first node and the second node by the output sub-circuit.

In an exemplary implementation mode, the shift register unit may further include: an output control sub-circuit; the method for driving the shift register unit may further include storing a voltage difference between signals at the first signal output terminal and the first power supply terminal by the output control sub-circuit.

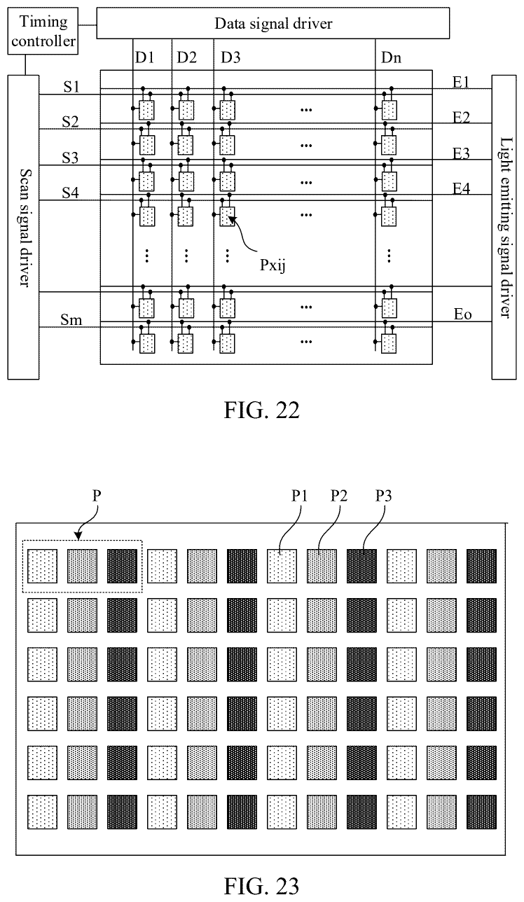

An embodiment of the present disclosure further provides a display apparatus. FIG. 22 is a schematic diagram of a structure of a display apparatus. As shown in FIG. 22, the display apparatus may include a timing controller, a data driver, a scan driver, a light emitting driver, and a display substrate. The display substrate includes a pixel array, the timing controller is respectively connected to the data driver, the scan driver and the light emitting driver, the data driver is respectively connected to a plurality of data signal lines (D1 to Dn), the scan driver is respectively connected to a plurality of scan signal lines (S1 to Sm), the light emitting driver is connected to a plurality of light emitting signal lines (E1 to Eo), respectively. The pixel array may include a plurality of sub-pixels Pxij, wherein i and j may be natural numbers. At least one sub-pixel Pxij may include a circuit unit and a light emitting device connected with the circuit unit. The circuit unit may include a pixel driving circuit, and the pixel driving circuit may be connected with a scan signal line, a light emitting signal line, and a data signal line respectively. In an exemplary implementation mode, the timing controller may provide the data driver with a grayscale value and a control signal which are suitable for a specification of the data driver, provide the scan driver with a clock signal and a scan start signal and the like which are suitable for a specification of the scan driver, and provide the light emitting driver with a clock signal and an emission stop signal and the like which are suitable for a specification of the light emitting driver. The data driver may generate data voltages to be provided to the data signal lines D1, D2, D3, . . . , and Dn using the grayscale value and the control signal that are received from the timing controller. For example, the data driver may sample the grayscale value using the clock signal and apply a data voltage corresponding to the grayscale value to the data signal lines D1 to Dn by taking a pixel row as a unit, wherein n may be a natural number. The scan driver may generate a scan signals to be provided to the scan signal lines S1, S2, S3, . . . , and Sm by receiving the clock signal and the scan start signal from the timing controller. For example, the scan driver may sequentially provide a scan signal with an on-level pulse to the scan signal lines S1 to Sm. For example, the scan driver may be constructed in a form of a shift register unit and may generate a scan signal in a manner in which a scan start signal provided in a form of an on-level pulse is transmitted to a next-stage circuit sequentially under control of the clock signal, wherein m may be a natural number. The light emitting driver may receive a clock signal, an emission stop signal, etc., from the timing controller to generate an emission signal to be provided to the light emitting signal lines E1, E2, E3, . . . , and Eo. For example, the light emitting driver may sequentially provide an emission signal with an off-level pulse to the light emitting signal lines E1 to Eo. For example, the light emitting driver may be constructed in a form of a shift register unit and generate an emission signal in a manner of sequentially transmitting an emission stop signal provided in a form of an off-level pulse to a next-stage circuit under control of the clock signal, wherein o may be a natural number.

In an exemplary implementation mode, the display apparatus may be a Liquid Crystal Display (LCD for short) or an Organic Light Emitting Diode (OLED for short) display apparatus. The display apparatus may be any product or component with a display function, such as a liquid crystal panel, electronic paper, an OLED panel, an Active-Matrix Organic Light Emitting Diode (AMOLED for short) panel, a mobile phone, a tablet computer, a television, a display, a notebook computer, a digital photo frame, or a navigator.

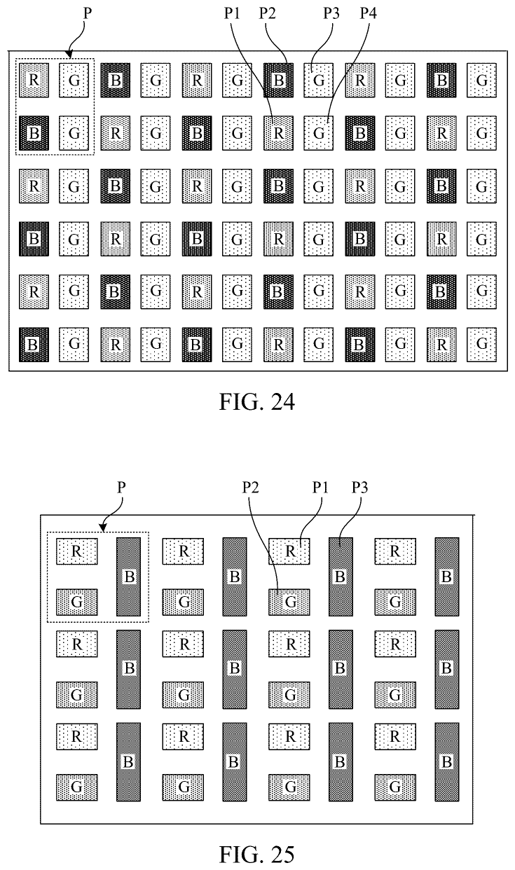

FIG. 23 is a first schematic diagram of a planar structure of a display substrate, FIG. 24 is a second schematic diagram of a planar structure of a display substrate, and FIG. 25 is a third schematic diagram of a planar structure of a display substrate. As shown in FIGS. 23 to 25, the display substrate may include a plurality of pixel units P arranged in a matrix, the plurality of pixel units P include a first sub-pixel P1 emitting light in a first color, a second sub-pixel P2 emitting light in a second color, and at least one third sub-pixel P3 emitting light in a third color, and each of the first sub-pixel P1, the second sub-pixel P2, and the third sub-pixel P3 includes a pixel driving circuit and a light emitting device. Pixel driving circuits in the first sub-pixel P1, the second sub-pixel P2, and the third sub-pixel P3 are connected with a scan signal line, a data signal line, and a light emitting signal line respectively. A pixel driving circuit is configured to receive a data voltage transmitted by the data signal line under control of the scan signal line and the light emitting signal line, and output a corresponding current to the light emitting device. Light emitting devices in the first sub-pixel P1, the second sub-pixel P2, and the third sub-pixel P3 are respectively connected to the pixel driving circuit of the sub-pixel in which the light emitting device is located, and the light emitting device is configured to emit light with a corresponding brightness in response to a current outputted by the pixel driving circuit of the sub-pixel in which the light emitting device is located.

In an exemplary implementation mode, the first sub-pixel P1 may be a red (R) sub-pixel emitting red light, the second sub-pixel P2 may be a blue (B) sub-pixel emitting blue light, and the third sub-pixel P3 may be a green (G) sub-pixel emitting green light. In an exemplary implementation mode, a sub-pixel may be in a shape of a rectangle, a rhombus, a pentagon, or a hexagon. Three sub-pixels may be arranged side by side horizontally, side by side vertically, or in a delta-shaped arrangement, the present disclosure is not limited thereto.

In an exemplary implementation mode, as shown in FIG. 23 and FIG. 25, a pixel unit may include three sub-pixels that may be arranged side by side horizontally, side by side vertically, or in a delta-shaped arrangement, the present disclosure is not limited thereto. FIG. 23 is illustrated by taking an arrangement side by side as an example, and FIG. 25 is illustrated by taking a delta-shaped arrangement as an example.

In an exemplary implementation mode, as shown in FIG. 24, a pixel unit may include four sub-pixels which may be one first sub-pixel, one second sub-pixel, and two third sub-pixels. The four sub-pixels may be arranged in a manner of standing side by side horizontally, in a manner of standing side by side vertically, or in a manner of a square, which is not limited in the present disclosure. FIG. 24 illustrates four sub-pixels arranged in a manner of a square as an example.

In an exemplary implementation mode, the light emitting device may be an Organic Light Emitting Diode (OLED), including a first electrode (anode), an organic light emitting layer, and a second electrode (cathode), which are stacked.

In an exemplary implementation mode, the organic emitting layer may include a Hole Injection Layer (HIL), a Hole Transport Layer (HTL), an Electron Block Layer (EBL), an Emitting Layer (EML), a Hole Block Layer (HBL), an Electron Transport Layer (ETL), and an Electron Injection Layer (EIL) that are stacked. In an exemplary implementation mode, hole injection layers of all sub-pixels may be connected together to be a common layer, electron injection layers of all the sub-pixels may be connected together to be a common layer, hole transport layers of all the sub-pixels may be connected together to be a common layer, electron transport layers of all the sub-pixels may be connected together to be a common layer, hole block layers of all the sub-pixels may be connected together to be a common layer, emitting layers of adjacent sub-pixels may be overlapped slightly or may be isolated, and electron block layers of adjacent sub-pixels may be overlapped slightly or may be isolated.

In an exemplary implementation mode, the display substrate is an LTPO display substrate.

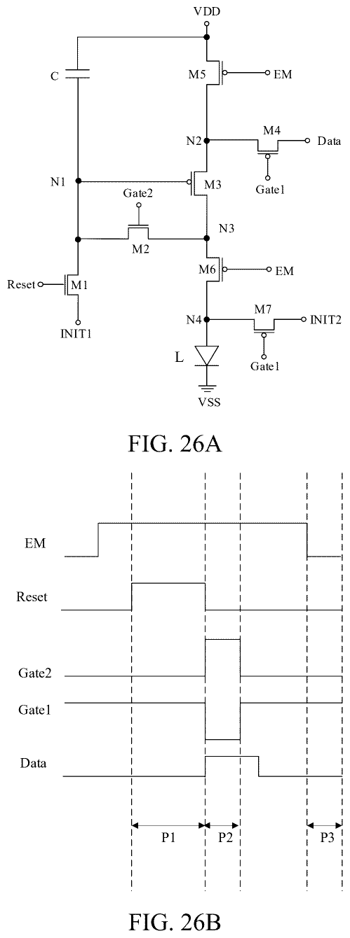

FIG. 26A is an equivalent circuit diagram of a pixel driving circuit. In an exemplary embodiment, the pixel driving circuit may have a structure of 3T1C, 4T1C, 5T1C, 5T2C, 6T1C, 7T1C, or 8T1C. As shown in FIG. 26A, the pixel driving circuit may include seven transistors (a first transistor M1 to a seventh transistor M7), and one capacitor C.

As shown in FIG. 26A, a gate electrode of the first transistor M1 is electrically connected to the reset signal line Reset, a first electrode of the first transistor M1 is electrically connected to the first initial signal line INIT1, and a second electrode of the first transistor M1 is electrically connected to the first node N1; a gate electrode of the second transistor M2 is electrically connected to the second scan signal line Gate2, a first electrode of the second transistor M2 is electrically connected to the first node N1, and a second electrode of the second transistor M2 is electrically connected to the third node N3; a gate electrode of the third transistor M3 is electrically connected to the first node N1, a first electrode of the third transistor M3 is electrically connected to the second node N2, and a second electrode of the third transistor M3 is electrically connected to the third node N3; a gate electrode of the fourth transistor M4 is electrically connected to the first scan signal line Gate1, a first electrode of the fourth transistor M4 is electrically connected to the data signal line Data, and a second electrode of the fourth transistor M4 is electrically connected to the second node N2; a gate electrode of the fifth transistor M5 is electrically connected to the light emitting signal line EM, a first electrode of the fifth transistor M5 is electrically connected to the high-level power supply line VDD, and a second electrode of the fifth transistor M5 is electrically connected to the second node N2; a gate electrode of the sixth transistor M6 is electrically connected to the light emitting signal line EM, a first electrode of the sixth transistor M6 is electrically connected to the third node N3, and a second electrode of the sixth transistor M6 is electrically connected to the fourth node N4; a gate electrode of the seventh transistor M7 is electrically connected to the first scan signal line Gate1, a first electrode of the seventh transistor M7 is electrically connected to the second initial signal line INIT2, and a second electrode of the seventh transistor M7 is electrically connected to the fourth node N4; a first plate of the capacitor C is electrically connected to the first node N1, and a second plate of the capacitor C is electrically connected to the high-level power supply line VDD.

In an exemplary implementation mode, for the first transistor M1 to the seventh transistor M7, low temperature poly silicon thin film transistors may be used, or oxide thin film transistors may be used, or both a low temperature poly silicon thin film transistor and an oxide thin film transistor may be used. An active layer of a low temperature poly silicon thin film transistor is made of Low Temperature Poly silicon (LTPS for short), and an active layer of an oxide thin film transistor is made of an oxide semiconductor (Oxide). The Low-temperature Poly Silicon thin film transistor has advantages such as a high mobility rate and fast charging, and the oxide thin film transistor has advantages such as a low leakage current. The Low Temperature Poly Silicon thin film transistor and the oxide thin film transistor are integrated on one display substrate to form a LTPO display substrate, and advantages of both the Low Temperature Poly Silicon thin film transistor and the oxide thin film transistor may be utilized, which can achieve low frequency drive, reduce power consumption, and improve display quality.

In an exemplary implementation mode, the first transistor M1 and the second transistor M2 are of a transistor type opposite to the third transistor M3 to the seventh transistor M7. Exemplarily, the first transistor M1 and the second transistor M2 may be N-type transistors, and the third transistors M3 to the seventh transistor M7 may be P-type transistors.

In an exemplary implementation mode, the first transistor M1 and the second transistor M2 may be oxide transistors, and the third transistor M3 to the seventh transistor M7 may be low-temperature poly silicon transistors.

In an exemplary implementation mode, a voltage value of a signal of the first initial signal line INIT1 is constant and the signal is a Direct Current (DC) signal. The voltage value of the signal of the first initial signal line INIT1 may be −3V.

In an exemplary implementation mode, the voltage value of the signal of the second initial signal line INIT2 is constant and the signal is a DC signal, and the voltage value of the signal of the second initial signal line INIT2 may be OV.

In an exemplary implementation mode, the light emitting device L may be electrically connected with the fourth node N4 and the low-level power supply line VSS, respectively.

In an exemplary implementation mode, the high-level power supply line VDD continuously provides a high-level signal, and the low power supply line VSS continuously provides a low-level signal.

FIG. 26B is a working timing diagram of the pixel driving circuit provided in FIG. 26A. An exemplary embodiment of the present disclosure is described below with reference to an operation process of the pixel driving circuit illustrated in FIG. 26A during a display stage. FIG. 26B illustrates an exemplary embodiment in which a first transistor M1 and a second transistor M2 are N-type transistors and a third transistor M3 to a seventh transistor M7 are P-type transistors. A pixel driving circuit in FIG. 26B includes a first transistor M1 to a seventh transistors M7, one capacitor C, and eight signal lines (a data signal line Data, a first scan signal line Gate1, a second scan signal line Gate2, a reset signal line Reset, a first initial signal line INIT1, a second initial signal line INIT2, a light emitting signal line EM, and a high-level power supply line VDD).

In conjunction with FIGS. 26A and 26B, the working process of the pixel driving circuit may include following stages.

In a first stage P1, referred to as an initialization stage, the signal of the reset signal line Reset is a high-level signal, the first transistor M1 is turned on, and the signal of the first initial signal line INIT1 is written to the first node N1 through the turned-on first transistor M1, so as to initialize (reset) the first node N1, and empty a pre-stored voltage in the first node N1 to complete the initialization.

In a second stage P2, referred to as a data writing stage or a threshold compensation stage, the signal of the first scan signal line Gate1 is a low-level signal, the signal of the second scan signal line Gate2 is a low-level signal, and the data signal line Data outputs a data voltage. In this stage, since the first node N1 is a low-level signal, the third transistor M3 is turned on. The signal of the first scan signal line Gate1 is a low-level signal, the fourth transistor M4 and the seventh transistor M7 are turned on, the signal of the second scan signal line Gate2 is a high-level signal, the second transistor M2 is turned on, the data voltage output by the data signal line Data is provided to the first node N1 through the turned-on fourth transistor M4, the second node N2, the turned-on third transistor M3, the third node N3 and the turned-on second transistor M2, and the difference between the data voltage output by the data signal line Data and the threshold voltage of the third transistor M3 is charged into the capacitor C until the voltage of the first node N1 is Vd−|Vth|, Vd is the data voltage output from the data signal line Data, Vth is the threshold voltage of the third transistor M3, the seventh transistor M7 is turned on, the signal of the second initial signal line INIT2 is written to the fourth node N4 through the turned-on seventh transistor M7 to initialize (reset) a first electrode of the light emitting device L, and empty a pre-stored voltage in the first electrode of the light emitting device L to complete the initialization.

In a third stage P3, referred to as a light emitting stage, the signal of the light emitting signal line EM is the low-level signal, the fifth transistor M5 and the sixth transistor M6 are turned on, and a power supply voltage output by the high-level power supply line VDD provides a drive voltage to the first electrode of the light emitting device L through the turned-on fifth transistor M5, the third transistor M3, and the sixth transistor M6, to drive the light emitting device L to emit light.

In a drive process of the pixel driving circuit, a driving current flowing through the third transistor M3 (drive transistor) is determined by a voltage difference between the gate electrode and the first electrode of the third transistor M3. Since the voltage of the first node N1 is Vd−|Vth|, the driving current of the third transistor M3 is as follows:

I=K*(Vgs−Vth)²−K*[(Vdd−Vd+|Vth|)−Vth]²=K*(Vdd−Vd)²

I is the driving current flowing through the third transistor M3, that is, a driving current for driving the light emitting device L, K is a constant, Vgs is the voltage difference between the gate electrode and the first electrode of the third transistor M3, Vth is the threshold voltage of the third transistor M3, Vd is the data voltage output by the data signal line Data, and Vdd is the power supply voltage output by the high-level power supply line VDD.

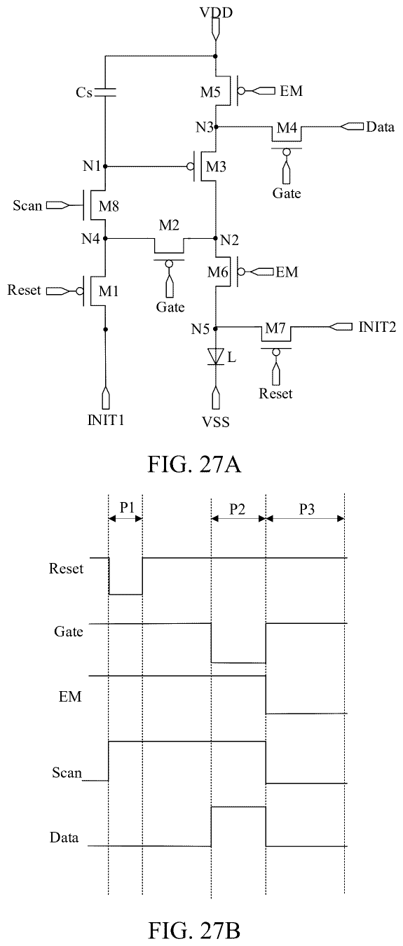

In an exemplary implementation mode, FIG. 27A is an equivalent circuit diagram of another pixel driving circuit. As shown in FIG. 27A, the pixel driving circuit may include eight transistors (a first transistor M1 to an eighth transistor M8), one capacitor C, and nine signal lines (a data signal line Data, a control signal line Scan, a scan signal line Gate, a reset signal line Reset, a light emitting signal line EM, a first initial signal line INIT1, a second initial signal line INIT2, a high-level power supply line VDD, and a low-level power supply line VSS).

In an exemplary implementation mode, a first plate of the capacitor C is connected with the high-level power supply line VDD, and a second plate of the capacitor C is connected with a first node N1. A control electrode of the first transistor M1 is connected with the reset signal line Reset, a first electrode of the first transistor M1 is connected with the first initial signal line INIT1, and a second electrode of the first transistor is connected with a fourth node N4. A control electrode of the second transistor M2 is connected with the scan signal line Gate, a first electrode of the second transistor M2 is connected with the fourth node N4, and a second electrode of the second transistor M2 is connected with a second node N2. A control electrode of the third transistor M3 is connected with the first node N1, a first electrode of the third transistor M3 is connected with a second node N2, and a second electrode of the third transistor M3 is connected with the third node N3. A control electrode of the fourth transistor M4 is connected with the scan signal line Gate, a first electrode of the fourth transistor M4 is connected with the data signal line Data, and a second electrode of the fourth transistor M4 is connected with the third node N3. A control electrode of the fifth transistor M5 is connected with the light emitting signal line EM, a first electrode of the fifth transistor M5 is connected with the high-level power supply line VDD, and a second electrode of the fifth transistor M5 is connected with the third node N3. A control electrode of the sixth transistor M6 is connected with the light emitting signal line EM, a first electrode of the sixth transistor M6 is connected with the second node N2, and a second electrode of the sixth transistor M6 is connected with a first electrode of a light emitting device L. A control electrode of the seventh transistor M7 is connected with the reset signal line Reset, a first electrode of the seventh transistor M7 is connected with the second initial signal line INIT2, a second electrode of the seventh transistor M7 is connected with the first electrode of the light emitting device L, and a second electrode of the light emitting device L is connected with the low-level power supply line VSS. A control electrode of the eighth transistor M8 is connected with the control signal line Scan, a first electrode of the eighth transistor M8 is connected with the first node N1, and a second electrode of the eighth transistor M8 is connected with the fourth node N4.

In an exemplary implementation mode, the control electrode of the seventh transistor M7 may also be connected with the scan signal line Gate, the first electrode of the seventh transistor M7 is connected with the second initial signal line INIT2, the second electrode of the seventh transistor M7 is connected with the first electrode of the light emitting device L, and the second electrode of the light emitting device L is connected with the low-level power supply line VSS.

In an exemplary implementation mode, a signal of the high-level power supply line VDD is a high-level signal continuously provided, and a signal of the low-level power supply line VSS is a low-level signal.

In an exemplary implementation mode, the eighth transistor M8 is a metal oxide transistor, and is an N-type transistor, and the first transistor M1 to the seventh transistor M7 are low temperature poly silicon transistors and are P-type transistors.

In an exemplary implementation mode, the eighth transistor M8 is an oxide transistor and may reduce a leakage current, improve performance of the pixel driving circuit, and may reduce power consumption of the pixel driving circuit.

FIG. 27B is a working timing diagram of the pixel driving circuit provided in FIG. 27A. An exemplary embodiment of the present disclosure is described below with reference to a working process of the pixel driving circuit illustrated in FIG. 27B. The working process of the pixel driving circuit may include following stages.

In a first stage A1, referred to as a reset stage, signals of the control signal line Scan, the light emitting signal line EM, and the scan signal line Gate are all high-level signals, and a signal of the reset signal line Reset is a low-level signal. The signal of the reset signal line Reset is the low-level signal, the first transistor M1 is turned on, a signal of the first initial signal line INIT1 is provided to the fourth node N4, the seventh transistor M7 is turned on, an initial voltage of the second initial signal line INIT2 is provided to the first electrode of the light emitting device L to initialize (reset) the first electrode of the light emitting device L, for example, empty a pre-stored voltage therein, initialization is completed, and the light emitting device L is ensured not to emit light. A signal of the control signal line Scan is a high-level signal, the eighth transistor M8 is turned on, a signal at the fourth node N4 is provided to the first node N1 to initialize the capacitor C, and an original data voltage in the capacitor C is cleared. Signals of the scan signal line Gate and the light emitting signal line EM are high-level signals, and the second transistor M2, the fourth transistor M4, the fifth transistor M5, the sixth transistor M6, and the seventh transistor M7 are turned off, and the light emitting device L does not emit light in this stage.

In a second stage A2, referred to as a data writing stage or a threshold compensation stage, a signal of the scan signal line Gate is a low-level signal, signals of the reset signal line Reset, the light emitting signal line EM, and the control signal line Scan are high-level signals, and the data signal line Data outputs a data voltage. In this stage, since the first node N1 is a low-level signal, the third transistor M3 is turned on. The signal of the scan signal line Gate is the low-level signal, the second transistor M2 and the fourth transistor M4 are turned on, a signal of the control signal line Scan is a high-level signal, and the eighth transistor M8 is turned on. The second transistor M2, the fourth transistor M4, and the eighth transistor M8 are turned on so that a data voltage output by the data signal line Data is provided to the first node N1 through the third node N3, the turned-on third transistor M3, the second node N2, the turned-on second transistor M2, the fourth node N4, and the turned-on eighth transistor M8. A difference between the data voltage output by the data signal line Data and a threshold voltage of the third transistor M3 is charged into the capacitor C until a voltage of the first node N1 is Vd-|Vth|, wherein Vd is the data voltage output by the data signal line Data, and Vth is the threshold voltage of the third transistor M3. A signal of the reset signal line Reset is a low-level signal, and the first transistor M1 and the seventh transistor M7 are turned off. A signal of the light emitting signal line EM is a high-level signal, and the fifth transistor M5 and the sixth transistor M6 are turned off.

In a third stage A3, referred to as a light emitting stage, signals of the control signal line Scan and the light emitting signal line EM are both low-level signals, and signals of the scan signal line Gate and the reset signal line Reset are high-level signals. A signal of the reset signal line Reset is a low-level signal, and the first transistor M1 and the seventh transistor M7 are turned off. A signal of the control signal line Scan is a low-level signal, the signals of the scan signal line Gate and the reset signal line Reset are the high-level signals, and the second transistor M2, the fourth transistor M4, and the eighth transistor M8 are turned off. A signal of the light emitting signal line EM is a low-level signal, the fifth transistor M5 and the sixth transistor M6 are turned on, and a power supply voltage output by the high-level power supply line VDD provides a drive voltage to the first electrode of the light emitting device L through the turned-on fifth transistor M5, the third transistor M3, and the sixth transistor M6, so as to drive the light emitting device L to emit light.

In a drive process of the pixel driving circuit, a driving current flowing through the third transistor M3 (drive transistor) is determined by a voltage difference between the control electrode and the first electrode of the third transistor M3. Since the voltage of the first node N1 is Vd−|Vth|, the driving current of the third transistor M3 is as follows:

$$I = K ⋆ {( V gs - V th )}^{2} = K ⋆ {[ ( V dd - V d + \vert V th \vert ) - V th ]}^{2} = K ⋆ {( V dd - V d )}^{2}$$

Herein, I is the driving current flowing through the third transistor M3, i.e., a driving current for driving the light emitting device L, K is a constant, Vgs is the voltage difference between the control electrode and the first electrode of the third transistor M3, Vth is the threshold voltage of the third transistor M3, Vd is the data voltage output by the data signal line Data, and Vdd is the power voltage output by the high-level power supply line VDD.

A display substrate according to an embodiment of the present disclosure may include a base substrate and sub-pixels, a gate line and a gate driving circuit disposed on the base substrate, the base substrate is provided with a display region and a non-display region, the gate driving circuit is located in the non-display region, the sub-pixels and the gate line are located in the display region, and the gate line is electrically connected to the sub-pixels and the gate driving circuit, respectively.

In an exemplary implementation mode, a sub-pixel includes a pixel driving circuit and a light emitting device. When the pixel driving circuit is the pixel driving circuit provided in FIG. 26A, the gate line may include at least one of a reset signal line, a first scan signal line, a second scan signal line, and a light emitting signal line.

In an exemplary implementation mode, a sub-pixel includes a pixel driving circuit and a light emitting device. When the pixel driving circuit is the pixel driving circuit provided in FIG. 27A, the gate line may include at least one of a reset signal line, a first scan signal line, a second scan signal line, a control signal line, and a light emitting signal line.

The shift register unit is the shift register unit in accordance with any one of the foregoing embodiments, and its implementation principle and implementation effect are similar to the foresaid implementation principle and implementation effect and will not be repeated herein.

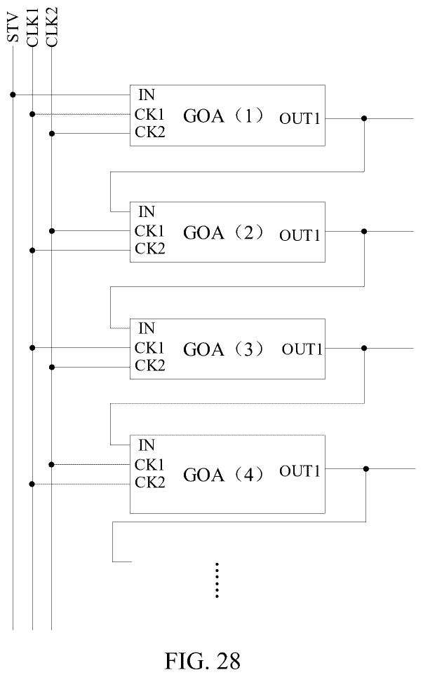

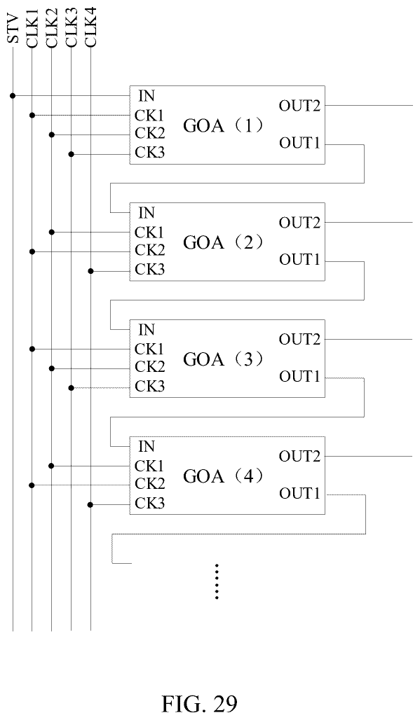

FIG. 28 is a first cascade schematic diagram of a gate driving circuit, and FIG. 29 is a second cascade schematic diagram of a gate driving circuit. As shown IN FIGS. 28 and 29, the first signal output terminal OUT1 of an i-th stage shift register unit GOA (i) is connected to the signal input terminal IN of an (i+1)-st stage shift register unit GOA (i+1), 1≤i<N, N is the total number of stages of the shift register unit. Here, FIG. 28 is illustrated by taking the shift register unit provided in FIGS. 12 and 13 as an example, and FIG. 29 is illustrated by taking the shift register unit provided in FIGS. 14 to 18 as an example.

In an exemplary implementation mode, the base substrate may be a rigid base substrate or a flexible base substrate, wherein the rigid base substrate may be, but is not limited to, one or more of glass and conductive foil. The flexible base substrate may be, but is not limited to, one or more of polyethylene terephthalate, ethylene terephthalate, polyether ether ketone, polystyrene, polycarbonate, polyarylate, polyarylester, polyimide, polyvinyl chloride, polyethylene, and textile fiber.

In an exemplary implementation mode, the flexible base substrate may include a first flexible material layer, a first inorganic material layer, a semiconductor layer, a second flexible material layer, and a second inorganic material layer which are stacked. Materials of the first flexible material layer and the second flexible material layer may be Polyimide (P1), Polyethylene Terephthalate (PET), or a surface-treated polymer soft film, etc., and materials of the first inorganic material layer and the second inorganic material layer may be Silicon Nitride (SiNx), Silicon Oxide (SiOx), or the like, for improving water and oxygen resistance of the base substrate. The first inorganic material layer and the second inorganic material layer may also be referred to as barrier layers, and a material of the semiconductor layer may be amorphous silicon (a-si). In an exemplary implementation mode, taking a stacked structure of PI1/Barrier1/a-si/PI2/Barrier2 as an example, its preparation process may include: first coating a layer of polyimide on a glass carrier board, after the layer of polyimide is cured to form a film, a first flexible (PI1) layer is formed; then depositing a layer of barrier thin film on the first flexible layer to form a first barrier (Barrier1) layer overlaying the first flexible layer; then depositing a layer of amorphous silicon thin film on the first barrier layer to form an amorphous silicon (a-si) layer covering the first barrier layer; then coating another layer of polyimide on the amorphous silicon layer, after this layer of polyimide is cured to form a film, a second flexible (PI2) layer is formed; and then depositing a layer of barrier thin film on the second flexible layer to form a second barrier (Barrier2 layer covering the second flexible layer, so as to complete preparation of the base substrate.

In an exemplary implementation mode, as shown in FIG. 28, the first signal output terminal OUT1 of a shift register units may be electrically connected to the gate line.

In an exemplary implementation mode, as shown in FIG. 29, the second signal output terminal OUT2 of a shift register unit may be electrically connected to the gate line.

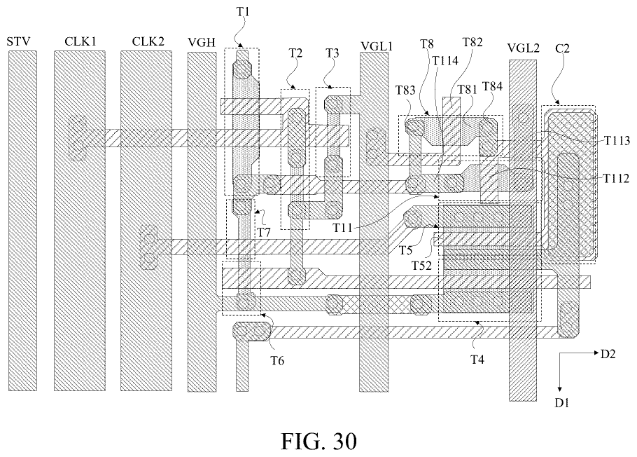

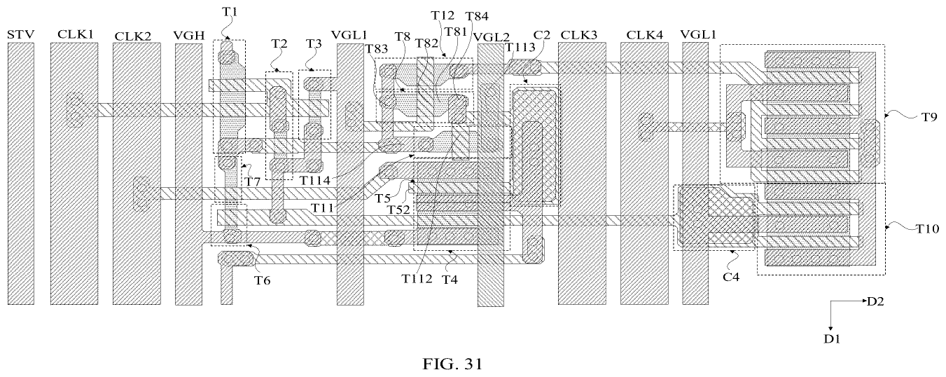

In an exemplary implementation mode, FIG. 30 is a first schematic diagram of a structure of a display substrate, and FIG. 31 is a second schematic diagram of a structure of a display substrate. FIG. 30 is illustrated by taking the shift register unit provided in FIG. 12 as an example, and FIG. 31 is illustrated by taking the shift register unit provided in FIG. 18 as an example. As shown in FIGS. 28 to 31, the display substrate may further include an initial signal line STV, a first clock signal line CLK1, a second clock signal line CLK2, a first power supply line VGH, a second power supply line VGL1, and a third power supply line VGL2 disposed on the base substrate and located in the non-display region.

In an exemplary implementation mode, the signal input terminal IN of a first-stage shift register unit GOA (1) is electrically connected to the initial signal line STV, the first power supply terminal of an i-th stage shift register unit is electrically connected to the first power supply line VGH, the second power supply terminal of the i-th stage shift register unit is electrically connected to the second power supply line VGL1, and the third power supply terminal of the i-th stage shift register unit is electrically connected to the third power supply line VGL2.

In an exemplary implementation mode, any one of the initial signal line STV, the first clock signal line CLK1, the second clock signal line CLK2, the first power supply line VGH, the second power supply line VGL1, and the third power supply line VGL2 extends in a first direction D1, and the gate line extends in a second direction D2, and the first direction D1 and the second direction D2 intersect.

In an exemplary implementation mode, as shown in FIGS. 30 and 31, the initial signal line STV, the first clock signal line CLK1, the second clock signal line CLK2, and the first power supply line VGH are sequentially arranged in a direction close to the display region, and are located at a side of the shift register unit away from the display region.

In an exemplary implementation mode, as illustrated in FIGS. 30 and 31, the shift register unit includes a plurality of transistors, and the second power supply line VGL1 is located at a side of the first power supply line VGH close to the display region, and is located between the plurality of transistors of the shift register unit.

In an exemplary implementation mode, as shown in FIGS. 30 and 31, the third power supply line VGL2 is located at a side of the second power supply line VGL1 close to the display region, and an orthographic projection of the third power supply line VGL2 on the base substrate is partially overlapped with an orthographic projection of the shift register unit on the base substrate.

In an exemplary implementation mode, as shown in FIGS. 30 and 31, the shift register unit includes a first transistor T1, a second transistor T2, a third transistor T3, a sixth transistor T6, and a seventh transistor T7. At least a part of any one of the first transistor T1, the second transistor T2, the third transistor T3, the sixth transistor T6, and the seventh transistor T7 is located between the first power supply line VGH and the second power supply line VGL1.

In an exemplary implementation mode, as shown in FIG. 31, the shift register unit includes a fourth transistor T4, a fifth transistor T5, an eighth transistor T8, an eleventh transistor T11, and a twelfth transistor T12, the number of second power supply lines VGL1 is at least one, and at least a part of any one of the fourth transistor T4, the fifth transistor T5, the eighth transistor T8, the eleventh transistor T11, and the twelfth transistor T12 is located at a side of the second power supply line VGL1 close to the display region.

In an exemplary implementation mode, as shown in FIGS. 30 and 31, the shift register unit includes: a second capacitor C2; the second capacitor C2 is located at a side of the third power supply line VGL2 close to the display region.

In an exemplary implementation mode, as shown in FIG. 31, the display substrate may further include a third clock signal line CLK3 and a fourth clock signal line CLK4 disposed on the base substrate and located in the non-display region, and any one of the third clock signal line CLK3 and the fourth clock signal line CLK4 extends in the first direction D1.

In an exemplary implementation mode, as shown in FIG. 31, the number of second power supply lines VGL1 is two, the second power supply line VGL1 close to the display region is located at a side of any one of the third clock signal line CLK3 and the fourth clock signal line CLK4 close to the display region, and the second power supply line VGL1 away from the display region is located between the first power supply line VGH and the third power supply line VGL2.

In an exemplary implementation mode, as illustrated in FIG. 31, the shift register unit includes a fourth transistor T4, a fifth transistor T5, an eighth transistor T8, a ninth transistor T9, a tenth transistor T10, an eleventh transistor T11, a twelfth transistor T12, and a fourth capacitor C4. The fourth transistor T4, the fifth transistor T5, the eighth transistor T8, the eleventh transistor T11, and the twelfth transistor T12 are located between the second power supply line VGL1 away from the display region and any one of the third clock signal line CLK3 and the fourth clock signal line CLK4, and the ninth transistor T9 and the tenth transistor T10 are located at a side of the second power supply line VGL1 close to the display region close to the display region.

In an exemplary implementation mode, as shown in FIG. 31, an orthographic projection of the second power supply line VGL1 close to the display region on the base substrate is partially overlapped with an orthographic projection of the fourth capacitor C4 on the base substrate.

In an exemplary implementation mode, as shown in FIGS. 28 to 31, the first clock signal terminal CK1 of the i-th stage shift register unit is electrically connected to one of the first clock signal line CLK1 and the second clock signal line CLK2, and the second clock signal terminal CK2 of the i-th stage shift register unit is electrically connected to the other of the first clock signal line CLK1 and the second clock signal line CLK2; the signal lines to which the first clock signal terminals of adjacent shift register units are connected are different, and the signal lines to which the second clock signal terminals of adjacent shift register units are connected are different. Exemplarily, the first clock signal terminal CK1 of an odd-numbered stage shift register unit may be electrically connected to the first clock signal line CLK1, the second clock signal terminal CK2 of the odd-numbered stage shift register unit may be electrically connected to the second clock signal line CLK2, the first clock signal terminal CK1 of an even-numbered stage shift register unit may be electrically connected to the second clock signal line CLK2, the second clock signal terminal CK2 of the even-numbered stage shift register unit may be electrically connected to the first clock signal line CLK1, alternatively, the first clock signal terminal CK1 of the odd-numbered stage shift register unit may be electrically connected to the second clock signal line CLK2, the second clock signal terminal CK2 of the odd-numbered stage shift register unit may be electrically connected to the first clock signal line CLK1, the first clock signal terminal CK1 of the even-numbered stage shift register unit may be electrically connected to the first clock signal line CLK1, the second clock signal terminal CK2 of the even-numbered stage shift register unit may be electrically connected to the second clock signal line CLK2, FIGS. 28 and 29 are illustrated by an example in which the first clock signal terminal CK1 of the odd-numbered stage shift register unit may be electrically connected to the first clock signal line CLK1, the second clock signal terminal CK2 of the odd-numbered stage shift register unit may be electrically connected to the second clock signal line CLK2, the first clock signal terminal CK1 of the even-numbered stage shift register unit may be electrically connected to the second clock signal line CLK2, and the second clock signal terminal CK2 of the even-numbered stage shift register unit may be electrically connected to the first clock signal line CLK1.

In an exemplary implementation mode, as shown in FIGS. 29 and 31, the third clock signal terminal CK3 of the i-th stage shift register unit is electrically connected to one of the third clock signal line CLK3 and the fourth clock signal line CLK4, and the third clock signal terminal CK3 of the (i+1)-st stage shift register unit is electrically connected to the other of the third clock signal line CLK3 and the fourth clock signal line CLK4. Exemplarily, the third clock signal terminal CK3 of the odd-numbered stage shift register unit is electrically connected to the third clock signal line CLK3, the third clock signal terminal CK3 of the even-numbered stage shift register unit is electrically connected to the fourth clock signal line CLK4, or the third clock signal terminal CK3 of the odd-numbered stage shift register unit is electrically connected to the fourth clock signal line CLK4, and the third clock signal terminal CK3 of the even-numbered stage shift register unit is electrically connected to the third clock signal line CLK3. FIG. 29 is illustrated by an example in which the third clock signal terminal CK3 of the odd-numbered stage shift register unit is electrically connected to the third clock signal line CLK3, and the third clock signal terminal CK3 of the even-numbered stage shift register unit is electrically connected to the fourth clock signal line CLK4.

In an exemplary implementation mode, as shown in FIGS. 30 and 31, an orthographic projection of the third power supply line VGL2 on the base substrate is partially overlapped with orthographic projections of the fourth transistor T4 and the fifth transistor T5 on the base substrate.

In an exemplary implementation mode, as shown in FIGS. 30 and 31, the active layer T81 of the eighth transistor T8 extends in the second direction D2, any one of the first electrode T83 and the second electrode T84 of the eighth transistor T8 extends in the first direction D1, and the gate electrode T82 of the eighth transistor T8 extends at least partially in the first direction D1.

In an exemplary implementation mode, as shown in FIGS. 30 and 31, the gate electrode T112 of the eleventh transistor and the gate electrode T52 of the fifth transistor are of an integral structure, an orthographic projection of the first electrode T113 of the eleventh transistor on the base substrate is partially overlapped with an orthographic projection of the third power supply line VGL2 on the base substrate, and the first electrode T113 of the eleventh transistor is electrically connected to the third power supply line VGL2, and the second electrode T114 of the eleventh transistor is integrally structured with the first electrode T83 of the eighth transistor and the first electrode T123 of the twelfth transistor.

In an exemplary implementation mode, as illustrated in FIG. 31, the width of any one of the first power supply line VGH, the second power supply line VGL1, and the third power supply line VGL2 in the second direction D2 is less than the width of any one of the first clock signal line CLK1, the second clock signal line CLK2, the third clock signal line CLK3, and the fourth clock signal line CLK4 in the second direction D2.

In an exemplary implementation mode, since the signal of the clock signal line is an AC signal, a wider width of any one of the first clock signal line CLK1, the second clock signal line CLK2, the third clock signal line CLK3, and the fourth clock signal line CLK4 in the second direction D2 can reduce the load of the clock signal line.

In an exemplary implementation mode, a channel width of an active layer of the tenth transistor is larger than a channel width of an active layer of the fourth transistor.

In an exemplary implementation mode, a channel width of an active layer of the tenth transistor is not less than 90 microns. Exemplarily, the channel width of the active layer of the tenth transistor may be about 100 microns.

In an exemplary implementation mode, the channel length of the active layer of the tenth transistor may be about 3.5 microns, and the channel width-to-length ratio of the active layer of the tenth transistor may be about 100/3.5.

In an exemplary implementation mode, a channel width of an active layer of the fourth transistor is not greater than 50 microns. Exemplarily, the channel width of the active layer of the fourth transistor may be about 25 microns.

In an exemplary implementation mode, the channel length of the active layer of the fourth transistor may be about 3.5 microns, and the channel width-to-length ratio of the active layer of the fourth transistor may be about 25/3.5.

In an exemplary implementation mode, a channel width of an active layer of the ninth transistor is greater than a channel width of an active layer of the fifth transistor.

In an exemplary implementation mode, a channel width of an active layer of the ninth transistor is not less than 90 microns. Exemplarily, the channel width of the active layer of the ninth transistor may be about 100 microns.

In an exemplary implementation mode, the channel length of the active layer of the ninth transistor may be about 3.5 microns, and the channel width-to-length ratio of the active layer of the ninth transistor may be about 100/3.5.

In an exemplary implementation mode, a channel width of an active layer of the fifth transistor is not greater than 50 microns. Exemplarily, the channel width of the active layer of the fifth transistor may be about 25 microns.

In an exemplary implementation mode, the channel length of the active layer of the fifth transistor may be about 3.5 microns, and the channel width-to-length ratio of the active layer of the fifth transistor may be about 25/3.5.

In an exemplary implementation mode, the display substrate may further include: a driving structure layer disposed on the base substrate; the driving structure layer includes a semiconductor layer, a first conductive layer, a second conductive layer, a third conductive layer and a fourth conductive layer which are sequentially stacked on the base substrate; the shift register unit includes: a plurality of transistors and a plurality of capacitors, and any one of the capacitors includes: a first plate and a second plate.

The semiconductor layer includes at least: active layers of a plurality of transistors located in at least one shift register unit.

The first conductive layer includes at least: control electrodes of a plurality of transistors and first plates of a plurality of capacitors located in at least one shift register unit.

The second conductive layer includes at least: second plates of a plurality of capacitors located in at least one shift register unit.

The third conductive layer includes at least: an initial signal line, a first clock signal line, a second clock signal line, a first power supply line, a second power supply line, a third clock signal line, a fourth clock signal line, and first and second electrodes of a plurality of transistors located in least one shift register unit.

The fourth conductive layer includes at least a third power supply line.

In an exemplary implementation mode, the driving structure layer may further include a first insulation layer, a second insulation layer, a third insulation layer, a fourth insulation layer, a fifth insulation layer, and a planarization layer, wherein the first insulation layer is located between the semiconductor layer and the first conductive layer, the second insulation layer is located between the first conductive layer and the second conductive layer, the third insulation layer is located between the second conductive layer and the third conductive layer, the fourth insulation layer is located between the third conductive layer and the fourth conductive layer, the fifth insulation layer is located on a side of the fourth conductive layer away from the base substrate, and the planarization layer is located on a side of the fifth insulation layer away from the base substrate.

Exemplary description is made below through a manufacturing process of a display substrate. A “patterning process” mentioned in the present disclosure includes photoresist coating, mask exposure, development, etching, photoresist stripping, and the like for a metal material, an inorganic material, or a transparent conductive material, and includes organic material coating, mask exposure, development, and the like for an organic material. Deposition may be any one or more of sputtering, evaporation, and chemical vapor deposition, coating may be any one or more of spray coating, spin coating, and inkjet printing, and etching may be any one or more of dry etching and wet etching, the present disclosure is not limited thereto. A “thin film” refers to a layer of thin film made of a certain material on a base substrate using deposition, coating, or other processes. If the “thin film” does not need to be processed through a patterning process in the entire manufacturing process, the “thin film” may also be called a “layer”. If the “thin film” needs to be processed through the patterning process in the entire manufacturing process, the “thin film” is called a “thin film” before the patterning process is performed and is called a “layer” after the patterning process is performed. At least one “pattern” is contained in the “layer” which has been processed through the patterning process. “A and B are provided in a same layer” in the present disclosure means that A and B are formed simultaneously through a same patterning process, and a “thickness” of a film layer is a dimension of the film layer in a direction perpendicular to a display substrate. In an exemplary embodiment of the present disclosure, “an orthographic projection of B being within a range of an orthographic projection of A” or “an orthographic projection of A containing an orthographic projection of B” means that a boundary of the orthographic projection of B falls within a range of a boundary of the orthographic projection of A, or the boundary of the orthographic projection of A is overlapped with the boundary of the orthographic projection of B.

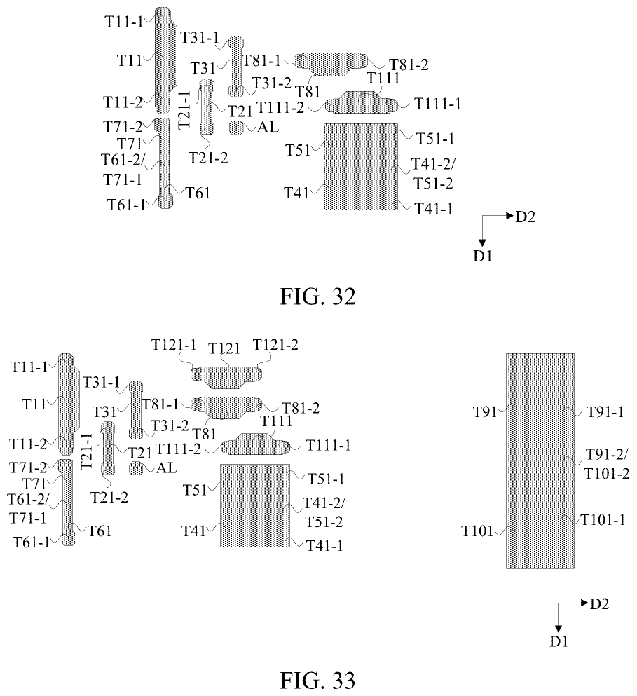

(1) Forming a pattern of a semiconductor layer on a base substrate, includes: depositing a semiconductor thin film on the base substrate, and patterning the semiconductor thin film through a patterning processes to form the pattern of the semiconductor layer. As shown in FIGS. 32 and 33, FIG. 32 is a schematic diagram after a pattern of a semiconductor layer is formed in FIG. 30, and FIG. 33 is a schematic diagram after a pattern of a semiconductor layer is formed in FIG. 31.

In an exemplary implementation mode, as illustrated in FIG. 32, the pattern of the semiconductor layer may include an active layer T11 of the first transistor to an active layer T81 of the eighth transistor, an active layer T111 of the eleventh transistor located in least one shift register unit, and an active connection block AL.

In an exemplary implementation mode, as illustrated in FIG. 33, the pattern of the semiconductor layer may include an active layer T11 of the first transistor to an active layer T121 of the twelfth transistor located in least one shift register unit, and an active connection block AL.

In an exemplary implementation mode, as shown in FIGS. 32 and 33, the active layer T41 of the fourth transistor and the active layer T51 of the fifth transistor are of an integral structure, and the active layer T61 of the sixth transistor and the active layer T71 of the seventh transistor are of an integral structure. The active layer T11 of the first transistor, the active layer T21 of the second transistor, the active layer T31 of the third transistor, the active layer T81 of the eighth transistor, the active layer T111 of the eleventh transistor, and the active connection block AL may be individually provided.

In an exemplary implementation mode, as shown in FIG. 33, the active layer T91 of the ninth transistor and the active layer T101 of the fourth transistor are of an integral structure, and the active layer T121 of the twelfth transistor may be individually provided.

In an exemplary implementation mode, as shown in FIGS. 32 and 33, the active layer T11 of the first transistor and the active layer T61 of the sixth transistor (also the active layer T71 of the seventh transistor) are arranged along the second direction D2, and the active layer T11 of the first transistor of a current stage shift register unit is located at a side of the active layer T61 of the sixth transistor of the current stage shift register unit (which is also the active layer T71 of the seventh transistor) close to a previous stage shift register unit. The active layer T21 of the second transistor is located at a side of the active layer T11 of the first transistor close to the display region. The active layer T31 of the third transistor and the active connection block AL are arranged in the second direction D2, and are located at a side of the active layer T21 of the second transistor close to the display region. The active layer T81 of the eighth transistor, the active layer T111 of the eleventh transistor, and the active layer T41 of the fourth transistor (also the active layer T51 of the fifth transistor) are sequentially arranged along the second direction D2, and are located at a side of the active layer T31 of the third transistor close to the display region, wherein the active layer T111 of the eleventh transistor of the current stage shift register unit is located at a side of the active layer T81 of the eighth transistor of the current stage shift register unit close to a next stage shift register unit, the active layer T41 of the fourth transistor (also the fifth transistor T51 of the active layer) of the current stage shift register unit is located at a side of the active layer T111 of the eleventh transistor of the current stage shift register unit close to the next stage shift register unit.

In an exemplary implementation mode, as shown in FIG. 33, the active layer T121 of the twelfth transistor of the current stage shift register unit is located at a side of the active layer T81 of the eighth transistor of the current stage shift register unit close to the previous stage shift register unit. The active layer of the ninth transistor (which is also the active layer of the fourth transistor) of the current stage shift register unit is located at a side of the active layer T41 of the fourth transistor (which is also the active layer T51 of the fifth transistor) close to the display region.

In an exemplary implementation mode, as shown in FIGS. 32 and 33, the active layer T11 of the first transistor to the active layer T71 of the seventh transistor have a shape of a strip and extend along the first direction D1. The active layer T81 of the eighth transistor and the active layer T11 of the eleventh transistor have a shape of a strip and extend along the second direction D2. The active connection block AL may be in a shape of a block.

In an exemplary implementation mode, as shown in FIGS. 32 and 33, the active layer of the ninth transistor (which is also the active layer of the fourth transistor) has a shape of a strip and extends along the first direction D1. The active layer T121 of the twelfth transistor has a shape of a strip and extends in the second direction D2.

In an exemplary implementation mode, an active layer of each transistor may include a first region, a second region, and a channel region located between the first region and the second region. Herein, the first region and the second region are made to be conductive after the substantially first conductive layer is formed, so they may also be called conductive regions. In an exemplary implementation mode, the second region T61-2 of the active layer T61 of the sixth transistor may simultaneously serve as the first region T71-2 of the active layer T31 of the seventh transistor, the second region T41-2 of the active layer T41 of the fourth transistor may simultaneously serve as the second region T51-2 of the active layer T51 of the fifth transistor, and the second region T91-2 of the active layer T91 of the ninth transistor may simultaneously serve as the second region T101-2 of the active layer T101 of the fourth transistor. The first region T11-1 and the second region T11-2 of the active layer T11 of the first transistor, the first region T21-1 and the second region T21-2 of the active layer T21 of the second transistor, the first region T31-1 and the second region T31-2 of the active layer T31 of the third transistor, the first region T41-1 of the active layer T41 of the fourth transistor, the first region T51-1 of the active layer T51 of the fifth transistor, the first region T61-1 of the active layer T61 of the sixth transistor, the second region T71-2 of the active layer T71 of the seventh transistor, the first region T81-1 and the second region T81-2 of the active layer T81 of the eighth transistor, the first region T91-1 of the active layer T91 of the ninth transistor, the first region T101-1 of the active layer T101 of the fourth transistor, the first region T111-1 and the second region T111-2 of the active layer T111 of the eleventh transistor and the first region T121-1 and the second region T121-2 of the active layer T121 of the twelfth transistor may be individually provided.

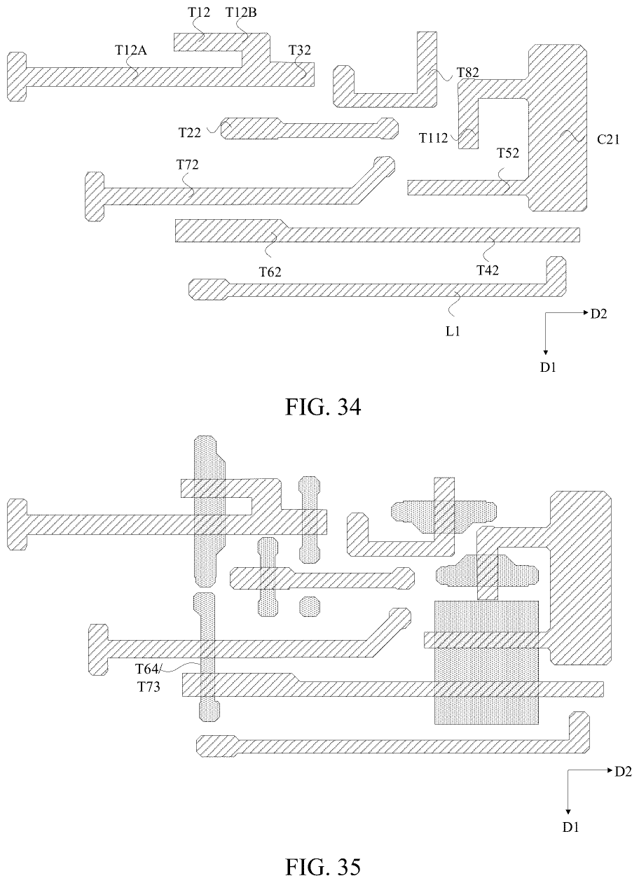

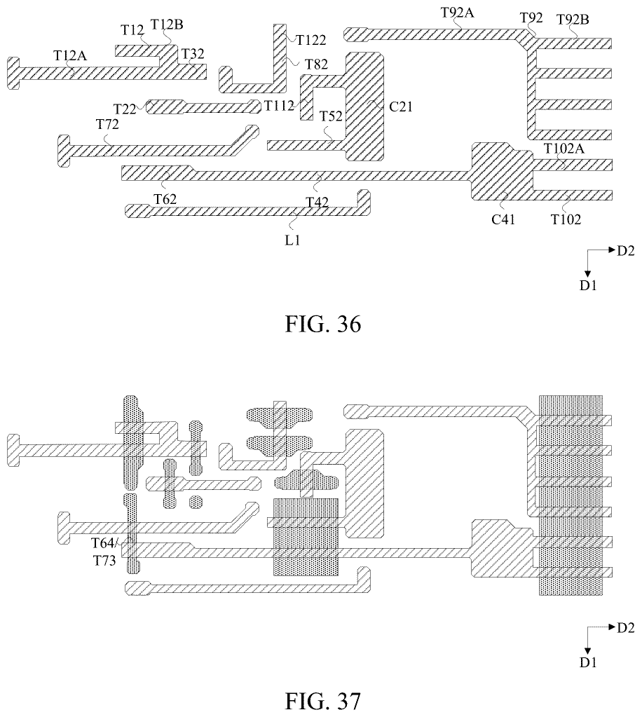

(2) Forming a pattern of a first conductive layer, includes: depositing a first insulating thin film and a first conductive thin film on the base substrate on which the aforementioned patterns are formed, patterning the first insulating thin film and the first conductive thin film through a patterning process to form a pattern of a first insulation layer and the pattern of the first conductive layer disposed on the pattern of the first insulation layer, as shown in FIGS. 34 to 37. FIG. 34 is a schematic diagram of a pattern of a first conductive layer in FIG. 30, FIG. 35 is a schematic diagram after a pattern of a first conductive layer is formed in FIG. 30, FIG. 36 is a schematic diagram of a pattern of a first conductive layer in FIG. 31, and FIG. 37 is a schematic diagram after a pattern of a first conductive layer is formed in FIG. 31. In an exemplary implementation mode, the first conductive layer may be referred to as a first gate metal (GATE1) layer.

In an exemplary implementation mode, as shown in FIGS. 34 and 35, the pattern of the first conductive layer may include the control electrode T12 of the first transistor to the control electrode T82 of the eighth transistor, the control electrode T112 of the eleventh transistor, the first plate C21 of the second capacitor located in at least one shift register unit, and a first connection line L1.

In an exemplary implementation mode, as shown in FIGS. 36 and 37, the pattern of the first conductive layer may include the control electrode T12 of the first transistor to the control electrode T122 of the twelfth transistor, the first plate C21 of the second capacitor, the first plate C41 of the fourth capacitor located in at least one shift register unit, and a first connection line L1.

In an exemplary implementation mode, as shown in FIGS. 34 to 37, the control electrode T12 of the first transistor and the control electrode T32 of the third transistor are of an integral structure. The control electrode T52 of the fifth transistor, the control electrode T112 of the eleventh transistor, and the first plate C21 of the second capacitor are of an integral structure. The control electrode T42 of the fourth transistor and the control electrode T62 of the sixth transistor are of an integral structure. The control electrode T22 of the second transistor, the control electrode T72 of the seventh transistor, the control electrode T82 of the eighth transistor, and the first connection line L1 may be individually provided.

In an exemplary implementation mode, as shown in FIGS. 36 and 37, the control electrode T42 of the fourth transistor, the control electrode T62 of the sixth transistor, the control electrode T102 of the fourth transistor, and the first plate C41 of the fourth capacitor are of an integral structure. The control electrode T82 of the eighth transistor and the control electrode T122 of the twelfth transistor are of an integral structure. The control electrode T92 of the ninth transistor may be individually provided.

In an exemplary implementation mode, as shown in FIGS. 34 to 37, the control electrode T12 of the first transistor includes a first connection portion T12A and a second connection portion T12B, the first connection portion T12A extends in the first direction D1, the second connection portion T12B has a shape of “¬”, and the second connection portion T12B is connected to a middle portion of the first connection portion T12A. The control electrode T32 of the third transistor may be in a shape of a strip and extend along the second direction D2. The control electrode T32 of the third transistor is connected to an end of the second connection portion T12B.

In an exemplary implementation mode, as shown in FIGS. 34 to 37, the first plate C21 of the second capacitor may have a shape of a square, the control electrode T52 of the fifth transistor may be in a shape of a strip and extend along the second direction D2, the control electrode T112 of the eleventh transistor is in a shape of a “┌”, and the control electrode T52 of the fifth transistor and the control electrode T112 of the eleventh transistor are located at a side of the first plate C21 of the second capacitor away from the display region.

In an exemplary implementation mode, as shown in FIGS. 34 and 35, the control electrode T42 of the fourth transistor (which is also the control electrode T62 of the sixth transistor) has a shape of a strip and extends in the second direction D2.

In an exemplary implementation mode, as shown in FIGS. 36 and 37, the first plate C41 of the fourth capacitor may have a shape of a square, and the control electrode T102 of the fourth transistor includes a plurality of first branch segments T102A, a first branch segment T102A extends in the second direction D2, and the plurality of first branch segments T102A are arranged in the first direction D1. The control electrode T62 of the sixth transistor and the control electrode T42 of the fourth transistor are located at a side of the first plate C41 of the fourth capacitor away from the display region, and the control electrode T102 of the fourth transistor is located at a side of the first plate C41 of the fourth capacitor close to the display region. FIGS. 36 and 37 are illustrated by taking 2 first branch segments T102A as an example.

In an exemplary implementation mode, as shown in FIGS. 34 to 37, the control electrode T82 of the eighth transistor may be in shape of a groove with an upward opening.

In an exemplary implementation mode, as shown in FIGS. 36 and 37, the control electrode T122 of the twelfth transistor has a shape of a strip and extends in the first direction D1.

In an exemplary implementation mode, as shown in FIGS. 36 and 37, the control electrode T92 of the ninth transistor includes a second connection segment T92A and a plurality of second branch segments T92B. The second connection section T92A has a shape of “¬”, a second branch section T92B extends in the second direction D2, and the plurality of second branch sections T92B are arranged in the first direction D1. The second connection segment T92A corresponds to a “comb back”, and the plurality of second branch segments T92B correspond to “comb teeth”.

In an exemplary implementation mode, as shown in FIGS. 34 to 37, the control electrode T22 of the second transistor, the control electrode T72 of the seventh transistor, and the first connection line L1 may be in a shape of a strip, and at least partially extend along the second direction D2.

In an exemplary implementation mode, the first connection segment T12A and the second connection segment T12B of the control electrode T12 of the first transistor are respectively disposed across the active layer of the first transistor, the control electrode T22 of the second transistor is disposed across the active layer of the second transistor, the control electrode T32 of the third transistor is disposed across the active layer of the third transistor, the control electrode T42 of the fourth transistor is disposed across the active layer of the fourth transistor, the control electrode T52 of the fifth transistor is disposed across the active layer of the fifth transistor, the control electrode T62 of the sixth transistor is disposed across the active layer of the sixth transistor, the control electrode T72 of the seventh transistor is disposed across the active layer of the seventh transistor, the control electrode T82 of the eighth transistor is disposed across the active layer of the eighth transistor, the plurality of second branch segments T92B of the control electrode T92 of the ninth transistor are disposed across the active layer of the ninth transistor, the plurality of first branch segments T102A of the control electrode T102 of the fourth transistor are disposed across the active layer of the fourth transistor, the control electrode T112 of the eleventh transistor is disposed across the active layer of the eleventh transistor, and the control electrode T122 of the twelfth transistor is disposed across the active layer of the twelfth transistor, that is, the extension direction of a control electrode of at least one transistor and the extension direction of an active layer of the at least one transistor are mutually perpendicular to each other.

In an exemplary implementation mode, this process further includes a conductorization treatment. The conductorization process includes, after the first conductive layer is formed, using the semiconductor layer in an area blocked by control electrodes of a plurality of transistors (i.e., an area where the semiconductor layer is overlapped with the control electrodes) as channel regions of the transistors, and the semiconductor layer which is not blocked by the first conductive layer is processed to become a conductorization layer to form electrode connection parts of the transistors. As shown in FIG. 24, an active connection line AL in the present disclosure is processed to become a conductorization layer to form the conductorized active connection line AL, and the second region of the active layer of the sixth transistor (also the first region of the active layer of the seventh transistor) after conductorization may be reused as the second electrode T64 of the sixth transistor and the first electrode T73 of the seventh transistor.

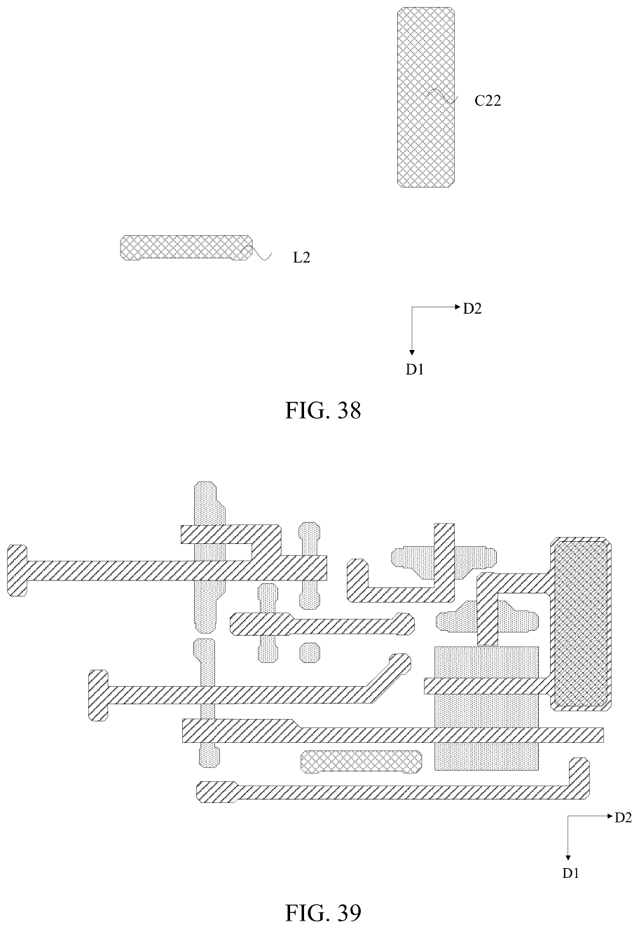

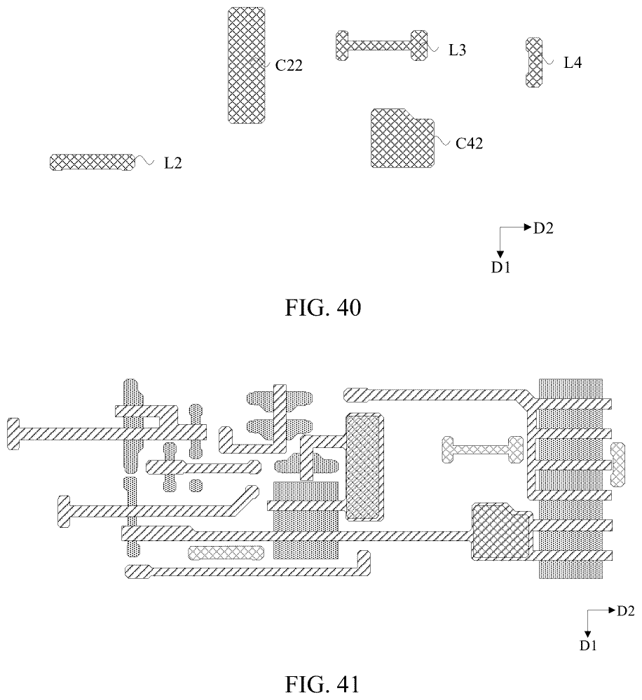

(3) Forming a pattern of a second conductive layer, includes: depositing a second insulating thin film and a second conductive thin film on the base substrate on which the aforementioned patterns are formed, patterning the second insulating thin film and the second conductive thin film through a patterning process to form a pattern of a second insulation layer and a pattern of a second conductive layer on the pattern of the second insulation layer, as shown in FIGS. 38 to 41. FIG. 38 is a schematic diagram of a pattern of a second conductive layer in FIG. 30, FIG. 39 is a schematic diagram after a pattern of a second conductive layer is formed in FIG. 30, FIG. 40 is a schematic diagram of a pattern of a second conductive layer in FIG. 31, and FIG. 41 is a schematic diagram after a pattern of a second conductive layer is formed in FIG. 31. In an exemplary implementation mode, the second conductive layer may be referred to as a second gate metal (GATE2) layer.

In an exemplary implementation mode, as shown in FIGS. 38 and 39, the pattern of the second conductive layer may include a second plate C22 of the second capacitor and a second connection line L2 located in at least one shift register unit.

In an exemplary implementation mode, as shown in FIGS. 40 and 41, the pattern of the second conductive layer may include a second plate C22 of the second capacitor, a second plate C42 of the fourth capacitor, a second connection line L2, a third connection line L3, and a fourth connection line L4 located in least one shift register unit.

In an exemplary implementation mode, as shown in FIGS. 38 to 41, the second plate C22 of the second capacitor is in a shape of a square, and an orthographic projection of the second plate C22 of the second capacitor on the base substrate is at least partially overlapped with an orthographic projection of the first plate of the second capacitor on the base substrate.

In an exemplary implementation mode, as shown in FIGS. 40 and 41, the second plate C42 of the fourth capacitor is in a shape of a square, and an orthographic projection of the second plate C42 of the fourth capacitor on the base substrate is at least partially overlapped with an orthographic projection of the first plate of the fourth capacitor on the base substrate.

In an exemplary implementation mode, as shown in FIGS. 38 to 41, the second connection line L2 may be in a shape of a strip and extend at least partially along the second direction D2.

In an exemplary implementation mode, as shown in FIGS. 40 and 41, the third connection line L3 may have a shape of a strip and extend at least partially along the second direction D2. The fourth connection line L4 may be in a shape of a strip, and at least partially extends in the first direction D1.

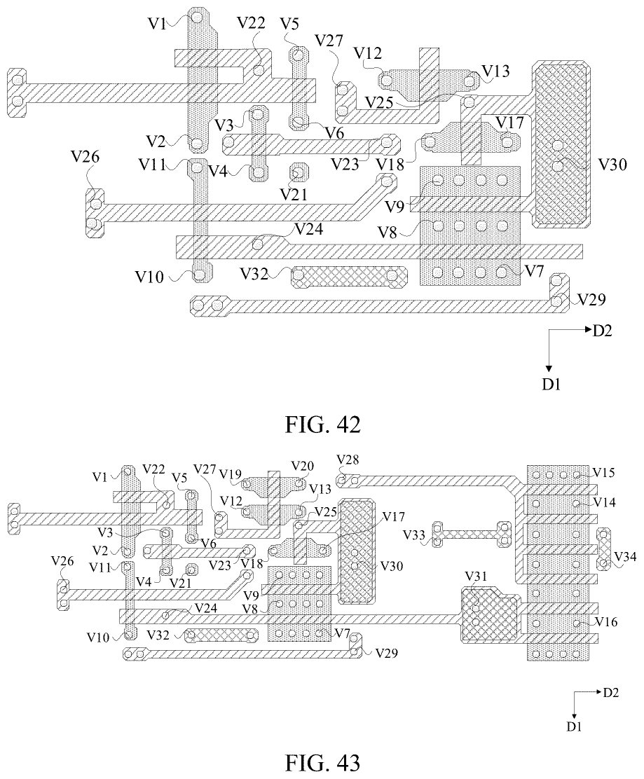

(4) Forming a pattern of a third insulation layer includes: depositing a third insulating thin film on the base substrate, on which the aforementioned patterns are formed, and patterning the third insulating thin film through the patterning processes to form the pattern of the third insulation layer overlaying the aforementioned structures. A pattern of a plurality of vias is provided in the third insulation layer, as shown in FIGS. 42 and 43. FIG. 42 is a schematic diagram after a pattern of a third insulation layer is formed in FIG. 30; and FIG. 43 is a schematic diagram after a pattern of a third insulation layer is formed in FIG. 31.

In an exemplary implementation mode, as illustrated in FIG. 42, the pattern of the plurality of vias may include a first via V1 to a thirteenth via V13, a seventeenth via V17, an eighteenth via V18, a twenty-first via V21 to a twenty-seventh via V27, a twenty-ninth via V29, a thirtieth via V30, and a thirty-second via V32.

In an exemplary implementation mode, as illustrated in FIG. 43, the pattern of the plurality of vias may include a first via V1 to a thirty-fourth via V34.

In an exemplary implementation mode, an orthographic projection of the first via V1 on the base substrate is within a range of an orthographic projection of a first region of an active layer of the first transistor on the base substrate, the first insulation layer and the second insulation layer within the first via V1 is etched away to expose a surface of the first region of the active layer of the first transistor, and the first via V1 is configured to enable a first electrode of a subsequently formed first transistor to be connected with the first region of the active layer of the first transistor through the via.

In an exemplary implementation mode, an orthographic projection of the second via V2 on the base substrate is within a range of an orthographic projection of a second region of an active layer of the first transistor on the base substrate, the first insulation layer and the second insulation layer within the second via V2 are etched away to expose a surface of the second region of the active layer of the first transistor, the second via V2 is configured to enable a second electrode of a subsequently formed first transistor (also a second electrode of the seventh transistor) to be connected with the second region of the active layer of the first transistor through the via.

In an exemplary implementation mode, an orthographic projection of the third via V3 on the base substrate is within a range of an orthographic projection of a first region of an active layer of the second transistor on the base substrate, the first insulation layer and the second insulation layer within the third via V3 are etched away to expose a surface of the first region of the active layer of the second transistor, and the third via V3 is configured to enable a first electrode of a subsequently formed second transistor to be connected with the first region of the active layer of the second transistor through the via.

In an exemplary implementation mode, an orthographic projection of the fourth via V4 on the base substrate is within a range of an orthographic projection of a second region of an active layer of the second transistor on the base substrate, the first insulation layer and the second insulation layer within the fourth via V4 are etched away to expose a surface of the second region of the active layer of the second transistor, the fourth via V4 is configured to enable a second electrode of a subsequently formed second transistor (also a second electrode of the third transistor) to be connected with the second region of the active layer of the second transistor through the via.

In an exemplary implementation mode, an orthographic projection of the fifth via V5 on the base substrate is within a range of an orthographic projection of a first region of an active layer of the third transistor on the base substrate, the first insulation layer and the second insulation layer within the fifth via V5 are etched away to expose a surface of the first region of the active layer of the third transistor, and the fifth via V5 is configured to enable a first electrode of a subsequently formed third transistor to be connected with the first region of the active layer of the third transistor through the via.

In an exemplary implementation mode, an orthographic projection of the sixth via V6 on the base substrate is within a range of an orthographic projection of a second region of an active layer of the third transistor on the base substrate, the first insulation layer and the second insulation layer within the sixth via V6 are etched away to expose a surface of the second region of the active layer of the third transistor, the sixth via V6 is configured to enable a second electrode of a subsequently formed third transistor (also a second electrode of the second transistor) to be connected with the second region of the active layer of the third transistor through the via.

In an exemplary implementation mode, an orthographic projection of the seventh via V7 on the base substrate is within a range of an orthographic projection of a first region of an active layer of the fourth transistor on the base substrate, the first insulation layer and the second insulation layer within the seventh via V7 are etched away to expose a surface of the first region of the active layer of the fourth transistor, and the seventh via V7 is configured to enable a first electrode of a subsequently formed fourth transistor to be connected with the first region of the active layer of the fourth transistor through the via.

In an exemplary implementation mode, an orthographic projection of the eighth via V8 on the base substrate is within a range of an orthographic projection of a second region of an active layer of the fourth transistor (also a second region of an active layer of the fifth transistor) on the base substrate, the first insulation layer and the second insulation layer within the eighth via V8 are etched away to expose a surface of the second region of the active layer of the fourth transistor (also the second region of the active layer of the fifth transistor), the eighth via V8 is configured to enable a second electrode of a subsequently formed fourth transistor (which is also a second electrode of the fifth transistor) to be connected with the second region of the active layer of the fourth transistor (which is also the second region of the active layer of the fifth transistor) through the via.

In an exemplary implementation mode, an orthographic projection of the ninth via V9 on the base substrate is within a range of an orthographic projection of a first region of an active layer of the fifth transistor on the base substrate, the first insulation layer and the second insulation layer within the ninth via V9 are etched away to expose a surface of the first region of the active layer of the fifth transistor, and the ninth via V9 is configured to enable a first electrode of a subsequently formed fifth transistor to be connected with the first region of the active layer of the fifth transistor through the via.

In an exemplary implementation mode, an orthographic projection of the tenth via V10 on the base substrate is within a range of an orthographic projection of a first region of an active layer of the sixth transistor on the base substrate, the first insulation layer and the second insulation layer within the tenth via V10 are etched away to expose a surface of the first region of the active layer of the sixth transistor, and the tenth via V10 is configured to enable a first electrode of a subsequently formed sixth transistor to be connected with the first region of the active layer of the sixth transistor through the via.

In an exemplary implementation mode, an orthographic projection of the eleventh via V11 on the base substrate is within a range of an orthographic projection of a second region of an active layer of the seventh transistor on the base substrate, the first insulation layer and the second insulation layer in the eleventh via V11 are etched away to expose a surface of the second region of the active layer of the seventh transistor, the eleventh via V11 is configured to enable a second electrode of a subsequently formed seventh transistor (also a second electrode of the first transistor) to be connected with the second region of the active layer of the seventh transistor through the via.

In an exemplary implementation mode, an orthographic projection of the twelfth via V12 on the base substrate is within a range of an orthographic projection of a first region of an active layer of the eighth transistor on the base substrate, the first insulation layer and the second insulation layer within the twelfth via V12 are etched away to expose a surface of the first region of the active layer of the eighth transistor, the twelfth via V12 is configured to enable a first electrode of a subsequently formed eighth transistor (also a second electrode of the eleventh transistor and a first electrode of the twelfth transistor) to be connected with the first region of the active layer of the eighth transistor through the via.

In an exemplary implementation mode, an orthographic projection of the thirteenth via V13 on the base substrate is within a range of an orthographic projection of a second region of an active layer of the eighth transistor on the base substrate, the first insulation layer and the second insulation layer within the thirteenth via V13 are etched away to expose a surface of the first region of the active layer of the eighth transistor, and the thirteenth via V13 is configured to enable a second electrode of a subsequently formed eighth transistor to be connected with the second region of the active layer of the eighth transistor through the via.

In an exemplary implementation mode, an orthographic projection of the fourteenth via V14 on the base substrate is within a range of an orthographic projection of a first region of an active layer of the ninth transistor on the base substrate, the first insulation layer and the second insulation layer within the fourteenth via V14 are etched away to expose a surface of the first region of the active layer of the ninth transistor, and the fourteenth via V14 is configured to enable a first electrode of a subsequently formed ninth transistor to be connected with the first region of the active layer of the ninth transistor through the via.

In an exemplary implementation mode, an orthographic projection of the fifteenth via V15 on the base substrate is within a range of an orthographic projection of a second region of an active layer of the ninth transistor (also a second region of an active layer of the fourth transistor) on the base substrate, the first insulation layer and the second insulation layer in the fifteenth via V15 are etched away to expose a surface of the second region of the active layer of the ninth transistor (also the second region of the active layer of the fourth transistor), the fifteenth via V15 is configured to enable a second electrode of a subsequently formed ninth transistor (which is also a second electrode of the fourth transistor) to be connected with the second region of the active layer of the ninth transistor (which is also the second region of the active layer of the fourth transistor) through the via.

In an exemplary implementation mode, an orthographic projection of the sixteenth via V16 on the base substrate is within a range of an orthographic projection of a first region of an active layer of the fourth transistor on the base substrate, the first insulation layer and the second insulation layer within the sixteenth via V16 are etched away to expose a surface of the first region of the active layer of the fourth transistor, and the sixteenth via V16 is configured to enable a first electrode of a subsequently formed fourth transistor to be connected with the first region of the active layer of the fourth transistor through the via.

In an exemplary implementation mode, an orthographic projection of the seventeenth via V17 on the base substrate is within a range of an orthographic projection of a first region of an active layer of the eleventh transistor on the base substrate, the first insulation layer and the second insulation layer within the seventeenth via V17 are etched away to expose a surface of the first region of the active layer of the eleventh transistor, and the seventeenth via V17 is configured to enable a first electrode of a subsequently formed eleventh transistor to be connected with the first region of the active layer of the eleventh transistor through the via.

In an exemplary implementation mode, an orthographic projection of the eighteenth via V18 on the base substrate is within a range of an orthographic projection of a second region of an active layer of the eleventh transistor on the base substrate, the first insulation layer and the second insulation layer in the eighteenth via V18 are etched away to expose a surface of the first region of the active layer of the eleventh transistor, the eighteenth via V18 is configured to enable a second electrode of a subsequently formed eleventh transistor (also a first electrode of the eighth transistor and a first electrode of the twelfth transistor) to be connected with the second region of the active layer of the eleventh transistor through the via.

In an exemplary implementation mode, an orthographic projection of the nineteenth via V19 on the base substrate is within a range of an orthographic projection of a first region of an active layer of the twelfth transistor on the base substrate, the first insulation layer and the second insulation layer within the nineteenth via V19 are etched away to expose a surface of the first region of the active layer of the twelfth transistor, the nineteenth via V19 is configured to enable a first electrode of a subsequently formed twelfth transistor (also a second electrode of the eleventh transistor and a first electrode of the eighth transistor) to be connected with the first region of the active layer of the twelfth transistor through the via.

In an exemplary implementation mode, an orthographic projection of the twentieth via V20 on the base substrate is within a range of an orthographic projection of a second region of an active layer of the twelfth transistor on the base substrate, the first insulation layer and the second insulation layer within the twentieth via V20 are etched away to expose a surface of the first region of the active layer of the twelfth transistor, and the twentieth via V20 is configured to enable a second electrode of a subsequently formed twelfth transistor to be connected with the second region of the active layer of the twelfth transistor through the via.

In an exemplary implementation mode, an orthographic projection of the twenty-first via V21 on the base substrate is within a range of an orthographic projection of an active connection portion on the base substrate, the first insulation layer and the second insulation layer in the twenty-first via V21 are etched away to expose a surface of the active connection portion, the twenty-first via V21 is configured to enable a second electrode of a subsequently formed second transistor (also a second electrode of the third transistor) to be connected with the active connection portion through the via.

In an exemplary implementation mode, an orthographic projection of the twenty-second via V22 onto the base substrate is within a range of an orthographic projection of a control electrode of the first transistor (also a control electrode of the third transistor) on the base substrate, the second insulation layer within the twenty-second via V22 is etched away to expose a surface of the control electrode of the first transistor (also the control electrode of the third transistor), the twenty-second via V22 is configured to enable one of subsequently formed first and second clock signal lines and a first electrode of the second transistor to be connected with the control electrode of the first transistor (also the control electrode of the third transistor) through the via.

In an exemplary implementation mode, an orthographic projection of the twenty-third via V23 on the base substrate is within a range of an orthographic projection of a control electrode of the second transistor on the base substrate, the second insulation layer in the twenty-third via V23 is etched away to expose a surface of the control electrode of the second transistor, the twenty-third via V23 is configured to enable a second electrode of a subsequently formed first transistor (also a first electrode of the seventh transistor) and a first electrode of a subsequently formed eighth transistor (also a second electrode of the eleventh transistor and a first electrode of the twelfth transistor) to be connected with the control electrode of the second transistor through the via.

In an exemplary implementation mode, an orthographic projection of the twenty-fourth via V24 on the base substrate is within a range of an orthographic projection of a control electrode of the fourth transistor (also a control electrode of the sixth transistor, a control electrode of the fourth transistor, and a first plate of the fourth capacitor) on the base substrate, the second insulation layer within the twenty-fourth via V24 is etched away to expose a surface of the control electrode of the fourth transistor (also the control electrode of the sixth transistor, the control electrode of the fourth transistor and the first plate of the fourth capacitor), the twenty-fourth via V24 is configured to enable a second electrode of a subsequently formed second transistor (also a second electrode of the third transistor) to be connected with the control electrode of the fourth transistor (also the control electrode of the sixth transistor, the control electrode of the fourth transistor, and the first plate of the fourth capacitor) through the via.

In an exemplary implementation mode, an orthographic projection of the twenty-fifth via V25 on the base substrate is within a range of an orthographic projection of a control electrode of the fifth transistor (also a control electrode of the eleventh transistor and a first plate of the second capacitor) on the base substrate, the second insulation layer in the twenty-fifth via V25 is etched away to expose a surface of the control electrode of the fifth transistor (also the control electrode of the eleventh transistor and the first plate of the second capacitor), the twenty-fifth via V25 is configured to enable a second electrode of a subsequently formed eighth transistor to be connected with the control electrode of the fifth transistor (also the control electrode of the eleventh transistor and the first plate of the second capacitor) through the via.

In an exemplary implementation mode, an orthographic projection of the twenty-sixth via V26 on the base substrate is within a range of an orthographic projection of a control electrode of the seventh transistor on the base substrate, the second insulation layer within the twenty-sixth via V26 is etched away to expose a surface of the control electrode of the seventh transistor, and the twenty-sixth via V26 is configured to enable the other of the subsequently formed first and second clock signal lines and a first electrode of the fifth transistor to be connected with the control electrode of the seventh transistor through the via.

In an exemplary implementation mode, an orthographic projection of the twenty-seventh via V27 on the base substrate is within a range of an orthographic projection of a control electrode of the eighth transistor (also a control electrode of the twelfth transistor) on the base substrate, the second insulation layer in the twenty-seventh via V27 is etched away to expose a surface of the control electrode of the eighth transistor (which is also the control electrode of the twelfth transistor), and the twenty-seventh via V27 is configured to enable a subsequently formed first second power supply line to be connected with the control electrode of the eighth transistor (which is also the control electrode of the twelfth transistor) through the via.

In an exemplary implementation mode, an orthographic projection of the twenty-eighth via V28 on the base substrate is within a range of an orthographic projection of a control electrode of the ninth transistor on the base substrate, the second insulation layer within the twenty-eighth via V28 is etched away to expose a surface of the control electrode of the ninth transistor, and the twenty-eighth via V28 is configured to enable a second electrode of a subsequently formed twelfth transistor to be connected with the control electrode of the ninth transistor through the via.

In an exemplary implementation mode, an orthographic projection of the twenty-ninth via V29 on the base substrate is within a range of an orthographic projection of the first connection line on the base substrate, the second insulation layer in the twenty-ninth via V29 is etched away to expose a surface of the first connection line, the twenty-ninth via V29 is configured to enable a second electrode of the fourth transistor (also a second electrode of the fifth transistor) of a subsequently formed current stage shift register unit and a first electrode of the first transistor of a next stage shift register unit to be connected with the first connection line through the via.

In an exemplary implementation mode, an orthographic projection of the thirtieth via V30 on the base substrate is within a range of an orthographic projection of a second plate of the second capacitor on the base substrate, the thirtieth via V30 exposes a surface of the second plate of the second capacitor, the thirtieth via V30 is configured to enable a second electrode of a subsequently formed fourth transistor (also a second electrode of the fifth transistor) to be connected with the second plate of the second capacitor through the via.

In an exemplary implementation mode, an orthographic projection of the thirty-first via V31 on the base substrate is located within a range of an orthographic projection of a second plate of the fourth capacitor on the base substrate, the thirty-first via V31 exposes a surface of the second plate of the fourth capacitor, and the thirty-first via V31 is configured to enable a subsequently formed second second power supply line to be connected with the second plate of the fourth capacitor through the via.

In an exemplary implementation mode, an orthographic projection of the thirty-second via V32 on the base substrate is within a range of an orthographic projection of the second connection line on the base substrate, the thirty-second via V32 exposes a surface of the second connection line, and the thirty-second via V32 is configured to enable a first electrode of a subsequently formed sixth transistor and a first electrode of a subsequently formed fourth transistor to be connected with the second connection line through the via.

In an exemplary implementation mode, an orthographic projection of the thirty-third via V33 on the base substrate is located within a range of an orthographic projection of the third connection line on the base substrate, the thirty-third via V33 exposes a surface of the third connection line, and the thirty-third via V33 is configured to enable a first electrode of a subsequently formed ninth transistor and one of the third clock signal line and the fourth clock signal line to be connected with the third connection line through the via.

In an exemplary implementation mode, an orthographic projection of the thirty-fourth via V34 on the base substrate is within a range of an orthographic projection of the fourth connection line on the base substrate, the thirty-fourth via V34 exposes a surface of the fourth connection line, the thirty-fourth via V34 is configured to enable a second electrode of a subsequently formed ninth transistor (which is also a second electrode of the fourth transistor) to be connected with the fourth connection line through the via.

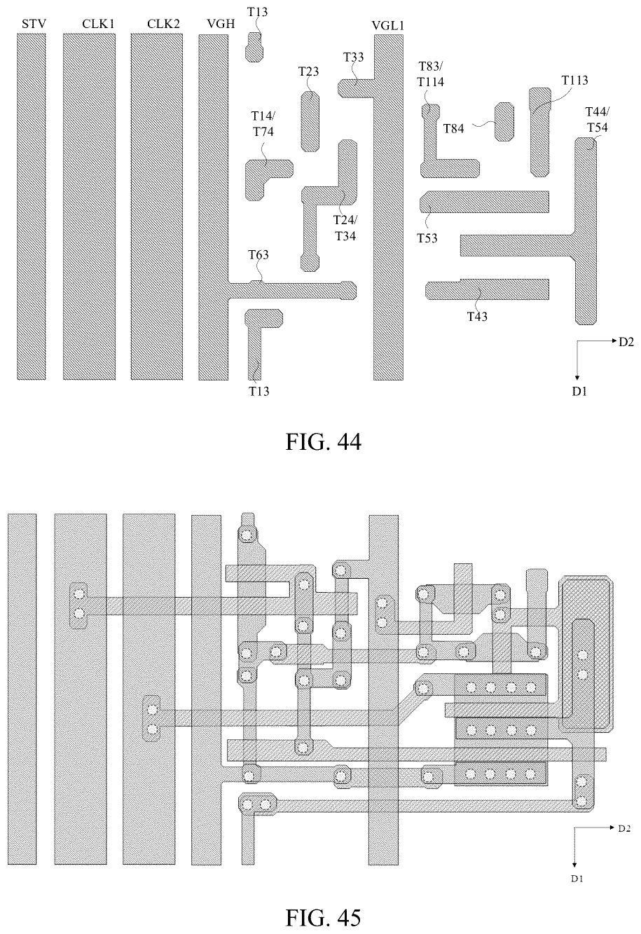

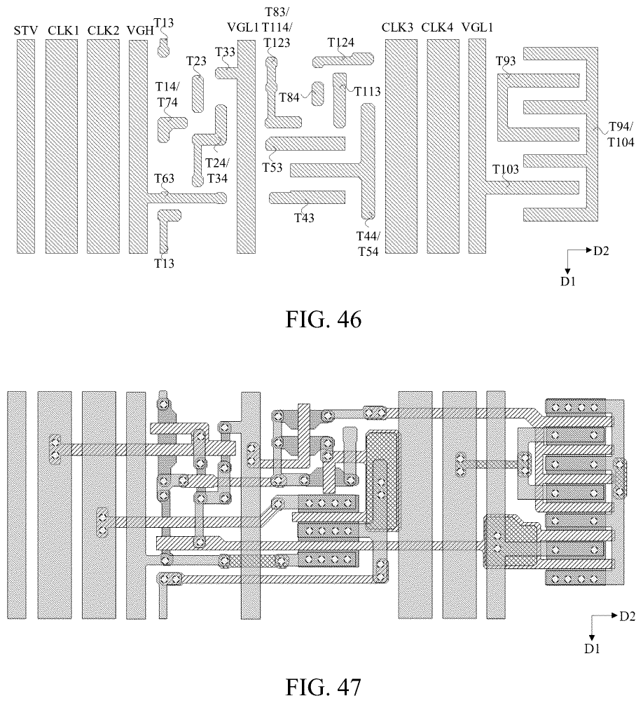

(5) Forming a pattern of a third conductive layer, includes: depositing a third metal thin film on the base substrate on which the aforementioned patterns are formed, patterning the third metal thin film through a patterning process to form a pattern of a third metal layer, as shown in FIGS. 44 to 47. FIG. 44 is a schematic diagram of a pattern of a third conductive layer in FIG. 30, FIG. 45 is a schematic diagram after a pattern of a third conductive layer is formed in FIG. 30, FIG. 46 is a schematic diagram of a pattern of a third conductive layer in FIG. 31, and FIG. 47 is a schematic diagram after a pattern of a third conductive layer is formed in FIG. 31. In an exemplary implementation, the third conductive layer may be referred to as a first source-drain metal (SD1) layer.

In an exemplary implementation mode, as illustrated in FIGS. 44 and 45, the pattern of the third conductive layer may include an initial signal line STV, a first clock signal line CLK1, a second clock signal line CLK2, a first power supply line VGH, a second power supply line VGL1, and a first electrode T13 and a second electrode T14 of the first transistor to a first electrode T83 and a second electrode T83 of the eighth transistor, and a first electrode T113 and a second electrode 114 of the eleventh transistor located in least one shift register unit.

In an exemplary implementation mode, as illustrated in FIGS. 46 and 47, the pattern of the third conductive layer may include an initial signal line STV, a first clock signal line CLK1, a second clock signal line CLK2, a third clock signal line CLK3, a fourth clock signal line CLK4, a first power supply line VGH, two second power supply lines VGL1, and a first electrode T13 and a second electrode T14 of the first transistor to a first electrode T123 and a second electrode 124 of the twelfth transistor located in least one shift register unit.

In an exemplary implementation mode, as shown in FIGS. 44 to 47, the second electrode T14 of the first transistor and the second electrode T74 of the seventh transistor are of an integral structure. The second electrode T24 of the second transistor and the second electrode T34 of the third transistor are of an integral structure. The second electrode T44 of the fourth transistor and the second electrode T54 of the fifth transistor are of an integral structure. The first power supply line VGH and the first electrode T63 of the sixth transistor are of an integral structure. The first second power supply line VGL1 and the first electrode T33 of the third transistor are of an integral structure. The second second power supply line VGL1 and the first electrode T103 of the fourth transistor are of an integral structure.

In an exemplary implementation mode, as shown in FIGS. 44 and 45, the first electrode T83 of the eighth transistor and the second electrode T114 of the eleventh transistor are of an integral structure. The second power supply line VGL1 and the first electrode T33 of the third transistor are of an integral structure.

In an exemplary implementation mode, as shown in FIGS. 46 and 47, the first electrode T83 of the eighth transistor, the second electrode T114 of the eleventh transistor, and the first electrode T123 of the twelfth transistor are of an integral structure. The second electrode T94 of the ninth transistor and the second electrode T104 of the fourth transistor are of an integral structure. The first second power supply line VGL1 and the first electrode T33 of the third transistor are of an integral structure. The second second power supply line VGL1 and the first electrode T103 of the fourth transistor are of an integral structure.

In an exemplary implementation mode, as shown in FIGS. 44 and 45, the initial signal line STV, the first clock signal line CLK1, the second clock signal line CLK2, the first power supply line VGH, and the second power supply line VGL1 are arranged sequentially along a side close to the display region. Any one of the initial signal line STV, the first clock signal line CLK1, the second clock signal line CLK2, the first power supply line VGH, and the second power supply line VGL1 extends in the first direction D1.

In an exemplary implementation mode, as shown in FIGS. 46 and 47, the initial signal line STV, the first clock signal line CLK1, the second clock signal line CLK2, the first power supply line VGH, the first second power supply line VGL1, the third clock signal line CLK3, the fourth clock signal line CLK4, and the second second power supply line VGL1 are arranged sequentially along a side close to the display region. Any one of the initial signal line STV, the first clock signal line CLK1, the second clock signal line CLK2, the first power supply line VGH, the first second power supply line VGL1, the third clock signal line CLK3, the fourth clock signal line CLK4, and the second second power supply line VGL1 extends in the first direction D1.

In an exemplary implementation mode, as shown in FIGS. 44 to 47, the first electrode T13 of the first transistor may be in a shape of a square and extend along the first direction D1. The first electrode T13 of the first transistor is connected to the first region of the active layer of the first transistor through the first via, and is connected to the first connection line located in a previous stage shift register unit through the twenty-ninth via of the previous stage shift register unit. As shown in FIGS. 44 and 45, the first electrode T13 of the first transistor is located between the first power supply line VGH and the second power supply line VGL1, and as shown in FIGS. 46 and 47, the first electrode T13 of the first transistor is located between the first power supply line VGH and the first second power supply line VGL1.

In an exemplary implementation mode, as shown in FIGS. 44 to 47, the second electrode T14 of the first transistor (which is also the second electrode T74 of the seventh transistor) may be in a shape of “┌”. The second electrode T14 of the first transistor (also the second electrode T74 of the seventh transistor) is connected to the second region of the active layer of the first transistor through the second via and to the second region of the active layer of the seventh transistor through the eleventh via V11, and is connected to the control electrode of the second transistor through the twenty-third via. As shown in FIGS. 44 and 45, the second electrode T14 of the first transistor (also the second electrode T74 of the seventh transistor) is located between the first power supply line VGH and the second power supply line VGL1. As shown in FIGS. 46 and 47, the second electrode T14 of the first transistor (also the second electrode T74 of the seventh transistor) is located between the first power supply line VGH and the first second power supply line VGL1.

In an exemplary implementation mode, as shown in FIGS. 44 to 47, the first electrode T23 of the second transistor may be in a shape of a strip and extend along the first direction D1. The first electrode T23 of the second transistor is connected to the first region of the active layer of the second transistor through the third via, and is connected to the control electrode of the first transistor (which is also the control electrode of the third transistor) through the twenty-second via. As shown in FIGS. 44 and 45, the first electrode T23 of the second transistor is located between the first power supply line VGH and the second power supply line VGL1, and as shown in FIGS. 46 and 47, the first electrode T23 of the second transistor is located between the first power supply line VGH and the first second power supply line VGL1.

In an exemplary implementation mode, as shown in FIGS. 44 to 47, the second electrode T24 of the second transistor (also the second electrode T34 of the third transistor) may be in a shape of a bending line and extend at least partially along the first direction D1. As shown in FIGS. 44 and 45, the second electrode T24 of the second transistor (also the second electrode T34 of the third transistor) is located between the first power supply line VGH and the second power supply line VGL1. The second electrode T24 of the second transistor (also the second electrode T34 of the third transistor) is connected to the second region of the active layer of the second transistor through the fourth via, is connected to the second region of the active layer of the third transistor through the sixth via, is connected to the active connection portion through the twenty-first via, and is connected to the control electrode of the fourth transistor (which is also the control electrode of the sixth transistor) through the twenty-fourth via. As shown in FIGS. 46 and 47, the second electrode T24 of the second transistor (also the second electrode T34 of the third transistor) is located between the first power supply line VGH and the first second power supply line VGL1. The second electrode T24 of the second transistor (also the second electrode T34 of the third transistor) is connected to the second region of the active layer of the second transistor through the fourth via, is connected to the second region of the active layer of the third transistor through the sixth via, is connected to the active connection portion through the twenty-first via, is connected to the control electrode of the fourth transistor (also the control electrode of the sixth transistor, the control electrode of the fourth transistor and the first plate of the fourth capacitor) through the twenty-fourth via.

In an exemplary implementation mode, as shown in FIGS. 44 to 47, the first electrode T33 of the third transistor may be in a shape of a strip and extend along the second direction D2. The first electrode T33 of the third transistor is connected to the first region of the active layer of the third transistor through the fifth via. As shown in FIGS. 44 and 45, the first electrode T33 of the third transistor is located between the first power supply line VGH and the second power supply line VGL1. As shown in FIGS. 46 and 47, the first electrode T33 of the third transistor is located between the first power supply line VGH and the first second power supply line VGL1.

In an exemplary implementation mode, as shown in FIGS. 44 to 47, the first electrode T43 of the fourth transistor may be in a shape of a strip and extend along the second direction D2. The first electrode T43 of the fourth transistor is connected to the first region of the active layer of the fourth transistor through the seventh via, and is connected to the second connection line through the thirty-second via. As shown in FIGS. 44 and 45, the first electrode T43 of the fourth transistor is located at a side of the second power supply line VGL1 close to the display region. As shown in FIGS. 46 and 47, the first electrode T43 of the fourth transistor is located between the first second power supply line VGL1 and the third clock signal line CLK3.

In an exemplary implementation mode, as shown in FIGS. 44 to 47, the second electrode T44 of the fourth transistor (which is also the second electrode T54 of the fifth transistor) may be in a shape of “┤”. The second electrode T44 of the fourth transistor (which is also the second electrode T54 of the fifth transistor) is connected to the second region of the active layer of the fourth transistor (which is also the second region of the active layer of the fifth transistor) through the eighth via, connected to the first connection line through the twenty-ninth via, and connected to the second plate of the second capacitor through the thirtieth via. As shown in FIGS. 44 and 45, the second electrode T44 of the fourth transistor (also the second electrode T54 of the fifth transistor) is located at a side of the second power supply line VGL1 close to the display region. As shown in FIGS. 46 and 47, the second electrode T44 of the fourth transistor (also the second electrode T54 of the fifth transistor) is located between the first second power supply line VGL1 and the third clock signal line CLK3.

In an exemplary implementation mode, as shown in FIGS. 44 to 47, the first electrode T53 of the fifth transistor may be in a shape of a strip and extend along the second direction D2. The first electrode T53 of the fifth transistor is connected to the first region of the active layer of the fifth transistor through the ninth via, and is connected to the control electrode of the seventh transistor through the twenty-sixth via. As shown in FIGS. 44 and 45, the first electrode T53 of the fifth transistor is located at a side of the second power supply line VGL1 close to the display region. As shown in FIGS. 46 and 47, the first electrode T53 of the fifth transistor is located between the first second power supply line VGL1 and the third clock signal line CLK3.

In an exemplary implementation mode, as shown in FIGS. 44 to 47, the first electrode T63 of the sixth transistor may be in a shape of a strip and extend along the second direction D2. The first electrode T63 of the sixth transistor is connected to the first region of the active layer of the sixth transistor through the tenth via, and is connected to the second connection line through the thirty-second via. As shown in FIGS. 44 and 45, the first electrode T63 of the sixth transistor is located between the first power supply line VGH and the second power supply line VGL1. As shown in FIGS. 46 and 47, the first electrode T63 of the sixth transistor is located between the first power supply line VGH and the first second power supply line VGL1.

In an exemplary implementation mode, as shown in FIGS. 44 and 45, the first electrode T83 of the eighth transistor (which is also the second electrode T114 of the eleventh transistor) may be in an “L” shape. The first electrode T83 of the eighth transistor (also the second electrode T114 of the eleventh transistor) is located at a side of the second power supply line VGL1 close to the display region. The first electrode T83 of the eighth transistor (also the second electrode T114 of the eleventh transistor) is connected to the first region of the active layer of the eighth transistor through the twelfth via, s connected to the second region of the active layer of the eleventh transistor through the eighteenth via, and is connected to the control electrode of the second transistor through the twenty-third via.

In an exemplary implementation mode, as shown in FIGS. 46 and 47, the first electrode T83 of the eighth transistor (also the second electrode T114 of the eleventh transistor and the first electrode T123 of the twelfth transistor) may be in an “L” shape. The first electrode T83 of the eighth transistor (also the second electrode T114 of the eleventh transistor and the first electrode T123 of the twelfth transistor) is located between the first second power supply line VGL1 and the third clock signal line CLK3. The first electrode T83 of the eighth transistor (also the second electrode T114 of the eleventh transistor and the first electrode T123 of the twelfth transistor) is connected to the first region of the active layer of the eighth transistor through the twelfth via, is connected to the second region of the active layer of the eleventh transistor through the eighteenth via, is connected to the first region of the active layer of the twelfth transistor through the nineteenth via, and is connected to the control electrode of the second transistor through the twenty-third via.

In an exemplary implementation mode, as shown in FIGS. 44 to 47, the second electrode T84 of the eighth transistor may be in a shape of a strip and extend along the first direction D1. The second electrode T84 of the eighth transistor is connected to the second region of the active layer of the eighth transistor through the thirteenth via, and is connected to the control electrode of the fifth transistor (also the control electrode of the eleventh transistor and the first plate of the second capacitor) through the twenty-fifth via. As shown in FIGS. 44 and 45, the second electrode T84 of the eighth transistor is located at a side of the second power supply line VGL1 close to the display region. As shown in FIGS. 46 and 47, the second electrode T84 of the eighth transistor is located between the first second power supply line VGL1 and the third clock signal line CLK3.

In an exemplary implementation mode, as shown in FIGS. 46 and 47, the first electrode T93 of the ninth transistor may be in a “[” shape. The first electrode T93 of the ninth transistor is located at a side of the second second power supply line VGL1 close to the display region. The first electrode T93 of the ninth transistor is connected to the first region of the active layer of the ninth transistor through the fourteenth via, and is connected to the third connection line through the thirty-third via.

In an exemplary implementation mode, as shown in FIGS. 46 and 47, the first electrode T103 of the fourth transistor may be in a shape of a strip and extend along the first direction D1. The first electrode T103 of the fourth transistor is located at a side of the second second power supply line VGL1 close to the display region. The first electrode T103 of the fourth transistor is connected to the first region of the active layer of the fourth transistor through the sixteenth via.

In an exemplary implementation mode, as shown in FIGS. 46 and 47, the first electrode 94 of the ninth transistor (which is also the second electrode T104 of the fourth transistor) may be in a shape of a comb, wherein comb teeth are located on a side of the comb back away from the display region. The first electrode 94 of the ninth transistor (which is also the second electrode T104 of the fourth transistor) is located at a side of the second second power supply line VGL1 close to the display region. The first electrode 94 of the ninth transistor (also the second electrode T104 of the fourth transistor) is connected to the second region of the active layer of the ninth transistor (also the second region of the active layer of the fourth transistor) through the fifteenth via, and is connected to the fourth connection line through the thirty-fourth via.

In an exemplary implementation mode, as shown in FIGS. 44 to 47, the first electrode T113 of the eleventh transistor may be in a shape of a strip and extend along the first direction D1. The first electrode T113 of the eleventh transistor is connected to the first region of the active layer of the eleventh transistor through the seventeenth via. As shown in FIGS. 44 and 45, the first electrode T113 of the eleventh transistor is located at a side of the second power supply line VGL1 close to the display region. As shown in FIGS. 46 and 47, the first electrode T113 of the eleventh transistor is located between the first second power supply line VGL1 and the third clock signal line CLK3.

In an exemplary implementation mode, as shown in FIGS. 44 to 47, the second electrode T124 of the twelfth transistor may be in a shape of a strip and extend along the second direction D2. The second electrode T124 of the twelfth transistor is located between the first second power supply line VGL1 and the third clock signal line CLK3. The second electrode T124 of the twelfth transistor is connected to the second region of the active layer of the twelfth transistor through the twentieth via, and is connected to the control electrode of the ninth transistor through the twenty-eighth via.

In an exemplary implementation mode, as shown in FIGS. 44 to 47, the control electrode of the first transistor (which is also the control electrode of the third transistor) is connected to one of the first clock signal line CLK1 and the second clock signal line CLK2 through the twenty-second via. FIGS. 45 and 47 are illustrated by an example in which the control electrode of the first transistor (which is also the control electrode of the third transistor) is connected to the first clock signal line CLK1 through the twenty-second via.

In an exemplary implementation mode, as shown in FIGS. 44 to 47, the control electrode of the seventh transistor is connected to the other of the first clock signal line CLK1 and the second clock signal line CLK2 through the twenty-sixth via. FIGS. 45 and 47 are illustrated in an example in which the control electrode of the seventh transistor is connected to the second clock signal line CLK2 through the twenty-sixth via.

In an exemplary implementation mode, as shown in FIGS. 44 and 45, the control electrode of the eighth transistor (which is also the control electrode of the twelfth transistor) is connected to the second power supply line VGL1 through the twenty-seventh via.

In an exemplary implementation mode, as shown in FIGS. 46 and 47, the control electrode of the eighth transistor (which is also the control electrode of the twelfth transistor) is connected to the first second power supply line VGL1 through the twenty-seventh via.

In an exemplary implementation mode, as shown in FIGS. 46 and 47, the second plate of the fourth capacitor is connected to the second second power supply line VGL1 through the thirty-first via.

In an exemplary implementation mode, as shown in FIGS. 46 and 47, the third connection line is connected to one of the third clock signal line CLK3 and the fourth clock signal line CLK4 through the thirty-third via. FIG. 47 is illustrated by an example in which the third connection line is connected to the third clock signal line CLK3 through the thirty-third via.

In an exemplary implementation mode, as shown in FIG. 47, an orthographic projection of the second second power supply line VGL1 on the base substrate is partially overlapped with an orthographic projection of the fourth capacitor on the base substrate.

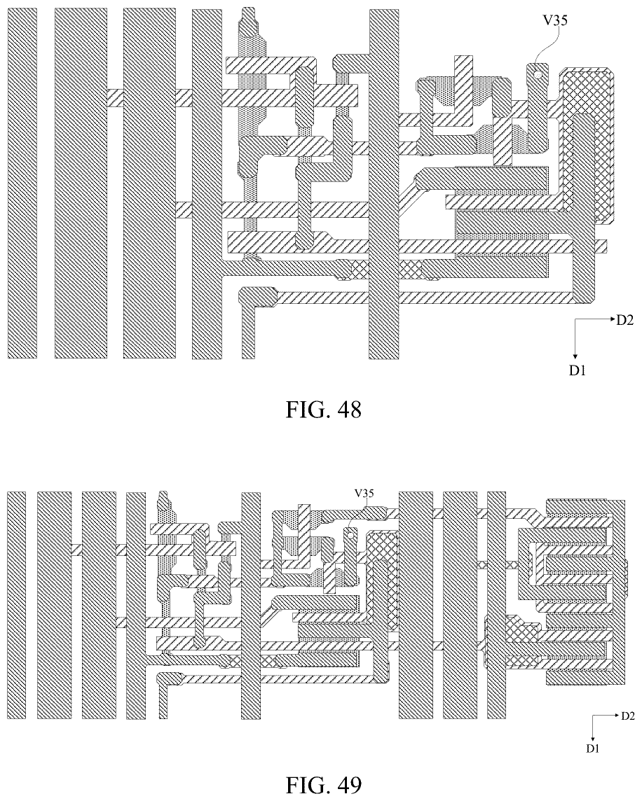

(6) Forming a pattern of a fourth insulation layer, which includes: depositing a fourth insulation thin film on the base substrate on which the aforementioned patterns are formed, and patterning the fourth insulation thin film through a patterning process to form the pattern of the fourth insulation layer overlaying the aforementioned structures, and the fourth insulation layer is provided with a pattern of vias, as shown in FIGS. 48 and 49. FIG. 48 is a schematic diagram after a pattern of a fourth insulation layer is formed in FIG. 30, and FIG. 49 is a schematic diagram after a pattern of a fourth insulation layer is formed in FIG. 31.

In an exemplary implementation mode, as shown in FIGS. 48 and 49, the pattern of vias may include a thirty-fifth via V35.

In an exemplary implementation mode, an orthographic projection of the thirty-fifth via V35 on the base substrate is within a range of an orthographic projection of a first electrode of the eleventh transistor on the base substrate, the thirty-fifth via V35 exposes a surface of the first electrode of the eleventh transistor, and the thirty-fifth via V35 is configured to enable a subsequently formed third power supply line to be connected with the first electrode of the eleventh transistor through the via.

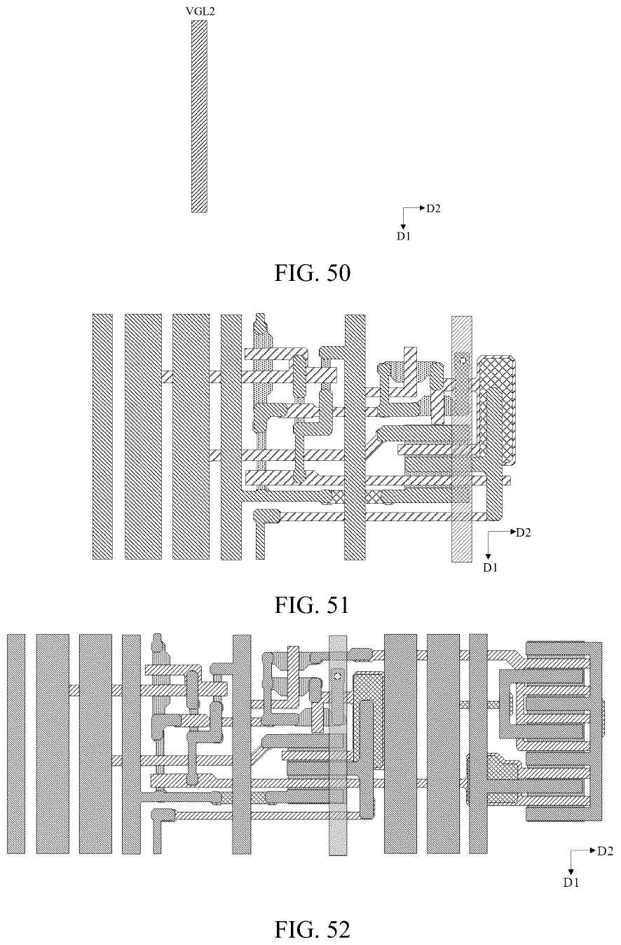

(7) Forming a pattern of a fourth conductive layer, includes: depositing a fourth metal thin film on the base substrate on which the aforementioned patterns are formed, patterning the fourth metal thin film through a patterning process to form a pattern of a fourth metal layer, as shown in FIGS. 50 to 52. FIG. 50 is a schematic diagram of a pattern of a fourth conductive layer in FIG. 30 and FIG. 31, FIG. 51 is a schematic diagram after a pattern of a fourth conductive layer is formed in FIG. 30, and FIG. 52 is a schematic diagram after a pattern of a fourth conductive layer is formed in FIG. 31. In an exemplary implementation, the fourth conductive layer may be referred to as a second source-drain metal (SD2) layer.

In an exemplary implementation mode, as shown in FIGS. 50 to 52, the pattern of the fourth conductive layer may include a third power supply line VGL2.

In an exemplary implementation mode, as illustrated in FIGS. 50 to 52, the third power supply line VGL2 may have a shape of a line and extend along the first direction D1. The third power supply line VGL2 is connected to the first electrode of the eleventh transistor through the thirty-fifth via. An orthographic projection of the third power supply line VGL2 on the base substrate is partially overlapped with orthographic projections of the fourth transistor and the fifth transistor on the base substrate.

In an exemplary implementation mode, as shown in FIG. 51, an orthographic projection of the third power supply line VGL2 on the base substrate is located at a side of an orthographic projection of the second power supply line on the base substrate close to the display region. As shown in FIG. 52, an orthographic projection of the third power supply line VGL2 on the base substrate is located between an orthographic projection of the first second power supply line on the base substrate and an orthographic projection of the third clock signal line on the base substrate.

(8) Forming a pattern of a planarization layer, includes: depositing a fifth insulating thin film on the base substrate on which the aforementioned patterns are formed, coating a second planarization thin film, patterning the fifth insulating thin film and the second planarization thin film through a patterning process, to form a pattern of a fifth insulation layer and the pattern of the planarization layer overlaying the aforementioned patterns.

So far, the driving structure layer has been prepared on the base substrate. In a plane parallel to the display substrate, the driving structure layer may include a plurality of shift register units, and the driving structure layer may be disposed on the base substrate. The driving structure layer may include a semiconductor layer, a first insulation layer, a first conductive layer, a second insulation layer, a second conductive layer, a third insulation layer, a third conductive layer, a fourth insulation layer, a fourth conductive layer, a fifth conductive layer and a planarization layer that are sequentially disposed on the base substrate.

In an exemplary implementation mode, the semiconductor layer may be an amorphous silicon layer, a polysilicon layer, or may be a metal oxide layer. Herein, the metal oxide layer may be an oxide including indium and tin, an oxide including tungsten and indium, an oxide including tungsten, indium, and zinc, an oxide including titanium and indium, an oxide including titanium, indium, and tin, an oxide including indium and zinc, an oxide including silicon, indium, and tin, or an oxide including indium or gallium and zinc. The metal oxide layer may be a single layer, a double-layer, or a multi-layer.

In an exemplary implementation mode, the first conductive layer, the second conductive layer, the third conductive layer, and the fourth conductive layer may be made of a metal material, such as any one or more of Argentum (Ag), Copper (Cu), Aluminum (Al), and Molybdenum (Mo), or an alloy material of the above metals, such as an Aluminum Neodymium alloy (AlNd) or a Molybdenum Niobium alloy (MoNb), and may be of a single-layer structure or a multi-layer composite structure, such as Mo/Cu/Mo.

In an exemplary implementation mode, the first insulation layer, the second insulation layer, the third insulation layer, the fourth insulation layer, and the fifth insulation layer may be made of any one or more of Silicon Oxide (SiOx), Silicon Nitride (SiNx), and Silicon Oxynitride (SiON), and may be a single layer, a multi-layer, or a composite layer.

In an exemplary implementation mode, the planarization layer may be made of an organic material, such as resin.

In an exemplary implementation mode, after preparation of the drive structure layer is completed, a light emitting structure layer is prepared on the drive structure layer, and a preparation process of the light emitting structure layer may include following operations.

Depositing an anode conductive thin film on the base substrate on which the above-mentioned patterns are formed, patterning the anode conductive thin film through a patterning process to form a pattern of an anode conductive layer disposed on the planarization layer, depositing a pixel definition thin film on the base substrate on which the above-mentioned patterns are formed, patterning the pixel definition thin film through a patterning process to form a pattern of a pixel definition layer exposing the pattern of the anode conductive layer, coating an organic light emitting material on the base substrate on which the pattern of the pixel definition layer is formed, patterning the organic light emitting material through a patterning process to form a pattern of an organic structure layer, depositing a cathode conductive thin film on the base substrate on which the pattern of the organic structure layer is formed, and patterning the cathode conductive thin film through a patterning process to form a cathode conductive layer.

So far, the light emitting structure layer has been manufactured on the base substrate.

In an exemplary implementation mode, a subsequent preparation process may include: forming an encapsulation structure layer on the cathode conductive layer, and the encapsulation structure layer may include a first encapsulation layer, a second encapsulation layer, and a third encapsulation layer which are stacked. The first encapsulation layer and the third encapsulation layer may be made of an inorganic material, the second encapsulation layer may be made of an organic material, and the second encapsulation layer is disposed between the first encapsulation layer and the third encapsulation layer, which may ensure that external water vapor cannot enter the light emitting structure layer.

In an exemplary implementation mode, the anode conductive layer includes at least patterns of a plurality of anodes.

In an exemplary implementation mode, the anode conductive layer may be of a single-layer structure, such as Indium Tin Oxide (ITO) or Indium Zinc Oxide (IZO), or may be of a multi-layer composite structure, such as ITO/Ag/ITO.

In an exemplary implementation mode, the organic structure layer may at least include: an organic emitting layer of a light emitting device.

In an exemplary implementation mode, the cathode conductive layer may include, at least, cathodes of a plurality of light emitting devices.

In an exemplary implementation mode, the cathode layer may be made of a metal material, such as any one or more of Argentum (Ag), Copper (Cu), Aluminum (Al), and Molybdenum (Mo), or the above conductive alloy materials, such as an Aluminum Neodymium alloy (AlNd) or a Molybdenum Niobium alloy (MoNb), and may have a single-layer structure or a multi-layer composite structure, such as Mo/Cu/Mo. Exemplarily, the fourth conductive layer may be of a three-layer stacked structure formed of titanium, aluminum, and titanium.

The display substrate according to the embodiment of the present disclosure may be applied to a display product with any resolution.

The accompanying drawings of the present disclosure only involve the structures involved in the embodiments of the present disclosure, and other structures may refer to usual designs.

For the sake of clarity, a thickness and size of a layer or a micro structure are enlarged in the accompanying drawings used for describing the embodiments of the present disclosure. It may be understood that when an element such as a layer, film, region, or substrate is described as being “on” or “under” another element, the element may be “directly” located “on” or “under” the another element, or there may be an intermediate element.

Although implementation modes of the present disclosure are disclosed above, contents described are only implementation modes used for ease of understanding of the present disclosure, but not intended to limit the present disclosure. Any of those skilled in the art of the present disclosure can make any modifications and variations in the implementation mode and details without departing from the spirit and scope of the present disclosure. However, the protection scope of the present disclosure should be subject to the scope defined by the appended claims.

1. A shift register unit comprising: a node control sub-circuit, an output sub-circuit, and a pull-down sub-circuit; wherein
the node control sub-circuit is electrically connected to a signal input terminal, a first clock signal terminal, a second clock signal terminal, a first power supply terminal, a second power supply terminal, a first node, a the second node, respectively, and is configured to provide a signal at the signal input terminal or the first power supply terminal to the first node and provide a signal at the second power supply terminal or the first clock signal terminal to the second node under control of signals at the first clock signal terminal and the second clock signal terminal;
the pull-down sub-circuit is electrically connected to the first node and a third power supply terminal, respectively, and is configured to provide a signal at the third power supply terminal to the first node;
the output sub-circuit is electrically connected to the second clock signal terminal, the first power supply terminal, the second power supply terminal, a first signal output terminal, the first node, and the second node, respectively, and is configured to provide a signal at the first power supply terminal or the second clock signal terminal to the first signal output terminal under control of signals at the first node, the second node, and the second power supply terminal;
an absolute value of a voltage value of the signal at the third power supply terminal is less than an absolute value of a voltage value of the signal at the second power supply terminal.

2. The shift register unit according to claim 1, wherein the pull-down sub-circuit comprises: an eleventh transistor;
a first electrode of the eleventh transistor is electrically connected to the third power supply terminal, and a second electrode of the eleventh transistor is electrically connected to the first node.

3. The shift register unit according to claim 2, wherein a control electrode of the eleventh transistor is electrically connected to the first node.

4. The shift register unit according to claim 1, wherein the node control sub-circuit comprises: a first transistor, a second transistor, a third transistor, a sixth transistor, and a seventh transistor;
a control electrode of the first transistor is connected to the first clock signal terminal, a first electrode of the first transistor is electrically connected to the signal input terminal, and a second electrode of the first transistor is electrically connected to the first node;
a control electrode of the second transistor is electrically connected to the first node, a first electrode of the second transistor is connected to the first clock signal terminal, and the second electrode of the second transistor is electrically connected to the second node;
a control electrode of the third transistor is electrically connected to the first clock signal terminal, a first electrode of the third transistor is connected to the second power supply terminal, and a second electrode of the third transistor is electrically connected to the second node;
a control electrode of the sixth transistor is electrically connected to the second node, a first electrode of the sixth transistor is connected to the first power supply terminal, and a second electrode of the sixth transistor is electrically connected to a fourth node;
a control electrode of a seventh transistor is electrically connected to the second clock signal terminal, a first electrode of the seventh transistor is connected to the fourth node, and a second electrode of the seventh transistor is electrically connected to the first node.

5. The shift register unit according to claim 1, wherein the output sub-circuit comprises: a fourth transistor, a fifth transistor, and an eighth transistor;
a control electrode of the fourth transistor is electrically connected to the second node, a first electrode of the fourth transistor is connected to the first power supply terminal, and a second electrode of the fourth transistor is electrically connected to the first signal output terminal;
a control electrode of the fifth transistor is electrically connected to a third node, a first electrode of the fifth transistor is connected to the second clock signal terminal, and a second electrode of the fifth transistor is electrically connected to the first signal output terminal;
a control electrode of the eighth transistor is electrically connected to the second power supply terminal, a first electrode of the eighth transistor is electrically connected to the first node, and a second electrode of the eighth transistor is electrically connected to the third node.

6. The shift register unit according to claim 5, wherein the pull-down sub-circuit comprises: an eleventh transistor;
a control electrode of the eleventh transistor is electrically connected to the third node.

7. The shift register unit according to claim 5, wherein the output sub-circuit further comprises: at least one of a first capacitor and a second capacitor;
a first plate of the first capacitor is electrically connected to the second node, and a second plate of the first capacitor is electrically connected to the first power supply terminal;
a first plate of the second capacitor is electrically connected to the third node, and a second plate of the second capacitor is electrically connected to the first signal output terminal.

8. The shift register unit according to claim 1, wherein the output sub-circuit is further electrically connected to a third clock signal terminal and a second signal output terminal, respectively, is configured to provide signals at the second power supply terminal or the third clock signal terminal to the second signal output terminal under control of signals at the first node and the second node.

9. The shift register unit according to claim 8, wherein the output sub-circuit comprises: a fourth transistor, a fifth transistor, an eighth transistor, a ninth transistor, and a tenth transistor;
a control electrode of the fourth transistor is electrically connected to the second node, a first electrode of the fourth transistor is connected to the first power supply terminal, and a second electrode of the fourth transistor is electrically connected to the first signal output terminal;
a control electrode of the fifth transistor is electrically connected to a third node, a first electrode of the fifth transistor is connected to the second clock signal terminal, and a second electrode of the fifth transistor is electrically connected to the first signal output terminal;
a control electrode of the eighth transistor is electrically connected to the second power supply terminal, a first electrode of the eighth transistor is electrically connected to the first node, and a second electrode of the eighth transistor is electrically connected to the third node;
a control electrode of the ninth transistor is electrically connected to the first node, a first electrode of the ninth transistor is connected to the third clock signal terminal, and a second electrode of the ninth transistor is electrically connected to the second signal output terminal;
a control electrode of the tenth transistor is electrically connected to the second node, a first electrode of the tenth transistor is connected to the second power supply terminal, and a second electrode of the tenth transistor is electrically connected to the second signal output terminal.

10. The shift register unit according to claim 9, wherein the output sub-circuit further comprises: a twelfth transistor; the control electrode of the ninth transistor is electrically connected to the first node through the twelfth transistor;
a control electrode of the twelfth transistor is electrically connected to the second power supply terminal, a first electrode of the twelfth transistor is electrically connected to the first node, and a second electrode of the twelfth transistor is electrically connected to the control electrode of the ninth transistor.

11. The shift register unit according to claim 9, wherein the output sub-circuit further comprises: at least one of a first capacitor, a second capacitor, a third capacitor, and a fourth capacitor;
a first plate of the first capacitor is electrically connected to the second node, and a second plate of the first capacitor is electrically connected to the first power supply terminal;
a first plate of the second capacitor is electrically connected to the third node, and a second plate of the second capacitor is electrically connected to the first signal output terminal;
a first plate of the third capacitor is electrically connected to the control electrode of the ninth transistor, and a second plate of the third capacitor is connected to the second signal output terminal; and
a first plate of the fourth capacitor is electrically connected to the second node, and a second plate of the fourth capacitor is connected to the second power supply terminal.

12. The shift register unit according to claim 8, wherein the signal at the third clock signal terminal and the signal at the second clock signal terminal are mutually inverted signals.

13. The shift register unit according to claim 1, further comprising: an output control sub-circuit;
the output control sub-circuit is electrically connected to the first power supply terminal and the first signal output terminal, respectively, and is configured to store a voltage difference between signals at the first signal output terminal and the first power supply terminal.

14. The shift register unit according to claim 13, wherein the output control sub-circuit comprises: a fifth capacitor;
a first plate of the fifth capacitor is electrically connected to the first power supply terminal, and a second electrode of the fifth capacitor is electrically connected to the first signal output terminal.

15. The shift register unit according to claim 1, wherein the signal at the first clock signal terminal and the signal at the second clock signal terminal are not simultaneously effective level signals.

16. A display substrate comprising: a base substrate and sub-pixels, a gate line and a gate driving circuit disposed on the base substrate, the base substrate is provided with a display region and a non-display region, the gate driving circuit is located in the non-display region, the sub-pixels and the gate line are located in the display region, and the gate line is electrically connected to the sub-pixels and the gate driving circuit, respectively;
the gate driving circuit comprises a plurality of cascaded shift register units as claimed in claim 1, wherein a first signal output terminal of an i-th stage shift register unit is connected to a signal input terminal of an (i+1)-st stage shift register unit, 1≤i<N, N is a total number of stages of the shift register units.

17. The display substrate according to claim 16, wherein a first signal output terminal of a shift register unit is electrically connected to the gate line.

18. The display substrate according to claim 16, further comprising: an initial signal line, a first clock signal line, a second clock signal line, a first power supply line, a second power supply line, and a third power supply line disposed on the base substrate and located in the non-display region;
any one of the initial signal line, the first clock signal line, the second clock signal line, the first power supply line, the second power supply line, and the third power supply line extends in a first direction, and the gate line extends in a second direction, and the first direction intersects the second direction.

19-39. (canceled)

40. A display apparatus, comprising: the display substrate of claim 16.

41. A method for driving a shift register unit, configured to drive the shift register unit according to claim 1, wherein the method comprises:
providing a signal at the signal input terminal or the first power supply terminal to the first node and providing a signal at the second power supply terminal or the first clock signal terminal to the second node under control of signals at the first clock signal terminal and the second clock signal terminal by the node control sub-circuit;
providing a signal at the third power supply terminal to the first node by the pull-down sub-circuit; and
providing a signal at the first power supply terminal or the second clock signal terminal to the first signal output terminal under control of signals at the first node and the second node by the output sub-circuit.

42. (canceled)
